(19) United States
(12) Patent Application Publication
(10) Pub. No.: US 2023/0121327 A1
(43) Pub. Date: Apr. 20, 2023

(54) NITRIDE SEMICONDUCTOR LIGHT-EMITTING ELEMENT

(71) Applicant: Nuvoton Technology Corporation Japan, Kyoto (JP)

(72) Inventors: Yasutomo MITSUI, Toyama (JP); Masanori HIROKI, Shiga (JP); Shigeo HAYASHI, Kyoto (JP); Masahiro KUME, Toyama (JP)

(21) Appl. No.: 18/068,297

(22) Filed: Dec. 19, 2022

Related U.S. Application Data
(63) Continuation of application No. PCT/JP2021/022901, filed on Jun. 16, 2021.

(30) Foreign Application Priority Data
Jul. 2, 2020 (JP) 2020-115021

(51) Int. Cl. H01L 33/32; H01L 33/00; H01L 33/38

(52) U.S. Cl. CPC H01L 33/32; H01L 33/0008; H01L 33/38

(57) ABSTRACT

A nitride semiconductor light-emitting element includes: a substrate; a rectangular semiconductor stack structure including an n-type semiconductor layer, an active layer, and a p-type semiconductor layer stacked in sequence above a main surface of the substrate; a p-side contact electrode in contact with the p-type semiconductor layer in a p-side contact region; and an n-side contact electrode in contact with the n-type semiconductor layer in an n-side contact region. In a plan view of the main surface, the semiconductor stack structure includes a first corner portion, the n-side contact region includes a linear first region extending in one direction from a first starting point spaced apart from the first corner portion, the p-side contact region is disposed between the first starting point and the first corner portion where the distance therebetween is less than or equal to 0.26 times the length of a shorter side of the semiconductor stack structure.

### CROSS REFERENCE TO RELATED APPLICATIONS

This is a continuation application of PCT International Application No. PCT/JP2021/022901 filed on Jun. 16, 2021, designating the United States of America, which is based on and claims priority of Japanese Patent Application No. 2020-115021 filed on Jul. 2, 2020. The entire disclosures of the above-identified applications, including the specifications, drawings and claims are incorporated herein by reference in their entirety.

### FIELD

The present disclosure relates to a nitride semiconductor light-emitting element.

### BACKGROUND

Nitride semiconductor light-emitting elements are used as a light source of automotive headlamps, etc. Automotive headlamps are increasingly miniaturized and becoming high-power. Accordingly, nitride semiconductor light-emitting elements used for automotive headlamps are also desired to be miniaturized and become high-power.

For example, in the nitride semiconductor light-emitting element described in Patent Literature (PTL) 1, current is injected into a wide range of an n-type semiconductor layer by causing an n-side electrode in contact with the n-type semiconductor layer to have an annular shape. This is an attempt to improve the luminance of the nitride semiconductor light-emitting elements.

### CITATION LIST

### Patent Literature

PTL 1: International Publication No. 2013/161208

### SUMMARY

### Technical Problem

However, the conventional nitride semiconductor light-emitting elements described in PTL 1, etc., fail to sufficiently reduce the loss component of the forward voltage that does not contribute to light emission. For this reason, the utilization efficiency of power has not been sufficiently improved in the conventional nitride semiconductor light-emitting elements. In addition, when the loss component of the forward voltage increases, the amount of heat generated in the nitride semiconductor light-emitting element increases, leading to a decrease in the performance and reliability of the nitride semiconductor light-emitting elements.

The present disclosure solves such problems and provides a nitride semiconductor light-emitting element that is capable of reducing the forward voltage.

### Solution to Problem

In order to solve the above-described problems, a nitride semiconductor light-emitting element according to one aspect of the present disclosure includes: a substrate; a semiconductor stack structure including an n-type semiconductor layer, an active layer, and a p-type semiconductor layer stacked in sequence above a main surface of the substrate, the semiconductor stack structure having a rectangular shape in a plan view of the main surface; a p-side contact electrode disposed above and in contact with the p-type semiconductor layer in a p-side contact region; and an n-side contact electrode disposed above and in contact with the n-type semiconductor layer in an n-side contact region. In the nitride semiconductor light-emitting element, in the plan view of the main surface, the semiconductor stack structure includes a first corner portion, the n-side contact region includes a first region having a linear shape and extending in one direction from a first starting point that is spaced apart from the first corner portion, the p-side contact region is disposed between the first starting point and the first corner portion, and distance r1 that is a distance between the first corner portion and the first starting point is less than or equal to 0.26 times length a of a shorter side of the semiconductor stack structure.

In addition, in one aspect of the nitride semiconductor light-emitting element according to the present disclosure, in the plan view of the main surface, the semiconductor stack structure includes a second corner portion disposed on a same side of a rectangular outer edge of the semiconductor stack structure as the first corner portion, the n-side contact region includes a second region having a linear shape and extending in one direction from a second starting point that is spaced apart from the second corner portion, the p-side contact region is disposed between the second starting point and the second corner portion, and distance r2 that is a distance between the second corner portion and the second starting point is less than or equal to 0.26 times length a of a shorter side of the semiconductor stack structure.

In addition, in one aspect of the nitride semiconductor light-emitting element according to the present disclosure, in the plan view of the main surface, the first region and the second region may intersect.

In addition, in one aspect of the nitride semiconductor light-emitting element according to the present disclosure, in the plan view of the main surface, an extended line of the first region and an extended line of the second may intersect.

In addition, in one aspect of the nitride semiconductor light-emitting element according to the present disclosure, in the plan view of the main surface, the semiconductor stack structure may include a third corner portion disposed diagonally to the first corner portion and a fourth corner portion disposed diagonally to the second corner portion, the n-side contact region may include a third region having a linear shape and extending in one direction from a third starting point that is spaced apart from the third corner portion, and a fourth region having a linear shape and extending in one direction from a fourth starting point that is spaced apart from the fourth corner portion, the p-side contact region may be disposed between the third starting point and the third corner portion, and between the fourth starting point and the fourth corner portion, and distance r3 that is a distance between the third corner portion and the third starting point may be less than or equal to 0.26 times length a of the shorter side, and distance r4 that is a distance between the fourth corner portion and the fourth starting point may be less than or equal to 0.26 times length a of the shorter side.

In addition, in one aspect of the nitride semiconductor light-emitting element according to the present disclosure, in the plan view of the main surface, the first region and the third region may be connected to each other, the third region being disposed on an extended line of the first region, the second region and the fourth region may be connected to each other, the fourth region being disposed on an extended line of the second region.

In addition, in one aspect of the nitride semiconductor light-emitting element according to the present disclosure, in the plan view of the main surface, the first region and the third region may extend in the same direction, and the second region and the fourth region may extend in the same direction.

In addition, in one aspect of the nitride semiconductor light-emitting element according to the present disclosure, in the plan view of the main surface, the third region may be disposed on an extended line of the first region and spaced apart from the first region, the fourth region may be disposed on an extended line of the second region and spaced apart from the second region.

In addition, in one aspect of the nitride semiconductor light-emitting element according to the present disclosure, in the plan view of the main surface, the first region and the third region may extend in the same direction, and the second region and the fourth region may extend in the same direction.

In addition, in one aspect of the nitride semiconductor light-emitting element according to the present disclosure, in the plan view of the main surface, the n-side contact region may include: a fifth region disposed between the first region and the third region and spaced apart from each of the first region and the third region, the fifth region having a linear shape; and a sixth region disposed between the second region and the fourth region and spaced apart from each of the second region and the fourth region, the sixth region having a linear shape, and the fifth region and the sixth region may intersect.

In addition, in one aspect of the nitride semiconductor light-emitting element according to the present disclosure, in the plan view of the main surface, the first region, the second region, the third region, and the fourth region may be spaced apart from one another.

In addition, in one aspect of the nitride semiconductor light-emitting element according to the present disclosure, proportion b of an area of the n-side contact region to an area of the semiconductor stack structure in the plan view of the main surface may be less than or equal to 0.3.

In addition, in one aspect of the nitride semiconductor light-emitting element according to the present disclosure, b≤0.3, r1=r2=r3=r4, and 0<r1/a<−0.54b²+0.59b+0.16 may be satisfied where: r1 denotes the first distance that is the distance between the first corner portion and the first starting point, r2 denotes the second distance that is the distance between the second corner portion and the second starting point, r3 denotes the third distance that is the distance between the third corner portion and the third starting point, r4 denotes the fourth distance that is the distance between the fourth corner portion and the fourth starting point; a denotes the length of the shorter side; and b denotes the proportion of an area of the n-side contact region to an area of the semiconductor stack structure in the plan view of the main surface.

In addition, in one aspect of the nitride semiconductor light-emitting element according to the present disclosure, b≤0.3, d1=d2=d3=d4, and 0<d1/a<1.41b²−1.13b+0.55 may be satisfied, where: d1 denotes a distance between the first region and the fifth region; d2 denotes a distance between the second region and the sixth region; d3 denotes a distance between the third region and the fifth region; d4 denotes a distance between the fourth region and the sixth region, a denotes the length of the shorter side; and b denotes the proportion of an area of the n-side contact region to an area of the semiconductor stack structure in the plan view of the main surface.

In addition, in one aspect of the nitride semiconductor light-emitting element according to the present disclosure, b≤0.3, d1=d2=d3=d4, and 0<d1/a<−0.92b²+1.12b+0.05 may be satisfied, where: d1 denotes a distance between the first region and the fifth region; d2 denotes a distance between the second region and the sixth region; d3 denotes a distance between the third region and the fifth region; d4 denotes a distance between the fourth region and the sixth region, a denotes the length of the shorter side; and b denotes the proportion of an area of the n-side contact region to an area of the semiconductor stack structure in the plan view of the main surface.

In addition, in one aspect of the nitride semiconductor light-emitting element according to the present disclosure, b≤0.3, d5=d6, and 0<d5/a<1.06b²−0.95b+0.61 may be satisfied, where: d5 denotes a fifth distance that is half a distance between the first region and the third region; d6 denotes a sixth distance that is half a distance between the second region and the fourth region; a denotes the length of the shorter side; and b denotes the proportion of an area of the n-side contact region to an area of the semiconductor stack structure in the plan view of the main surface.

In addition, in one aspect of the nitride semiconductor light-emitting element according to the present disclosure, b≤0.3, d5=d6, and 0<d5/a<−0.95b²+0.89b+0.11 may be satisfied, where: d5 denotes a fifth distance that is half a distance between the first region and the third region; d6 denotes a sixth distance that is half a distance between the second region and the fourth region; a denotes the length of the shorter side; and b denotes the proportion of an area of the n-side contact region to an area of the semiconductor stack structure in the plan view of the main surface.

In addition, in one aspect of the nitride semiconductor light-emitting element according to the present disclosure, in the plan view of the main surface, the first region and the second region may be connected to each other.

In addition, in one aspect of the nitride semiconductor light-emitting element according to the present disclosure, in the plan view of the main surface, the n-side contact region may include: a first additional region having a linear shape and extending from the first starting point in a direction different from a direction of the first region; a second additional region having a linear shape and extending from the second starting point in a direction different from a direction of the second region; a third additional region having a linear shape and extending from the third starting point in a direction different from a direction of the third region; and a fourth additional region having a linear shape and extending from the fourth starting point in a direction different from a direction of the fourth region, the first region and the second additional region may be connected to each other, the second region and the third additional region may be connected to each other, the third region and the fourth additional region may be connected to each other, and the fourth region and the first additional region may be connected to each other.

In addition, in one aspect of the nitride semiconductor light-emitting element according to the present disclosure, in the plan view of the main surface, the first region and the second additional region may extend in the same direction, the second region and the third additional region the third region and the fourth additional region may extend linearly in the same direction, and the fourth region and the first additional region may extend in the same direction.

In addition, in one aspect of the nitride semiconductor light-emitting element according to the present disclosure, in the plan view of the main surface, the second region may be disposed on an extended line of the first region and spaced apart from the first region. The second region may extend in a same direction as the first region

In addition, in one aspect of the nitride semiconductor light-emitting element according to the present disclosure, in the plan view of the main surface, the n-side contact region may include: a first additional region having a linear shape and extending from the first starting point in a direction different from a direction of the first region; a second additional region having a linear shape and extending from the second starting point in a direction different from a direction of the second region; a third additional region having a linear shape and extending from the third starting point in a direction different from a direction of the third region; and a fourth additional region having a linear shape and extending from the fourth starting point in a direction different from a direction of the fourth region, the second additional region may be disposed on an extended line of the first region and spaced apart from the first region, the second additional region extending in the same direction as the first region, the third additional region may be disposed on an extended line of the second region and spaced apart from the second region, the third additional region extending in the same direction as the second region, the fourth additional region may be disposed on an extended line of the third region and spaced apart from the third region, the fourth additional region extending in the same direction as the third region, and the first additional region may be disposed on an extended line of the fourth region and spaced apart from the fourth region, the first additional region extending in the same direction as the fourth region.

In addition, in one aspect of the nitride semiconductor light-emitting element according to the present disclosure, b≤0.3, r1=r2=r3=r4, and 0<r1/a≤0.26 may be satisfied where: r1 denotes the first distance that is the distance between the first corner portion and the first starting point, r2 denotes the second distance that is the distance between the second corner portion and the second starting point, r3 denotes the third distance that is the distance between the third corner portion and the third starting point, r4 denotes the fourth distance that is the distance between the fourth corner portion and the fourth starting point; a denotes the length of the shorter side; and b denotes the proportion of an area of the n-side contact region to an area of the semiconductor stack structure in the plan view of the main surface.

In addition, in one aspect of the nitride semiconductor light-emitting element according to the present disclosure, b≤0.3, r1=r2=r3=r4, and −0.26b+0.15<r1/a≤0.26 may be satisfied where: r1 denotes the first distance that is the distance between the first corner portion and the first starting point, r2 denotes the second distance that is the distance between the second corner portion and the second starting point, r3 denotes the third distance that is the distance between the third corner portion and the third starting point, r4 denotes the fourth distance that is the distance between the fourth corner portion and the fourth starting point; a denotes the length of the shorter side; and b denotes the proportion of an area of the n-side contact region to an area of the semiconductor stack structure in the plan view of the main surface.

In addition, in one aspect of the nitride semiconductor light-emitting element according to the present disclosure, b≤0.3, d7=d8=d9=d10, and −2.50b²+1.75b−0.15<d7/a<−0.30b+0.35 may be satisfied where: d7 denotes a seventh distance that is a distance between the first region and the second additional region, d8 denotes an eighth distance that is a distance between the second region and the third additional region, d9 denotes a ninth distance that is a distance between the third region and the fourth additional region, d10 denotes a tenth distance that is a distance between the fourth region and the first additional region; a denotes the length of the shorter side; and b denotes a proportion of an area of the n-side contact region to an area of the semiconductor stack structure in the plan view of the main surface.

In addition, in one aspect of the nitride semiconductor light-emitting element according to the present disclosure, b≤0.3, d7=d8=d9=d10, and 0<d7/a<−5.20b²+2.09b+0.09 may be satisfied where: d7 denotes a seventh distance that is a distance between the first region and the second additional region, d8 denotes an eighth distance that is a distance between the second region and the third additional region, d9 denotes a ninth distance that is a distance between the third region and the fourth additional region, d10 denotes a tenth distance that is a distance between the fourth region and the first additional region; a denotes the length of the shorter side; and b denotes a proportion of an area of the n-side contact region to an area of the semiconductor stack structure in the plan view of the main surface.

In addition, in one aspect of the nitride semiconductor light-emitting element according to the present disclosure, the nitride semiconductor light-emitting element may include: a substrate; a semiconductor stack structure including an n-type semiconductor layer, an active layer, and a p-type semiconductor layer stacked in sequence above a main surface of the substrate, the semiconductor stack structure having a rectangular shape in a plan view of the main surface of the substrate; a p-side contact electrode disposed above and in contact with the p-type semiconductor layer in a p-side contact region; and a plurality of n-side contact electrodes disposed above the n-type semiconductor layer, each of the plurality of n-side contact electrodes being in contact with the n-type semiconductor layer in a corresponding one of a plurality of n-side contact regions arranged in a matrix of at least three rows and three columns. In the nitride semiconductor light-emitting element, in the plan view of the main surface, the semiconductor stack structure may include a first corner portion, the plurality of n-side contact regions may include: a first n-side contact region disposed in closest proximity to the first corner portion; a first Xn-side contact region disposed adjacent to the first n-side contact region in a row direction; and a first Yn-side contact region disposed adjacent to the first n-side contact region in a column direction, the first n-side contact region may be disposed in a first unit having a rectangular shape, the first unit being enclosed by: a straight line that is equidistant from a center of gravity of the first n-side contact region and a center of gravity of the first Xn-side contact region; a straight line that is equidistant from the center of gravity of the first n-side contact region and a center of gravity of the first Yn-side contact region; and an outer edge of the semiconductor stack structure, the first n-side contact region may include a first region having a linear shape and extending in one direction from a first starting point that is spaced apart from the first corner portion, the p-side contact region may be disposed between the first starting point and the first corner portion, and distance r1 that is a distance between the first corner portion and the first starting point may be less than or equal to 0.26 times length a1 of a shorter side of the first unit.

In addition, in one aspect of the nitride semiconductor light-emitting element according to the present disclosure, in the plan view of the main surface, the semiconductor stack structure may include a second corner portion disposed on a same side of a rectangular outer edge of the semiconductor stack structure as the first corner portion, a third corner portion disposed diagonally to the first corner portion, and a fourth corner portion disposed diagonally to the second corner portion, the plurality of n-side contact regions may include: a second n-side contact region disposed in closest proximity to the second corner portion; a second Xn-side contact region disposed adjacent to the second n-side contact region in a row direction; a second Yn-side contact region disposed adjacent to the second n-side contact region in a column direction; a third n-side contact region disposed in closest proximity to the third corner portion; a third Xn-side contact region disposed adjacent to the third n-side contact region in a row direction; a third Yn-side contact region disposed adjacent to the third n-side contact region in a column direction; a fourth n-side contact region disposed in closest proximity to the fourth corner portion; a fourth Xn-side contact region disposed adjacent to the fourth n-side contact region in a row direction; and a fourth Yn-side contact region disposed adjacent to the fourth n-side contact region in a column direction, the second n-side contact region may be disposed in a second unit having a rectangular shape, the second unit being enclosed by: a straight line that is equidistant from a center of gravity of the second n-side contact region and a center of gravity of the second Xn-side contact region; a straight line that is equidistant from the center of gravity of the second n-side contact region and a center of gravity of the second Yn-side contact region; and an outer edge of the semiconductor stack structure, the third n-side contact region may be disposed in a third unit having a rectangular shape, the third unit being enclosed by: a straight line that is equidistant from a center of gravity of the third n-side contact region and a center of gravity of the third Xn-side contact region; a straight line that is equidistant from the center of gravity of the third n-side contact region and a center of gravity of the third Yn-side contact region; and an outer edge of the semiconductor stack structure, the fourth n-side contact region may be disposed in a fourth unit having a rectangular shape, the fourth unit being enclosed by: a straight line that is equidistant from a center of gravity of the fourth n-side contact region and a center of gravity of the fourth Xn-side contact region; a straight line that is equidistant from the center of gravity of the fourth n-side contact region and a center of gravity of the fourth Yn-side contact region; and an outer edge of the semiconductor stack structure, the second n-side contact region may include a second region having a linear shape and extending in one direction from a second starting point that is spaced apart from the second corner portion, the third n-side contact region may include a third region having a linear shape and extending in one direction from a third starting point that is spaced apart from the third corner portion, the fourth n-side contact region may include a fourth region having a linear shape and extending in one direction from a fourth starting point that is spaced apart from the fourth corner portion, the p-side contact region may be disposed between the second starting point and the second corner portion, between the third starting point and the third corner portion, and between the fourth starting point and the fourth corner portion, and distance r2 that is a distance between the second corner portion and the second starting point may be less than or equal to 0.26 times length a2 of a shorter side of the second unit, distance r3 that is a distance between the third corner portion and the third starting point may be less than or equal to 0.26 times length a3 of a shorter side of the third unit, and distance r4 that is a distance between the fourth corner portion and the fourth starting point may be less than or equal to 0.26 times length a4 of a shorter side of the fourth unit.

In addition, in one aspect of the nitride semiconductor light-emitting element according to the present disclosure, in the plan view of the main surface, the plurality of n-side contact regions may be arranged in a matrix of N rows and M columns where N≥3 and M≥3, centers of gravity of M n-side contact regions among the plurality of n-side contact regions may be on a straight line, the M n-side contact regions being disposed in each of first to N-th rows, centers of gravity of N n-side contact regions among the plurality of n-side contact regions may be on a straight line, the N n-side contact regions being disposed in each of first to M-th columns, in a unit enclosed by (i) a third straight line that divides equally a region between a first straight line and a second straight line, (ii) a fifth straight line that divides equally a region between the second straight line and a fourth straight line, (iii) an eighth straight line that divides equally a region between a sixth straight line and a seventh straight line, and (iv) a tenth straight line that divides equally a region between the seventh straight line and a ninth straight line, the first straight line connecting centers of gravity of the M n-side contact regions disposed in an i−1-th row where 2≤i≤N−1, the second straight line connecting centers of gravity of the M n-side contact regions disposed in an i-th row, the fourth straight line connecting centers of gravity of the M n-side contact regions disposed in an i+1-th row, the sixth straight line connecting centers of gravity of the N n-side contact regions disposed in an j−1-th column where 2≤j≤M−1, the seventh straight line connecting centers of gravity of the N n-side contact regions disposed in a j-th column, the ninth straight line connecting the centers of gravity of the N n-side contact regions disposed in a j+1-th column, the unit may include: a first unit corner portion between the third straight line and the eighth straight line; a second unit corner portion between the fifth straight line and the eighth straight line; a third unit corner portion disposed diagonally to the first unit corner portion; and a fourth unit corner portion disposed diagonally to the second unit corner portion, among the plurality of n-side contact regions, an n-side contact region disposed in the unit may include a first unit region extending in one direction from a first unit starting point that is spaced apart from the first unit corner portion, the first unit region having a linear shape, the p-side contact region may be disposed between the first unit starting point and the first unit corner portion, distance ru1 that is a distance from the first unit corner portion and the first unit starting point may be less than or equal to 0.26 times length au1 of a shorter side of the unit, and among the plurality of n-side contact regions, n-side contact regions disposed in all of the units that satisfy 2≤i≤N−1, and 2≤j≤M−1 may include the first unit region.

In addition, in one aspect of the nitride semiconductor light-emitting element according to the present disclosure, the n-side contact region disposed in the unit may include: a second unit region having a linear shape and extending in one direction from a second unit starting point that is spaced apart from the second unit corner portion; a third unit region having a linear shape and extending in one direction from a third unit starting point that is spaced apart from the third unit corner portion; and a fourth unit region having a linear shape and extending in one direction from a fourth unit starting point that is spaced apart from the fourth unit corner portion, the p-side contact region may be disposed between the second unit starting point and the second unit corner portion, between the third unit starting point and the third unit corner portion, and between the fourth unit starting point and the fourth unit corner portion, and distance rut between the second unit corner portion and the second unit starting point, distance ru3 between the third unit corner portion and the third unit starting point, and distance ru4 between the fourth unit corner portion and the fourth unit starting point may be each less than or equal to 0.26 times length au1 of the shorter side of the unit.

In addition, in one aspect of the nitride semiconductor light-emitting element according to the present disclosure, in the plan view of the main surface, the first n-side contact region, the second n-side contact region, the third n-side contact region, and the fourth n-side contact region may each have an X shape, and b≤0.10 may be satisfied where b denotes the proportion of an area of the n-side contact region to an area of the semiconductor stack structure.

In addition, in one aspect of the nitride semiconductor light-emitting element according to the present disclosure, in the plan view of the main surface, the first n-side contact region, the second n-side contact region, the third n-side contact region, and the fourth n-side contact region may each have a rectangular annular shape, and b≤0.07 may be satisfied where b denotes the proportion of an area of the n-side contact region to an area of the semiconductor stack structure.

### Advantageous Effects

With the present disclosure, it is possible to provide a nitride semiconductor light-emitting element that is capable of reducing the forward voltage.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a diagram schematically illustrating the overall configuration of a nitride semiconductor light-emitting element according to Embodiment 1.

FIG. 2 is a cross sectional view schematically illustrating one example of the mounting aspect of the nitride semiconductor light-emitting element according to Embodiment 1.

FIG. 3 is a cross sectional view schematically illustrating a first process of a manufacturing method of the nitride semiconductor light-emitting element according to Embodiment 1.

FIG. 4 is a cross sectional view schematically illustrating a second process of the manufacturing method of the nitride semiconductor light-emitting element according to Embodiment 1.

FIG. 5 is a cross sectional view schematically illustrating a third process of the manufacturing method of the nitride semiconductor light-emitting element according to Embodiment 1.

FIG. 6 is a cross sectional view schematically illustrating a fourth process of the manufacturing method of the nitride semiconductor light-emitting element according to Embodiment 1.

FIG. 7 is a plan view illustrating the configurations of an n-side contact region and a p-side contact region according to Embodiment 1.

FIG. 8 illustrates graphs indicating the relationship between each position of the p-side contact region and the distance from the position to the n-side contact region, in each of the nitride semiconductor light-emitting element according to a comparison example and the nitride semiconductor light-emitting element according to Embodiment 1.

FIG. 9 is a graph indicating the relationship between forward voltage Vf and ratio r/a. Ratio r/a is the ratio of distance r from each of the corner portions to the n-side contact region to length a of the shorter side of the nitride semiconductor light-emitting element according to Embodiment 1.

FIG. 10 is a graph indicating the relationship between a normalized forward voltage and ratio r/a. Ratio r/a is the ratio of distance r from each of the corner portions to the n-side contact region to length a of the shorter side of the nitride semiconductor light-emitting element according to Embodiment 1.

FIG. 11 is a graph indicating the relationship between proportion b of the area of the n-side contact region to the area of the semiconductor stack structure of the nitride semiconductor light-emitting element according to Embodiment 1 and the maximum value of ratio r/a which allows the normalized forward voltage to be less than 1.

FIG. 12 is a graph indicating the relationship between proportion b of the area of the n-side contact region to the area of the semiconductor stack structure of the nitride semiconductor light-emitting element according to Embodiment 1 and the ratio of the light emission output to the nitride semiconductor light-emitting element according to the comparison example.

FIG. 13 is a plan view schematically illustrating the configuration of the n-side contact region of the nitride semiconductor light-emitting element according to Variation 1 of Embodiment 1.

FIG. 14 is a graph indicating the relationship between ratio d/a and the normalized forward voltage in the nitride semiconductor light-emitting element according to Variation 1 of Embodiment 1.

FIG. 15 is a graph indicating the relationship between proportion b and the maximum value of ratio d/a. Proportion b is the proportion of the area of the n-side contact region to the area of the semiconductor stack structure of the nitride semiconductor light-emitting element according to Variation 1 of Embodiment 1.

FIG. 16 is a graph indicating the relationship between proportion b of the area of the n-side contact region to the area of the semiconductor stack structure of the nitride semiconductor light-emitting element according to Variation 1 of Embodiment 1 and the maximum value of ratio d/a which allows the normalized forward voltage to be less than 1.

FIG. 17 is a plan view schematically illustrating the configuration of the n-side contact region of the nitride semiconductor light-emitting element according to Variation 2 of Embodiment 1.

FIG. 18 is a graph indicating the relationship between ratio d/a and the normalized forward voltage in the nitride semiconductor light-emitting element according to Variation 2 of Embodiment 1.

FIG. 19 is a graph indicating the relationship between proportion b of the area of the n-side contact region to the area of the semiconductor stack structure of the nitride semiconductor light-emitting element and the maximum value of ratio d/a according to Variation 2 of Embodiment 1.

FIG. 20 is a graph indicating the relationship between proportion b of the area of the n-side contact region to the area of the semiconductor stack structure of the nitride semiconductor light-emitting element and the maximum value of ratio d/a which allows the normalized forward voltage to be less than 1 according to Variation 2 of Embodiment 1.

FIG. 21 is a plan view schematically illustrating the configuration of the n-side contact region of the nitride semiconductor light-emitting element according to Variation 3 of Embodiment 1.

FIG. 22 is a plan view schematically illustrating the configuration of the n-side contact region of the nitride semiconductor light-emitting element according to Variation 4 of Embodiment 1.

FIG. 23 is a plan view schematically illustrating the configuration of the n-side contact region of the nitride semiconductor light-emitting element according to Variation 5 of Embodiment 1.

FIG. 24 is a plan view schematically illustrating the configuration of the n-side contact region of the nitride semiconductor light-emitting element according to Variation 6 of Embodiment 1.

FIG. 25 is a plan view schematically illustrating the configuration of the n-side contact region of the nitride semiconductor light-emitting element according to Variation 7 of Embodiment 1.

FIG. 26 is a plan view schematically illustrating the configuration of the n-side contact region of the nitride semiconductor light-emitting element according to Variation 8 of Embodiment 1.

FIG. 27 is a plan view schematically illustrating the configuration of the n-side contact region of the nitride semiconductor light-emitting element according to Embodiment 2.

FIG. 28 is a graph indicating the relationship between forward voltage Vf and ratio r/a. Ratio r/a is the ratio of distance r from each of the corner portions to the n-side contact region to length a of the shorter side of the nitride semiconductor light-emitting element according to Embodiment 2.

FIG. 29 is a graph indicating the relationship between the normalized forward voltage and ratio r/a. Ratio r/a is the ratio of distance r from each of the corner portions to the n-side contact region to length a of the shorter side of the nitride semiconductor light-emitting element according to Embodiment 2.

FIG. 30 is a graph indicating the relationship between proportion b of the area of the n-side contact region to the area of the semiconductor stack structure of the nitride semiconductor light-emitting element and the maximum value of ratio r/a which allows the normalized forward voltage to be less than the case where ratio r/a is 0.26 according to Embodiment 2.

FIG. 31 is a graph indicating the relationship between proportion b of the area of the n-side contact region to the area of the semiconductor stack structure of the nitride semiconductor light-emitting element according to Embodiment 2 and the ratio of the light emission output to the nitride semiconductor light-emitting element according to the comparison example.

FIG. 32 is a plan view schematically illustrating the configuration of the n-side contact region of the nitride semiconductor light-emitting element according to Variation 1 of Embodiment 2.

FIG. 33 is a plan view schematically illustrating the configuration of the n-side contact region included in the nitride semiconductor light-emitting element according to Variation 2 of Embodiment 2.

FIG. 34 is a plan view schematically illustrating the configuration of the n-side contact region of the nitride semiconductor light-emitting element according to Variation 3 of Embodiment 2.

FIG. 35 is a graph indicating the relationship between ratio d/a and the normalized forward voltage in the nitride semiconductor light-emitting element according to Variation 3 of Embodiment 2. Ratio d/a is the ratio of distance d by which the regions are spaced apart from each other to length a of the shorter side of the semiconductor stack structure.

FIG. 36 is a graph indicating the relationship between proportion b of the area of the n-side contact region to the area of the semiconductor stack structure of the nitride semiconductor light-emitting element and the minimum and maximum values of ratio d/a that is the ratio of distance d by which the regions are spaced apart from each other to length a of the shorter side of the semiconductor stack structure according to Variation 3 of Embodiment 2.

FIG. 37 is a graph indicating the relationship between proportion b of the area of the n-side contact region to the area of the semiconductor stack structure of the nitride semiconductor light-emitting element and the maximum value of ratio d/a which allows the normalized forward voltage to be less than 1 according to Variation 3 of Embodiment 2.

FIG. 38 is a plan view schematically illustrating the configuration of the n-side contact region of the nitride semiconductor light-emitting element according to Variation 4 of Embodiment 2.

FIG. 39 is a graph indicating the relationship between ratio d/a and the normalized forward voltage in the nitride semiconductor light-emitting element according to Variation 4 of Embodiment 2. Ratio d/a is the ratio of distance d by which the regions are spaced apart from each other to length a of the shorter side of the semiconductor stack structure.

FIG. 40 is a graph indicating the relationship between proportion b of the area of the n-side contact region to the area of the semiconductor stack structure of the nitride semiconductor light-emitting element and the minimum and maximum values of ratio d/a that is the ratio of distance d by which the regions are spaced apart from each other to length a of the shorter side of the semiconductor stack structure according to Variation 4 of Embodiment 2.

FIG. 41 is a graph indicating the relationship between proportion b of the area of the n-side contact region to the area of the semiconductor stack structure of the nitride semiconductor light-emitting element and the maximum value of ratio d/a which allows the normalized forward voltage to be less than 1 according to Variation 4 of Embodiment 2.

FIG. 42 is a plan view schematically illustrating the configuration of the n-side contact region of the nitride semiconductor light-emitting element according to Variation 5 of Embodiment 2.

FIG. 43 is a plan view schematically illustrating the configuration of a plurality of n-side contact regions of the nitride semiconductor light-emitting element according to Embodiment 3.

FIG. 44 is a plan view schematically illustrating the configuration of the unit including the n-side contact region locate at the center among the plurality of n-side contact regions according to Embodiment 3.

FIG. 45 is a diagram schematically illustrating the overall configuration of a nitride semiconductor light-emitting element according to Embodiment 4.

FIG. 46 is a cross sectional view schematically illustrating one example of the mounting aspect of the nitride semiconductor light-emitting element according to Embodiment 4.

FIG. 47 is a cross sectional view schematically illustrating a first process of the manufacturing method of the nitride semiconductor light-emitting element according to Embodiment 4.

FIG. 48 is a cross sectional view schematically illustrating a second process of the manufacturing method of the nitride semiconductor light-emitting element according to Embodiment 4.

FIG. 49 is a cross sectional view schematically illustrating a third process of the manufacturing method of the nitride semiconductor light-emitting element according to Embodiment 4.

FIG. 50 is a cross sectional view schematically illustrating a fourth process of the manufacturing method of the nitride semiconductor light-emitting element according to Embodiment 4.

### DESCRIPTION OF EMBODIMENTS

Hereinafter, embodiments of the present disclosure will be described with reference to the drawings. It should be noted that each of the embodiments described below shows a specific example of the present disclosure. Therefore, numerical values, shapes, materials, structural components, the arrangement and connection of the structural components, etc. indicated in the following embodiments are mere examples, and are not intended to limit the scope of the present disclosure.

In addition, each of the diagrams is a schematic diagram and thus is not necessarily strictly illustrated. Therefore, the scale sizes and the like are not necessarily exactly represented in each of the diagrams. In each of the diagrams, substantially the same structural components are assigned with the same reference signs, and redundant descriptions will be omitted or simplified.

Moreover, in the present specification, the terms “above” and “below” do not refer to the vertically upward direction and vertically downward direction in terms of absolute spatial recognition, but are used as terms defined by relative positional relationships based on the layering order in a layered configuration. Furthermore, the terms “above” and “below” are applied not only when two structural components are disposed with a gap therebetween or when a separate structural component is interposed between two structural components, but also when two structural components are disposed in close contact with each other or when two structural components come into contact with each other.

### Embodiment 1

A nitride semiconductor light-emitting element according to Embodiment 1 will be described.

### 1-1. Overall Configuration

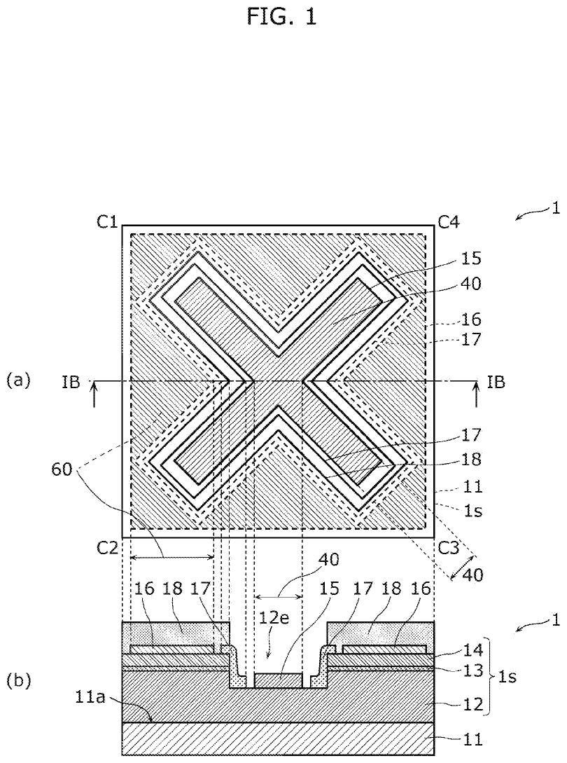

First, an overall configuration of a nitride semiconductor light-emitting element according to the present embodiment will be described with reference to the drawings. FIG. 1 is a diagram schematically illustrating the overall configuration of nitride semiconductor light-emitting element 1 according to the present embodiment. FIG. 1 illustrates plan view (a) and cross-sectional view (b) of nitride semiconductor light-emitting element 1. Cross-sectional view (b) of FIG. 1 illustrates a cross-section surface taken along line IB-IB indicated in plan view (a).

As illustrated in FIG. 1, nitride semiconductor light-emitting element 1 includes: substrate 11; semiconductor stack structure 1s; n-side contact electrode 15; p-side contact electrode 16; insulating layer 17; and cover electrode 18. According to the present embodiment, nitride semiconductor light-emitting element 1 is a flip-chip light emitting diode (LED) in which semiconductor stack structure 1s, n-side contact electrode 15, and p-side contact electrode 16 are disposed on a main surface 11a side of substrate 11. Main surface 11a is one of main surfaces of substrate 11. Nitride semiconductor light-emitting element 1, for example, emits light having a wavelength in the 450 nm band.

Substrate 11 is a plate-like component which serves as a base of nitride semiconductor light-emitting element 1. As board 11, for example, a light-transmissive substrate such as a sapphire substrate, a GaN substrate, etc. can be used.

Semiconductor stack structure 1s is a stack structure including a plurality of semiconductor layers disposed above main surface 11a of substrate 11. Semiconductor stack structure 1s includes n-type semiconductor layer 12, active layer 13, and p-type semiconductor layer 14 which are stacked in sequence above main surface 11a of substrate 11. Semiconductor stack structure 1s includes exposure portion 12e in which n-type semiconductor layer 12 is exposed, as a result of removing a portion of p-type semiconductor layer 14 and active layer 13 disposed above n-type semiconductor layer 12.

As illustrated in plan view (a) of FIG. 1, semiconductor stack structure 1s has a rectangular shape in a plan view of main surface 11a of substrate 11. In other words, semiconductor stack structure 1s has a rectangular outer edge. In the plan view of main surface 11a of substrate 11, semiconductor stack structure 1s includes first corner portion C1, second corner portion C2, third corner portion C3, and fourth corner portion C4.

N-type semiconductor layer 12 is a layer including an n-type semiconductor that is disposed above substrate 11. N-type semiconductor layer 12 includes an n-type GaN-based semiconductor layer. N-type semiconductor layer 12 may include a plurality of layers such as n-type clad layers. As n-type semiconductor layer 12, for example, an n-type AlGaN layer may be used. As an n-type dopant that is included in n-type semiconductor layer 12, Si, Ge, etc. can be used.

Active layer 13 is a light-emitting layer disposed above n-type semiconductor layer 12. According to the present embodiment, an InGaN-based semiconductor layer is used as active layer 13. Active layer 13 may have a single-layer structure or have a quantum well structure.

P-type semiconductor layer 14 is a layer including a p-type semiconductor dispose above active layer 13. P-type semiconductor layer 14 includes a p-type GaN-based semiconductor layer. P-type semiconductor layer 14 may include a plurality of layers such as p-type clad layers. As p-type semiconductor layer 14, for example, a p-type AlGaN layer may be used. As a p-type dopant that is included in p-type semiconductor layer 14, Mg, etc. can be used.

N-side contact electrode 15 is a conductive layer that is disposed above n-type semiconductor layer 12 and is in contact with n-type semiconductor layer 12 in n-side contact region 40. N-side contact electrode 15 is disposed in exposure portion 12e in which n-type semiconductor layer 12 is exposed. The configuration of n-side contact electrode 15 is not particularly limited as long as n-side contact electrode 15 is a conductive layer that makes ohmic contact with n-type semiconductor layer 12. According to the present embodiment, n-side contact electrode 15 is a stack structure including an Al layer having a thickness of 0.3 μm, a Ti layer having a thickness of 0.3 μm, and an Au layer having a thickness of 1.0 μm, which are stacked in sequence from the n-type semiconductor layer 12 side.

N-side contact region 40 has an X shape in the plan view of main surface 11a of substrate 11, as illustrated in plan view (a) of FIG. 1. The detailed configuration of n-side contact region 40 will be described below.

P-side contact electrode 16 is a conductive layer that is disposed above p-type semiconductor layer 14, and in contact with p-type semiconductor layer 14 in p-side contact region 60. The configuration of p-side contact electrode 16 is not particularly limited as long as p-side contact electrode 16 is a conductive layer that makes ohmic contact with p-type semiconductor layer 14. According to the present embodiment, p-side contact electrode 16 is a stack structure including an Ag layer having a thickness of 0.2 μm, a Ti layer having a thickness of 0.7 μm, and an Au layer having a thickness of 0.3 μm, which are stacked in sequence above p-type semiconductor layer 14. The Ag layer is a reflective metal that makes ohmic contact with p-type semiconductor layer 14, and reflects light generated in active layer 13. The Ti layer and the Au layer are barrier electrodes that cover the Ag layer.

Insulating layer 17 is a layer that comprises an insulating material. Insulating layer 17 covers continuously a portion of exposure portion 12e in which n-type semiconductor layer 12 is exposed and a portion above p-type semiconductor layer 14. Insulating layer 17 may include an opening portion defined above exposure portion 12e. The configuration of insulating layer 17 is not particularly limited as long as insulating layer 17 is a layer that comprises an insulating material. According to the present embodiment, insulating layer 17 is a layer that comprises SiO₂ and has a thickness of 1.0 μm.

Cover electrode 18 is an electrode that covers p-side contact electrode 16. The configuration of cover electrode 18 is not particularly limited as long as cover electrode 18 is a conductive film. According to the present embodiment, cover electrode 18 is a stack structure including an Al layer having a thickness of 0.3 μm, a Ti layer having a thickness of 0.3 μm, and an Au layer having a thickness of 1.0 μm, which are stacked in sequence so as to cover p-side contact electrode 16. It should be noted that cover electrode 18 may have the configuration equivalent to the configuration of n-side contact electrode 15.

### 1-2. Mounting Aspect

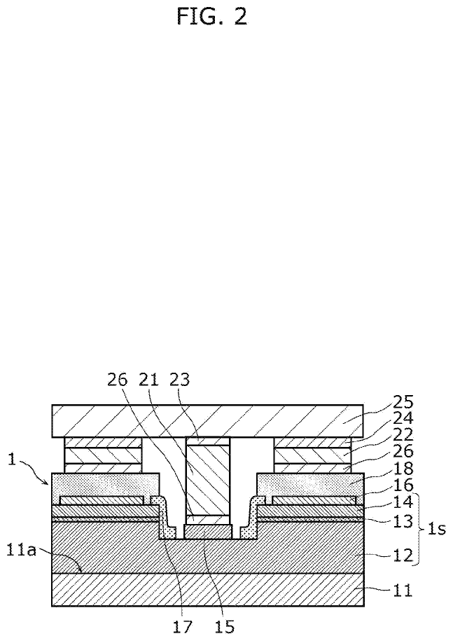

Next, a mounting aspect of nitride semiconductor light-emitting element 1 according to the present embodiment will be described. FIG. 2 is a cross sectional view schematically illustrating one example of the mounting aspect of nitride semiconductor light-emitting element 1 according to the present embodiment.

As illustrated in FIG. 2, in one example of the mounting aspect of nitride semiconductor light-emitting element 1 according to the present embodiment, nitride semiconductor light-emitting element 1 is flip-chip mounted on mounting substrate 25. In other words, nitride semiconductor light-emitting element 1 is mounted on mounting substrate 25 in an orientation such that semiconductor stack structure 1s faces mounting substrate 25.

Mounting substrate 25 is a substrate on which nitride semiconductor light-emitting element 1 is mounted, and n-side wiring electrode 23 and p-side wiring electrode 24 are disposed on a main surface of mounting substrate 25 on which nitride semiconductor light-emitting element 1 is mounted. The configuration of mounting substrate 25 is not particularly limited. According to the present embodiment, mounting substrate 25 is a ceramic substrate comprising an AlN sintered body.

N-side wiring electrode 23 and p-side wiring electrode 24 are conductive layers disposed on mounting substrate 25. N-side wiring electrode 23 and p-side wiring electrode 24 are insulated from each other. The configuration of each of n-side wiring electrode 23 and p-side wiring electrode 24 is not particularly limited as long as n-side wiring electrode 23 and p-side wiring electrode 24 are conductive layers. According to the present embodiment, each of n-side wiring electrode 23 and p-side wiring electrode 24 comprises Au.

Cover electrode 18 of nitride semiconductor light-emitting element 1 is electrically connected to p-side wiring electrode 24 of mounting substrate 25, and n-side contact electrode 15 is electrically connected to n-side wiring electrode 23 of mounting substrate 25.

Seed metal 26 and p-side connecting member 22 are disposed in sequence from the cover electrode 18 side between cover electrode 18 and p-side wiring electrode 24. Seed metal 26 and n-side connecting member 21 are disposed in sequence from the n-side contact electrode 15 side between n-side contact electrode 15 and n-side wiring electrode 23.

Seed metal 26 is a metal layer disposed above cover electrode 18 and n-side contact electrode 15, and serves as a base for p-side connecting member 22 and n-side connecting member 21. The configuration of seed metal 26 is not particularly limited as long as seed metal 26 is a metal layer that serves as a base for p-side connecting member 22 and n-side connecting member 21. According to the present embodiment, seed metal 26 is a stack structure in which a Ti layer having a thickness of 0.1 μm and an Au layer having a thickness of 0.3 μm are stacked in sequence from the semiconductor stack structure 1s side.

P-side connecting member 22 is a conductive member that connects seed metal 26 and p-side wiring electrode 24. N-side connecting member 21 is a conductive member that connects seed metal 26 and n-side wiring electrode 23. P-side connecting member 22 and n-side connecting member 21 are not particularly limited as long as p-side connecting member 22 and n-side connecting member 21 are conductive members. P-side connecting member 22 and n-side connecting member 21 may be conductive members with high thermal conductivity. With this configuration, it is possible to facilitate heat discharge from nitride semiconductor light-emitting element 1 to mounting substrate 25. P-side connecting member 22 and n-side connecting member 21 are, for example, bumps that comprise Au. It should be noted that p-side connecting member 22 and n-side connecting member 21 may be, for example, any one of Au, Ag, Al, or Cu, or an alloy of a combination of them.

Nitride semiconductor light-emitting element 1 is mounted on mounting substrate 25 as described above. With the configuration as described above, an electric current is supplied to nitride semiconductor light-emitting element 1 from the mounting substrate 25 side, and light generated in active layer 13 is emitted from the substrate 11 side of nitride semiconductor light-emitting element 1.

### 1-3. Manufacturing Method

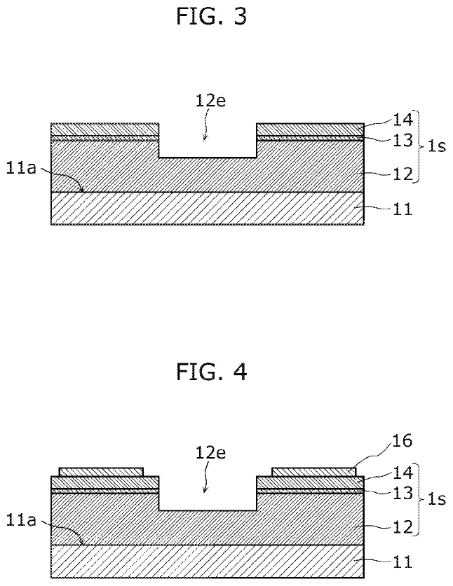

Next, the manufacturing method of nitride semiconductor light-emitting element 1 according to the present embodiment will be described with reference to FIG. 3 to FIG. 6. FIG. 3 to FIG. 6 are cross sectional views schematically illustrating the processes of a manufacturing method of nitride semiconductor light-emitting element 1 according to the present embodiment.

First, as illustrated in FIG. 3, substrate 11 is prepared, and semiconductor stack structure 1s is stacked on main surface 11a that is one of the main surfaces of substrate 11. According to the present embodiment, n-type semiconductor layer 12 that includes an n-type GaN-based semiconductor layer, active layer 13 that includes an InGaN-based semiconductor layer, and p-type semiconductor layer 14 that includes a p-type GaN-based semiconductor layer are stacked in stated order above main surface 11a that is one of the main surfaces of substrate 11 comprising a sapphire substrate or a GaN substrate, using an epitaxial growth technique by the metal organic chemical vapor deposition (MOCVD) method. Then, portions of p-type semiconductor layer 14, active layer 13, and n-type semiconductor layer 12 are removed to form exposure portion 12e which is a recess in which n-type semiconductor layer 12 is exposed. According to the present embodiment, dry etching is used to remove the portions of p-type semiconductor layer 14, active layer 13, and n-type semiconductor layer 12.

Then, as illustrated in FIG. 4, a p-side contact electrode 16 having a predetermined shape is formed above p-type semiconductor layer 14. According to the present embodiment, photolithography technique is used to form a resist pattern provided with an opening in the region in which p-type semiconductor layer 14 is disposed. Then, an Ag film having a thickness of 0.2 μm is deposited by the sputtering method, and the resist and Ag on the resist are removed by the lift-off method to form an Ag layer as a reflective metal patterned in a predetermined shape. Then, a stacked film including a Ti film having a thickness of 0.7 μm and an Au film having a thickness of 0.3 μm, which cover the Ag layer, is deposited by the sputtering method. Then, a resist pattern that covers p-type semiconductor layer 14 is formed by the photolithography technique, an excess portion of the stacked film formed in a region other than the region above p-type semiconductor layer 14 is removed by wet etching, and the resist is removed by organic cleaning. In this manner, p-side contact electrode 16 including the Ag layer, the Ti layer, and the Au layer is formed. Here, the outer edge of p-side contact electrode 16 and the outer edge of semiconductor stack structure 1s are spaced apart from each other with a gap of 8 μm, for example. In addition, the edge of p-side contact electrode 16 on the n-side contact electrode side and the edge of exposure portion 12e are spaced apart with a gap of 8 μm, for example.

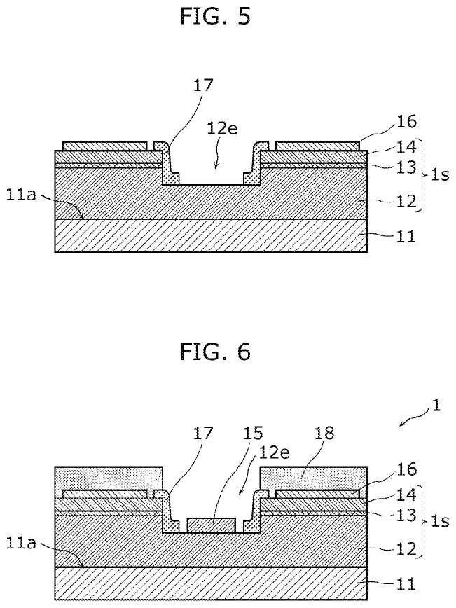

Then, as illustrated in FIG. 5, insulating layer 17 is formed. According to the present embodiment, an oxide film that comprises SiO₂ and has a thickness of 1.0 μm is deposited on the entire surface above semiconductor stack structure 1s and p-side contact electrode 16. Then, a resist pattern is formed in which portions of n-type semiconductor layer 12 and p-type semiconductor layer 14 are opened, and the resist is removed after the oxide film in the region in which the resist pattern is not formed is removed by wet etching. In this manner, insulating layer 17 in which the portion above exposure portion 12e and the portion above p-side contact electrode 16 of the oxide film are removed is formed.

Then, as illustrated in FIG. 6, n-side contact electrode 15 having a predetermined shape and cover electrode 18 are simultaneously formed in a region in which insulating layer 17 is not disposed in exposure portion 12e and a region above p-type semiconductor layer 14, respectively. According to the present embodiment, a resist pattern is formed to cover the region between p-type semiconductor layer 14 and the region in which n-side contact electrode 15 is formed, and a stacked film including an Al film having a thickness of 0.3 μm, a Ti film having a thickness of 0.3 μm, and an Au film having a thickness of 1.0 μm is formed using an electron beam (EB) deposition method. Then, n-side contact electrode 15 including an Al layer, a Ti layer, and an Au layer and cover electrode 18 are formed by removing the resist and the stacked film above the resist by the lift-off method.

As described above, nitride semiconductor light-emitting element 1 according to the present embodiment can be manufactured.

### 1-4. Detailed Configuration of N-Side Contact Region 40

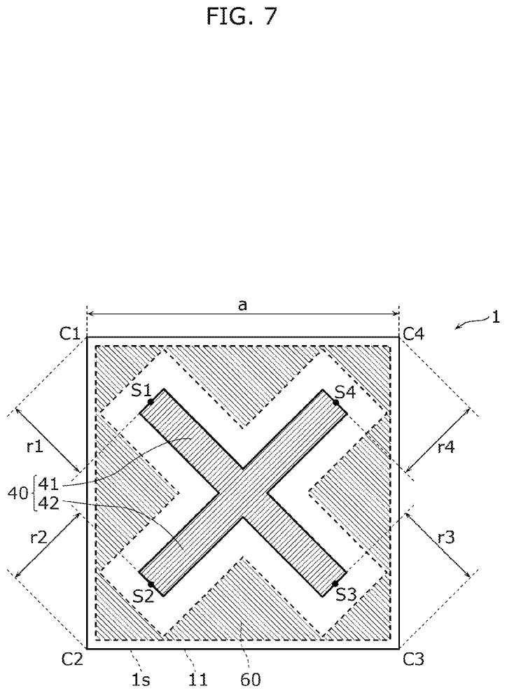

Next, the detailed configurations of n-side contact region 40 and p-side contact region 60 of nitride semiconductor light-emitting element 1 according to the present embodiment will be described with reference to FIG. 7. FIG. 7 is a plan view illustrating the configurations of n-side contact region 40 and p-side contact region 60 according to the present embodiment. It should be noted that the following describes the configurations of n-side contact region 40, etc. in a plan view of main surface 11a of substrate 11.

As illustrated in FIG. 7, in nitride semiconductor light-emitting element 1 according to the present embodiment, in a plan view of main surface 11a of substrate 11, semiconductor stack structure 1s has a rectangular shape, and includes first corner portion C1, second corner portion C2, third corner portion C3, and fourth corner portion C4 respectively corresponding to the four vertexes of the rectangular shape. Second corner portion C2 is a corner portion adjacent to first corner portion C1. In other words, second corner portion C2 is a corner portion disposed on the same side of a rectangular outer edge of semiconductor stack structure 1s as first corner portion C1. Third corner portion C3 is a corner portion disposed diagonally to first corner portion C1. Fourth corner portion C4 is a corner portion disposed diagonally to second corner portion C2.

N-side contact region 40 includes first region 41. According to the present embodiment, n-side contact region 40 further includes second region 42. First region 41 is a linear region extending in one direction from first starting point S1 which is spaced apart from first corner portion C1. Second region 42 is a linear region extending in one direction from second starting point S2 which is spaced apart from second corner portion C2. Here, a linear region means a stripe-shaped region having a certain width extending along a straight line. The ratio of the length direction to the width of the linear region is greater than or equal to 2, for example. The edge of the linear region may have, for example, a rectangular shape or a semicircular shape.

P-side contact region 60 is disposed between first starting point S1 and first corner portion C1, and between second starting point S2 and second corner portion C2. It should be noted that no n-side contact region 40 is disposed between first starting point S1 and first corner portion C1, and between second starting point S2 and second corner portion C2.

Distance r1 between first corner portion C1 and first starting point S1 is less than or equal to 0.26 times length a of a shorter side of semiconductor stack structure 1s in a plan view of main surface 11a of substrate 11. Here, the shorter side of semiconductor stack structure 1s means the shorter two of the four sides of the rectangular outer edge of semiconductor stack structure 1s in a plan view. The shape of semiconductor stack structure 1s in a plan view is square according to the present embodiment. In addition, according to the present embodiment, distance r2 between second corner portion C2 and second starting point S2 is less than or equal to 0.26 times length a of the shorter side of semiconductor stack structure 1s in a plan view of main surface 11a of substrate 11.

According to the present embodiment, first region 41 linearly extends from first starting point S1 to third starting point S3. Third starting point S3 is a starting point that is spaced apart from third corner portion C3. Second region 42 linearly extends from second starting point S2 to fourth starting point S4. Fourth starting point S4 is a starting point that is spaced apart from fourth corner portion C4. First region 41 and second region 42 intersect. In other words, n-side contact region 40 has an X shape.

According to the present embodiment, distance r3 between third corner portion C3 and third starting point S3 and distance r4 between fourth corner portion C4 and fourth starting point S4 are each less than or equal to 0.26 times length a of the shorter side of semiconductor stack structure 1s in a plan view of main surface 11a of substrate 11. It should be noted that distances r1, r2, r3, and r4 are not particularly limited as long as distances r1, r2, r3, and r4 are each less than or equal to 0.26 times length a of the shorter side. According to the present embodiment, distances r1, r2, r3, and r4 are equal to one another.

P-side contact region 60 is disposed between third starting point S3 and third corner portion C3 and between fourth starting point S4 and fourth corner portion C4. It should be noted that no n-side contact region 40 is disposed between third starting point S3 and third corner portion C3 and between fourth starting point S4 and fourth corner portion C4.

### 1-5. Function and Advantageous Effect

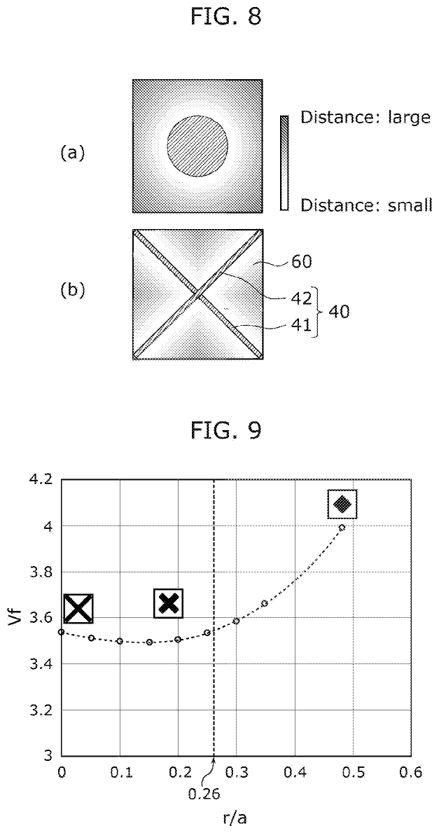

Next, a function and an advantageous effect of nitride semiconductor light-emitting element 1 according to the present embodiment will be described with reference to FIG. 8. FIG. 8 is a diagram illustrating the relationship between each position of the p-side contact region and the distance from the position to the n-side contact region, in each of the nitride semiconductor light-emitting element according to a comparison example and nitride semiconductor light-emitting element 1 according to the present embodiment. Graphs (a) and (b) illustrated in FIG. 8 each indicate the relationship between each position of the p-side contact region and the distance from the position to the n-side contact region in a plan view of the main surface of the substrate of the nitride semiconductor light-emitting element according to a comparison example and nitride semiconductor light-emitting element 1 according to the present embodiment. The shaded hatched region in each of the graphs indicates the n-side contact region, and almost the entire area other than the n-side contact region corresponds to the p-side contact region. In each of the graphs in FIG. 8, the region with the larger distance is represented in darker gray.

The nitride semiconductor light-emitting element according to the comparison example includes a semiconductor stack structure having a rectangular shape in a plan view of the main surface of the substrate as with nitride semiconductor light-emitting element 1 according to the present embodiment. In nitride semiconductor light-emitting element according to the comparison example, the outer edge of the n-side contact region is circular, as indicated in graph (a) of FIG. 8. In the nitride semiconductor light-emitting element according to the comparison example including such an n-side contact region, the distance between the position in proximity to the corner portion of the semiconductor stack structure in the p-side contact region and the n-side contact region becomes large. Since it is necessary for the current injected into the light-emitting layer at this position to travel this distance in the n-type layer in the planar direction, the electrical resistance of the nitride semiconductor light-emitting element according to the comparison becomes large. As a result, the forward voltage becomes high in the nitride semiconductor light-emitting element according to the comparison example.

On the other hand, in nitride semiconductor light-emitting element 1 according to the present embodiment, as indicated in graph (b) of FIG. 8, n-side contact region 40 includes first region 41 that linearly extends from the position in proximity to the corner portion of semiconductor stack structure 1s. Accordingly, it is possible to reduce the distance from the corner portion of semiconductor stack structure 1s to n-side contact region 40, in p-side contact region 60. As a result, it is possible to reduce the electrical resistance between the corner portion of semiconductor stack structure 1s and n-side contact region 40, in p-side contact region 60. This enables reduction in the forward voltage in nitride semiconductor light-emitting element 1 according to the present embodiment. In addition, according to the present embodiment, as described above, since the distance from each of first corner portion C1, second corner portion C2, third corner portion C3, and fourth corner portion C4 to n-side contact region 40 is less than or equal to 0.26 times length a of the shorter side of semiconductor stack structure 1s, it is possible to reduce the distance from the position in proximity to each of the four corner portions of semiconductor stack structure 1s to n-side contact region 40, in p-side contact region 60. As a result, with nitride semiconductor light-emitting element 1 according to the present embodiment, it is possible to further reduce the forward voltage.

The forward voltage in nitride semiconductor light-emitting element 1 according to the present embodiment will be described with reference to FIG. 9. FIG. 9 is a graph indicating the relationship between forward voltage Vf and ratio r/a. Ratio r/a is the ratio of distance r from each of the corner portions to n-side contact region 40 to length a of the shorter side of nitride semiconductor light-emitting element 1 according to the present embodiment. The horizontal axis of the graph in FIG. 9 indicates ratio r/a and the vertical axis indicates forward voltage Vf.

In the graph illustrated in FIG. 9, the experimental results of forward voltage Vf when (i) distance r1 between first corner portion C1 and first starting point S1, distance r2 between second corner portion C2 and second starting point S2, distance r3 between third corner portion C3 and third starting point S3, and distance r4 between fourth corner portion C4 and fourth starting point S4 are equal to one another, and (ii) proportion b is 0.2 are indicated. Proportion b is a proportion of the area of n-side contact region 40 to the area of semiconductor stack structure 1s in a plane view of main surface 11a of substrate 11. In this experiment, ratio r/a, etc. are varied under the condition that the widths of first region 41 and second region 42 are equal to each other. Distances r from the corner portions to n-side contact region 40 respectively correspond to distances r1, r2, r3 and r4. Forward voltage Vf represents the forward voltage when the supply current is 1 A for nitride semiconductor light-emitting element 1 with the shorter side and the longer side being the same 1 mm.

As indicated schematically in the graph of FIG. 9, as ratio r/a on the horizontal axis becomes smaller, each region of n-side contact region 40 (i.e., first region 41 and second region 42) becomes narrower and longer, and as ratio r/a becomes greater, each region of n-side contact region 40 becomes wider and shorter. When ratio r/a is approximately 0.48, the shape of n-side contact region 40 is not an X but a rectangle, and thus forward voltage Vf of the case where ratio r/a is approximately less than or equal to 0.48 is indicated in FIG. 9.

As illustrated in FIG. 9, forward voltage Vf is a minimal value of approximately 3.5 V when ratio r/a is approximately 0.14, and is close to a minimal value of less than 3.6 V when ratio r/a is greater than 0 and less than or equal to 0.26. On the other hand, in the nitride semiconductor light-emitting element of the above-described comparative example (graph (a) in FIG. 8), forward voltage Vf is greater than or equal to 3.8 V.

As described above, in nitride semiconductor light-emitting element 1 according to the present embodiment, ratio r/a is greater than 0 and less than or equal to 0.26, and thus it is possible to reduce forward voltage Vf compared to the nitride semiconductor light-emitting element according to the comparison example. With nitride semiconductor light-emitting element 1 according to the present embodiment, it is possible to reduce forward voltage Vf, and thus the loss component that is included in forward voltage Vf and does not contribute to light emission can be reduced. As a result, with nitride semiconductor light-emitting element 1 according to the present embodiment, it is possible to increase the utilization efficiency of power and reduce heat generation due to the loss component. In addition, since heat generation can be reduced, it is possible to enhance the performance and reliability of nitride semiconductor light-emitting element 1.

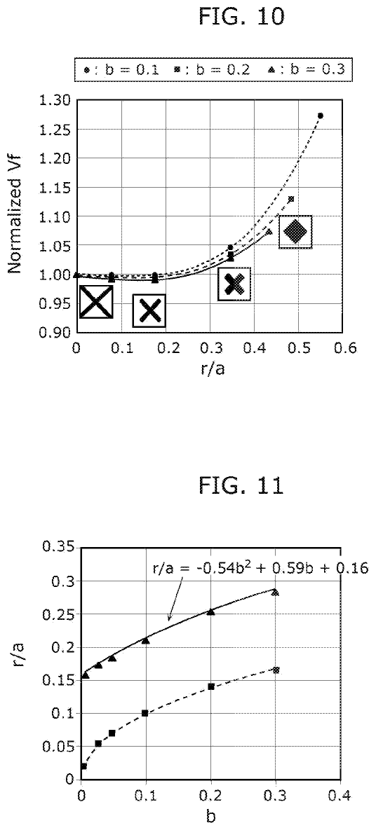

Next, the relationship between forward voltage Vf and proportion b of the area of n-side contact region 40 to the area of semiconductor stack structure 1s of nitride semiconductor light-emitting element 1 according to the present embodiment will be described with reference to FIG. 10. FIG. 10 is a graph indicating the relationship between normalized forward voltage Vf and ratio r/a. Ratio r/a is the ratio of distance r from each of the corner portions to n-side contact region 40 to length a of the shorter side of nitride semiconductor light-emitting element 1 according to the present embodiment. The horizontal axis of the graph in FIG. 10 indicates ratio r/a and the vertical axis indicates normalized forward voltage Vf. In FIG. 10, the experimental results when proportion b is 0.1, 0.2, and 0.3 are indicated by a circle, a square, and a triangle, respectively. Normalized forward voltage Vf represents the ratio of forward voltage Vf to forward voltage Vf when the ratio r/a is 0.

As illustrated in FIG. 10, normalized forward voltage Vf has a minimal value in the range in which ratio r/a is greater than 0 and less than or equal to 0.26 for each of the cases where proportion b of the area of n-side contact region 40 is 0.1, 0.2, and 0.3.

The maximum value of ratio r/a indicated in FIG. 10 is ratio r/a when n-side contact region 40 has a rectangular shape instead of an X shape. Here, the range of ratio r/a which allows normalized forward voltage Vf to be smaller than in the case where ratio r/a is at the maximum will be considered. As illustrated in FIG. 10, in the range where ratio r/a is greater than 0 and less than or equal to the maximum value, normalized forward voltage Vf is at the maximum when ratio r/a is at the maximum for any proportion b of the area of n-side contact region 40. Accordingly, when ratio r/a is less than these maximum values, normalized forward voltage Vf can be smaller than in the case where ratio r/a is at the maximum. As illustrated in FIG. 10, when proportion b is 0.1, 0.2, and 0.3, the maximum values of ratio r/a are approximately 0.55, 0.48, and 0.43, respectively, and the maximum value of ratio r/a is greater than 0.26 in any of the cases. Accordingly, in the case where proportion b is greater than or equal to 0.1 and less than or equal to 0.3, normalized forward voltage Vf can be smaller than in the case where ratio r/a is at the maximum when ratio r/a is less than or equal to 0.26. It should be noted that, although the experimental results for the case where proportion b is less than 0.1 are not shown, the maximum value of ratio r/a is greater when proportion b is less than 0.1 than in the case where proportion b is 0.1. Accordingly, in the case where proportion b is less than 0.1, normalized forward voltage Vf can also be smaller than in the case where ratio r/a is at the maximum when ratio r/a is less than or equal to 0.26. In view of the above, in the case where proportion b is less than or equal to 0.3 and ratio r/a is less than or equal to 0.26, normalized forward voltage Vf can be smaller than in the case where ratio r/a is at the maximum.

Next, the range of ratio r/a which allows normalized forward voltage Vf as indicated in FIG. 10 to be less than 1 will be considered. As illustrated in FIG. 10, normalized forward voltage Vf is 1 when ratio r/a is 0, and normalized forward voltage Vf is less than 1 in the range in which ratio r/a is greater than 0 and less than a predetermined value. Here, the maximum value of the range of ratio r/a in which normalized forward voltage Vf is less than 1 will be explained with reference to FIG. 11.

FIG. 11 is a graph indicating the relationship between proportion b of the area of n-side contact region 40 to the area of semiconductor stack structure 1s of nitride semiconductor light-emitting element 1 according to the present embodiment and the maximum value of ratio r/a which allows normalized forward voltage Vf to be less than 1. The horizontal axis of the graph in FIG. 11 indicates proportion b, and the vertical axis indicates ratio r/a. In FIG. 11, the maximum value of ratio r/a which allows normalized forward voltage Vf to be less than 1 is indicated by a triangle. It should be noted that ratio r/a in the case where normalized forward voltage Vf has a minimal value is also indicated by a square in FIG. 11.

As illustrated in FIG. 11, when the relationship between proportion b and the maximum value of ratio r/a which allows normalized forward voltage Vf to be less than 1 is approximated by a quadratic function of proportion b, the relationship can be represented by the following expression (1) when b is less than or equal to 0.3.

r/a=−0.54b²+0.59b+0.16 (1)

Accordingly, distances r1 to r4, length a of the shorter side of semiconductor stack structure 1s, and proportion b may satisfy the following expressions (2) to (4).

b≤0.3 (2)

r1=r2=r3=r4 (3)

r1/a<−0.54b²+0.59b+0.16 (4)

This allows forward voltage Vf of nitride semiconductor light-emitting element 1 to be less than forward voltage Vf of the case where ratio r/a is 0.

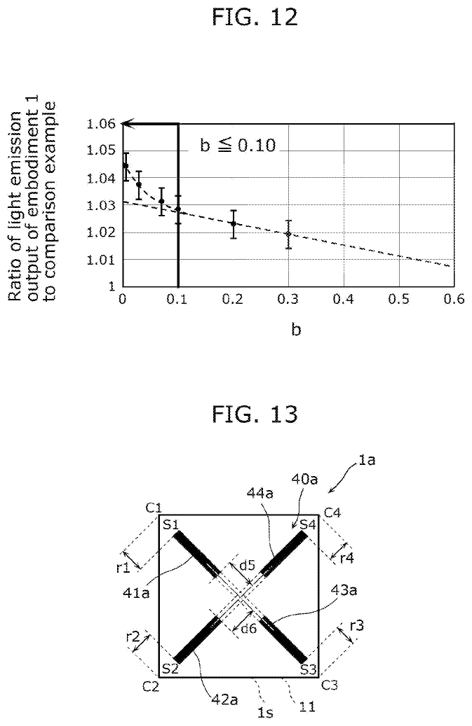

Next, the relationship between a light emission output and proportion b of the area of n-side contact region 40 to the area of semiconductor stack structure 1s of nitride semiconductor light-emitting element 1 will be described with reference to FIG. 12. FIG. 12 is a graph indicating the relationship between (i) proportion b of the area of n-side contact region 40 to the area of semiconductor stack structure 1s of nitride semiconductor light-emitting element 1 according to the present embodiment and (ii) the ratio of the light emission output of nitride semiconductor light-emitting element 1 according to the present embodiment in the case where ratio r/a is the ratio when normalized forward voltage Vf has a minimal value to the light emission output of the nitride semiconductor light-emitting element according to the comparison example. FIG. 12 is a graph indicating the experimental results. The horizontal axis of the graph indicates proportion b and the vertical axis indicates the ratio of the light emission output.

As illustrated in FIG. 12, the ratio of the light emission output is greater than 1 in the entire range in which proportion b is less than or equal to 0.3. In other words, nitride semiconductor light-emitting element 1 according to the present embodiment has a greater light emission output than the nitride semiconductor light-emitting element according to the comparison example. In addition, as proportion b decreases from 0.3 to 0.1, the ratio of the light emission output increases substantially linearly, and as proportion b decreases further from 0.1, the ratio of the light emission output increases more steeply than linearly. Accordingly, in nitride semiconductor light-emitting element 1 according to the present embodiment, proportion b may satisfy b≤0.10. In this manner, it is possible to further increase the light emission output of nitride semiconductor light-emitting element 1 compared to the light emission output of the nitride semiconductor light-emitting element of the comparison example.

### 1-6. Variation 1

Next, a nitride semiconductor light-emitting element according to Variation 1 of Embodiment 1 will be described. The nitride semiconductor light-emitting element according to the present variation matches nitride semiconductor light-emitting element 1 according to Embodiment 1 in points other than that the n-side contact region includes four regions which are not connected one another. The following describes the nitride semiconductor light-emitting element according to the present variation focusing on the differences from nitride semiconductor light-emitting element 1 according to Embodiment 1.

First, the configuration of an n-side contact region of the nitride semiconductor light-emitting element according to the present variation will be described with reference to FIG. 13. FIG. 13 is a plan view schematically illustrating the configuration of n-side contact region 40a of nitride semiconductor light-emitting element 1a according to the present variation. FIG. 13 illustrates n-side contact region 40a in a plan view of main surface 11a of substrate 11.

As illustrated in FIG. 13, n-side contact region 40a according to the present variation includes first region 41a, second region 42a, third region 43a, and fourth region 44a. First region 41a is a linear region extending in one direction from first starting point S1 which is spaced apart from first corner portion C1. Second region 42a is a linear region extending in one direction from second starting point S2 which is spaced apart from second corner portion C2. Third region 43a is a linear region extending in one direction from third starting point S3 which is spaced apart from third corner portion C3. Fourth region 44a is a linear region extending in one direction from fourth starting point S4 which is spaced apart from fourth corner portion C4.

In the present variation, distance r1 between first corner portion C1 and first starting point Si, distance r2 between second corner portion C2 and second starting point S2, distance r3 between third corner portion C3 and third starting point S3, and distance r4 between fourth corner portion C4 and fourth starting point S4 are each less than or equal to 0.26 times length a of the shorter side of semiconductor stack structure 1s in the plan view of main surface 11a of substrate 11. It should be noted that distances r1, r2, r3, and r4 are not particularly limited as long as distances r1, r2, r3, and r4 are each less than or equal to 0.26 times length a of the shorter side. According to the present variation, distances r1, r2, r3, and r4 are equal to one another.

Third region 43a is disposed on the extended line of first region 41a and spaced apart from first region 41a, and fourth region 44a is disposed on the extended line of second region 42a and spaced apart from second region 42a.

First region 41a, second region 42a, third region 43a, and fourth region 44a are disposed to be spaced apart from one another.

First region 41a and third region 43a extend in the same direction, and second region 42a and fourth region 44a extend in the same direction.

The extended line of first region 41a intersects the extended line of second region 42a. The extended line of second region 42a intersects the extended line of third region 43a. The extended line of third region 43a intersects the extended line of fourth region 44a. The extended line of fourth region 44a intersects the extended line of first region 41a.

It should be noted that, since nitride semiconductor light-emitting element 1a according to the present variation includes n-side contact region 40a that is different from that of Embodiment 1, the configurations of n-side contact electrode 15, p-side contact region 60, p-side contact electrode 16, and cover electrode 18 are also different from those of nitride semiconductor light-emitting element 1 according to Embodiment 1. In the plan view of main surface 11a of substrate 11, the shape of n-side contact electrode 15 is similar to the shape of n-side contact region 40a, and p-side contact region 60 and p-side contact electrode 16 are disposed substantially in the entire region of semiconductor stack structure 1s other than the region in which n-side contact region is disposed. Cover electrode 18 is disposed above p-side contact electrode 16. Although the description will be omitted below, in each of the following variations and in each of the following embodiments, the configuration of the other components can also be changed according to the configuration of the n-side contact region.

With nitride semiconductor light-emitting element 1a according to the present variation that has the configuration as described above, the same advantageous effects as those of nitride semiconductor light-emitting element 1 according to Embodiment 1 are yielded as well.

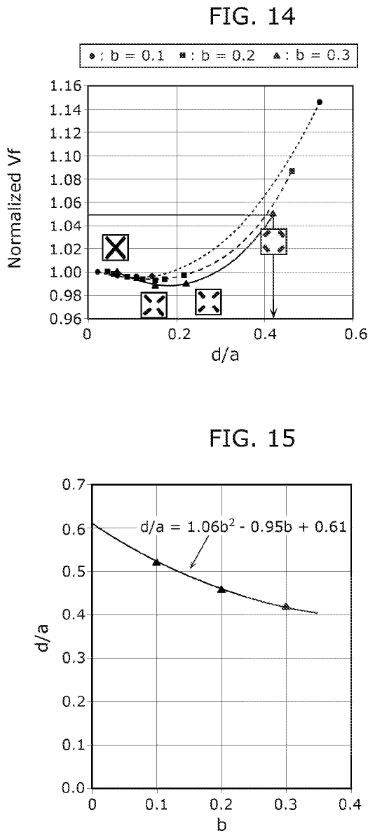

Next, the relationship between (i) d5 which is half the distance between first region 41a and third region 43a indicated in FIG. 13, (ii) d6 which is half the distance between second region 42a and fourth region 44a indicated in FIG. 13, and (iii) forward voltage Vf will be described with reference to FIG. 14. It should be noted that, in the following description, the experimental results in the case where: d5=d6=d; r1=r2=r3=r4; and ratio r1/a is the ratio when normalized forward voltage Vf has a minimal value (indicated by the squares in FIG. 11) will be described. FIG. 14 is a graph indicating the relationship between ratio d/a and normalized forward voltage Vf in nitride semiconductor light-emitting element 1a according to the present variation. It should be noted that the horizontal axis of the graph in FIG. 14 indicates ratio d/a and the vertical axis indicates normalized forward voltage Vf. In FIG. 14, the experimental results when proportion b is 0.1, 0.2, and 0.3 are indicated by a circle, a square, and a triangle, respectively. Normalized forward voltage Vf represents the ratio of forward voltage Vf to forward voltage Vf of the case where ratio d/a is 0. In this experiment, ratio d/a, etc. were varied under the condition that the area of n-side contact region 40a is equal and the width of each region is equal.

As indicated schematically in the graph of FIG. 14, as ratio d/a on the horizontal axis becomes smaller, each region of n-side contact region 40a becomes narrower and longer, and as ratio d/a increases, each region of n-side contact region 40a becomes wider and shorter.

Here, the range of ratio d/a which allows normalized forward voltage Vf to be smaller than in the case where ratio d/a is at the maximum (i.e., a limit value for the width of each region to be placeable in proximity to a corresponding one of the corner portions) will be considered. As indicated in FIG. 14, for any value of proportion b, normalized forward voltage Vf is at the maximum when ratio d/a is at the maximum. For example, as indicated by the arrow in FIG. 14, when proportion b is 0.3, the maximum value of ratio d/a is approximately 0.42, and when ratio d/a is less than 0.42, normalized forward voltage Vf is smaller than in the case where ratio d/a is at the maximum. As described above, when ratio d/a is less than the maximum value, it is possible to reduce the forward voltage compared to the case where ratio d/a is at the maximum.

The range of the value of ratio d/a that allows forward voltage Vf to be less than in the case where ratio d/a indicated in FIG. 14 is at the maximum will be described with reference to FIG. 15. FIG. 15 is a graph indicating the relationship between the maximum value of ratio d/a and proportion b of the area of n-side contact region 40a to the area of semiconductor stack structure is of nitride semiconductor light-emitting element 1a according to the present variation. The horizontal axis of the graph in FIG. 15 indicates proportion b, and the vertical axis indicates ratio d/a. In FIG. 15, the maximum value of ratio d/a is indicated by a triangle.

As illustrated in FIG. 15, when the relationship between proportion b and the maximum value of ratio d/a is approximated by a quadratic function of proportion b, the relationship can be represented by the following expression (5) when b is less than or equal to 0.3.

d/a=1.06b²−0.95b+0.61 (5)

Accordingly, distances d5 and d6, length a of the shorter side of semiconductor stack structure 1s, and proportion b may satisfy the following expressions (6) to (8).

b≤0.3 (6)

d5=d6 (7)

0<d5/a<1.06b²−0.95b+0.61 (8)

This allows forward voltage Vf of nitride semiconductor light-emitting element 1a to be less than forward voltage Vf of the case where ratio d/a is at the maximum.

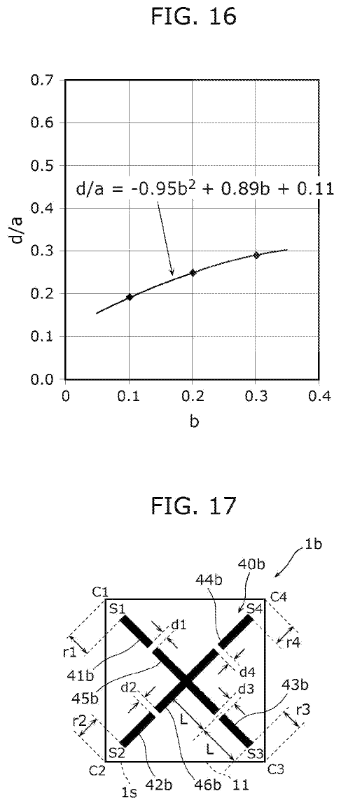

Next, the range of ratio d/a which allows normalized forward voltage Vf as indicated in FIG. 14 to be less than or equal to 1 will be considered. As illustrated in FIG. 14, normalized forward voltage Vf is 1 when ratio d/a is 0, and normalized forward voltage Vf is less than or equal to 1 in the range in which ratio d/a is greater than 0 and less than or equal to a predetermined value. Here, the maximum value of the range of ratio d/a in which the normalized forward voltage Vf is less than or equal to 1 will be explained with reference to FIG. 16.

FIG. 16 is a graph indicating the relationship between proportion b of the area of n-side contact region 40a to the area of semiconductor stack structure 1s of nitride semiconductor light-emitting element 1a according to the present variation and the maximum value of ratio d/a which allows normalized forward voltage Vf to be less than or equal to 1. The horizontal axis of the graph in FIG. 16 indicates proportion b, and the vertical axis indicates ratio d/a. In FIG. 16, the maximum value of ratio d/a which allows normalized forward voltage Vf to be less than or equal to 1 is indicated by a diamond.

As illustrated in FIG. 16, when the relationship between proportion b and the maximum value of ratio d/a which allows normalized forward voltage Vf to be less than or equal to 1 is approximated by a quadratic function of proportion b, the relationship can be represented by the following expression (9) when b is less than or equal to 0.3.

d/a=−0.95b²+0.89b+0.11 (9)

Accordingly, distances d5 and d6, length a of the shorter side of semiconductor stack structure 1s, and proportion b may satisfy the following expressions (10) to (12).

b≤0.3 (10)

d5=d6 (11)

d5/a<−0.95b²+0.89b+0.11 (12)

This allows forward voltage Vf of nitride semiconductor light-emitting element 1b to be less than forward voltage Vf of the case where ratio d/a is 0.

### 1-7. Variation 2

Next, a nitride semiconductor light-emitting element according to Variation 2 of Embodiment 1 will be described. The nitride semiconductor light-emitting element according to the present variation matches nitride semiconductor light-emitting element 1a according to Variation 1 of Embodiment 1 in points other than that the n-side contact region includes six regions. The following describes the nitride semiconductor light-emitting element according to the present variation focusing on the differences from nitride semiconductor light-emitting element 1a according to Variation 1 of Embodiment 1.

First, the configuration of an n-side contact region of the nitride semiconductor light-emitting element according to the present variation will be described with reference to FIG. 17. FIG. 17 is a plan view schematically illustrating the configuration of n-side contact region 40b of nitride semiconductor light-emitting element 1b according to the present variation. FIG. 17 illustrates n-side contact region 40b in a plan view of main surface 11a of substrate 11.

As illustrated in FIG. 17, n-side contact region 40b according to the present variation includes first region 41b, second region 42b, third region 43b, fourth region 44b, fifth region 45b, and sixth region 46b. First region 41b is a linear region extending in one direction from first starting point S1 which is spaced apart from first corner portion C1. Second region 42b is a linear region extending in one direction from second starting point S2 which is spaced apart from second corner portion C2. Third region 43b is a linear region extending in one direction from third starting point S3 which is spaced apart from third corner portion C3. Fourth region 44b is a linear region extending in one direction from fourth starting point S4 which is spaced apart from fourth corner portion C4.

Fifth region 45b is a linear region which is disposed between first region 41b and third region 43b, and is spaced apart from each of first region 41b and third region 43b. According to the present variation, fifth region 45b extends in the same direction as first region 41b and third region 43b.

Sixth region 46b is a linear region which is disposed between second region 42b and fourth region 44b, and is spaced apart from each of second region 42b and fourth region 44b. According to the present variation, sixth region 46b extends in the same direction as second region 42b and fourth region 44b.

Fifth region 45b and sixth region 46b intersect.

In the present variation, distance r1 between first corner portion C1 and first starting point S1, distance r2 between second corner portion C2 and second starting point S2, distance r3 between third corner portion C3 and third starting point S3, and distance r4 between fourth corner portion C4 and fourth starting point S4 are each less than or equal to 0.26 times length a of the shorter side of semiconductor stack structure 1s in the plan view of main surface 11a of substrate 11. It should be noted that distances r1, r2, r3, and r4 are not particularly limited as long as distances r1, r2, r3, and r4 are each less than or equal to 0.26 times length a of the shorter side. According to the present variation, distances r1, r2, r3, and r4 are equal to one other.

Third region 43b is disposed on the extended line of first region 41b and spaced apart from first region 41b, and fourth region 44b is disposed on the extended line of second region 42b and spaced apart from second region 42b.

First region 41b, second region 42b, third region 43b, and fourth region 44b are disposed to be spaced apart from one another.

First region 41b and third region 43b extend in the same direction, and second region 42b and fourth region 44b extend in the same direction.

The extended line of first region 41b intersects the extended line of second region 42b. The extended line of second region 42b intersects the extended line of third region 43b. The extended line of third region 43b intersects the extended line of fourth region 44b. The extended line of fourth region 44b intersects the extended line of first region 41b.

With nitride semiconductor light-emitting element 1b according to the present variation that has the configuration as described above, the same advantageous effects as those of nitride semiconductor light-emitting element 1 according to Embodiment 1 are yielded as well.

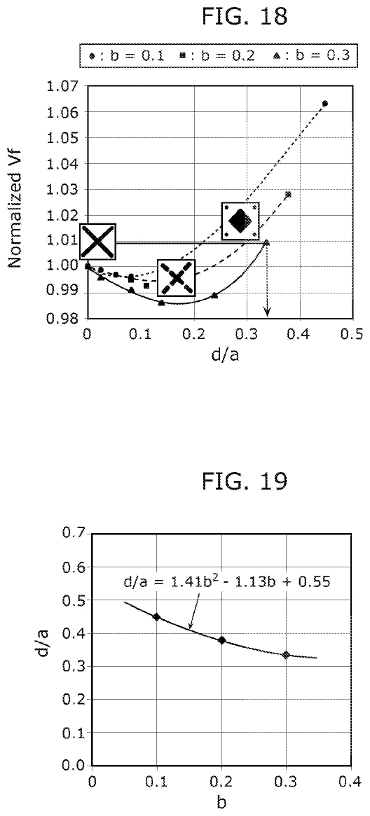

Here, the relationship between: distance d1 between first region 41b and fifth region 45b; distance d2 between second region 42b and sixth region 46b; distance d3 between third region 43b and fifth region 45b; distance d4 between fourth region 44b and sixth region 46b; and forward voltage Vf of nitride semiconductor light-emitting element 1b will be described with reference to FIG. 18. It should be noted that, in the following description, the experimental results in the case where: d1=d2=d3=d4=d; r1=r2=r3=r4; and ratio r1/a is the ratio when normalized forward voltage Vf has a minimal value (indicated by the square in FIG. 11) will be described. FIG. 18 is a graph indicating the relationship between ratio d/a and normalized forward voltage Vf, in nitride semiconductor light-emitting element 1b according to the present variation. It should be noted that the horizontal axis of the graph in FIG. 18 indicates ratio d/a and the vertical axis indicates normalized forward voltage Vf. In FIG. 18, the experimental results when proportion b is 0.1, 0.2, and 0.3 are indicated by a circle, a square, and a triangle, respectively. Normalized forward voltage Vf represents the ratio of forward voltage Vf to forward voltage Vf of the case where ratio d/a is 0. In this experiment, ratio d/a, etc. were varied under the condition that the area of the n-side contact region is equal and that length L of each of first region 41b, second region 42b, third region 43b and fourth region 44b is equal to ½ the length of each of fifth region 45b and sixth region 46b.

As indicated schematically in the graph of FIG. 18, as ratio d/a on the horizontal axis decreases, each region of n-side contact region 40b becomes narrower and longer, and as ratio d/a increases, each region of n-side contact region 40b becomes wider and shorter. In addition, when distance d becomes larger than a certain value, the widths of first region 41b, second region 42b, third region 43b, and fourth region 44b cannot be equal to the widths of fifth region 45b and sixth region 46b. In this case, the experiment was conducted under the condition that fifth region 45b and sixth region 46b are wider than first region 41b, second region 42b, third region 43b, and fourth region 44b.

Here, the range of ratio d/a which allows normalized forward voltage Vf to be smaller than in the case where ratio d/a is at the maximum (i.e., a limit value for the width of each region to be placeable in proximity to a corresponding one of the corner portions) will be considered. As indicated in FIG. 18, for any value of proportion b, normalized forward voltage Vf is at the maximum when ratio d/a is at the maximum. For example, as indicated by the arrow in FIG. 18, when proportion b is 0.3, the maximum value of ratio d/a is approximately 0.33, and when ratio d/a is less than 0.33, normalized forward voltage Vf is smaller than in the case where ratio d/a is at the maximum value. As described above, when ratio d/a is less than the maximum value, it is possible to reduce the forward voltage than in the case where ratio d/a is at the maximum.

The range of the value of ratio d/a that allows forward voltage Vf to be less than in the case where ratio d/a is at the maximum as indicated in FIG. 18 will be described with reference to FIG. 19. FIG. 19 is a graph indicating the relationship between the maximum value of ratio d/a and proportion b of the area of n-side contact region 40b to the area of semiconductor stack structure 1s of nitride semiconductor light-emitting element 1b according to the present variation. The horizontal axis of the graph in FIG. 19 indicates proportion b, and the vertical axis indicates ratio d/a. In FIG. 19, the maximum value of ratio d/a is indicated by a diamond.

As illustrated in FIG. 19, when the relationship between proportion b and the maximum value of ratio d/a is approximated by a quadratic function of proportion b, the relationship can be represented by the following expression (13) when b is less than or equal to 0.3.

d/a=1.41b²−1.13b+0.55 (13)

Accordingly, distances d1 to d4, length a of the shorter side of semiconductor stack structure 1s, and proportion b may satisfy the following expressions (14) to (16).

b≤0.3 (14)

d1=d2=d3=d4 (15)

0<d1/a<1.41b²−1.13b+0.55 (16)

This allows forward voltage Vf of nitride semiconductor light-emitting element 1b to be less than forward voltage Vf of the case where ratio d/a is at the maximum.

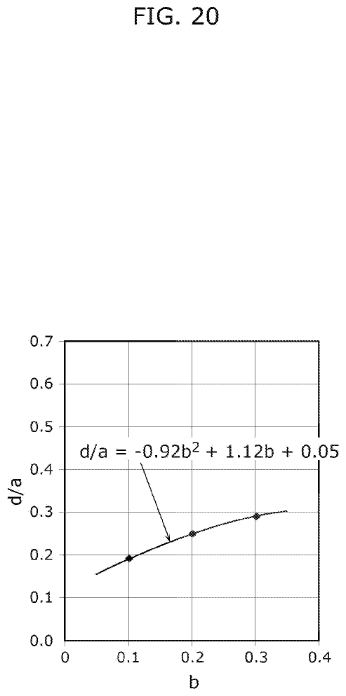

Next, the range of ratio d/a which allows normalized forward voltage Vf as indicated in FIG. 18 to be less than or equal to 1 will be considered. As illustrated in FIG. 18, normalized forward voltage Vf is 1 when ratio d/a is 0, and normalized forward voltage Vf is less than or equal to 1 in the range in which ratio d/a is greater than 0 and less than or equal to a predetermined value. Here, the result of calculating the maximum value of ratio d/a that allows normalized forward voltage Vf to be less than or equal to 1 will be described with reference to FIG. 20. FIG. 20 is a graph indicating the relationship between (i) proportion b of the area of n-side contact region 40b to the area of semiconductor stack structure is of nitride semiconductor light-emitting element 1b according to the present variation and (ii) the maximum value of ratio d/a which allows normalized forward voltage Vf to be less than or equal to 1. The horizontal axis of the graph in FIG. 20 indicates proportion b, and the vertical axis indicates ratio d/a. In FIG. 20, the maximum value of ratio d/a which allows normalized forward voltage Vf to be less than or equal to 1 is indicated by a diamond.

As illustrated in FIG. 20, when the relationship between proportion b and the maximum value of ratio d/a which allows normalized forward voltage Vf to be less than or equal to 1 is approximated by a quadratic function of proportion b, the relationship can be represented by the following expression (17) when b is less than or equal to 0.3.

d/a=−0.92b²+1.12b+0.05 (17)

Accordingly, distances d1 to d4, length a of the shorter side of semiconductor stack structure 1s, and proportion b may satisfy the following expressions (18) to (20).

b≤0.3 (18)

d1=d2=d3=d4 (19)

d1/a<−0.92b²+1.12b+0.05 (20)

This allows forward voltage Vf of nitride semiconductor light-emitting element 1b to be less than forward voltage Vf of the case where ratio d/a is 0.

### 1-8. Variation 3

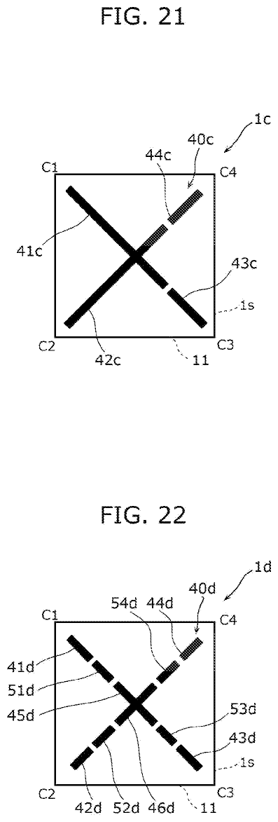

Next, a nitride semiconductor light-emitting element according to Variation 3 of Embodiment 1 will be described. The nitride semiconductor light-emitting element according to the present variation matches nitride semiconductor light-emitting element 1a according to Variation 1 of Embodiment 1 in points other than that the n-side contact region includes four regions and that, among the four regions, the first region and the second region intersect. The following describes the nitride semiconductor light-emitting element according to the present variation focusing on the differences from nitride semiconductor light-emitting element 1a according to Variation 1 of Embodiment 1, with reference to FIG. 21.

FIG. 21 is a plan view schematically illustrating the configuration of n-side contact region 40c of nitride semiconductor light-emitting element 1c according to the present variation. FIG. 21 illustrates n-side contact region 40c in a plan view of main surface 11a of substrate 11.

As illustrated in FIG. 21, n-side contact region 40c according to the present variation includes first region 41c, second region 42c, third region 43c, and fourth region 44c. First region 41c is a linear region extending in one direction from first starting point S1 which is spaced apart from first corner portion C1. Second region 42c is a linear region extending in one direction from second starting point S2 which is spaced apart from second corner portion C2. Third region 43c is a linear region extending in one direction from third starting point S3 which is spaced apart from third corner portion C3. Fourth region 44c is a linear region extending in one direction from fourth starting point S4 which is spaced apart from fourth corner portion C4.

Third region 43c is disposed on the extended line of first region 41c and spaced apart from first region 41c, and fourth region 44c is disposed on the extended line of second region 42c and spaced apart from second region 42c.

First region 41c and third region 43c extend in the same direction, and second region 42c and fourth region 44c extend in the same direction.

First region 41c and second region 42c intersect. Second region 42c and the extended line of third region 43c intersect. The extended line of third region 43c and the extended line of fourth region 44c intersect. The extended line of fourth region 44c and first region 41c intersect.

With nitride semiconductor light-emitting element 1c according to the present variation that has the configuration as described above, the same advantageous effects as those of nitride semiconductor light-emitting element 1 according to Embodiment 1 are yielded as well.

### 1-9. Variation 4

Next, a nitride semiconductor light-emitting element according to Variation 4 of Embodiment 1 will be described. The nitride semiconductor light-emitting element according to the present variation matches nitride semiconductor light-emitting element 1b according to Variation 2 of Embodiment 1 in points other than that the n-side contact region includes 10 regions. The following describes the nitride semiconductor light-emitting element according to the present variation focusing on the differences from nitride semiconductor light-emitting element 1b according to Variation 2 of Embodiment 1, with reference to FIG. 22.

FIG. 22 is a plan view schematically illustrating the configuration of n-side contact region 40d of nitride semiconductor light-emitting element 1d according to the present variation. FIG. 22 illustrates n-side contact region 40d in a plan view of main surface 11a of substrate 11.

As illustrated in FIG. 22, n-side contact region 40d according to the present variation includes first region 41d, second region 42d, third region 43d, fourth region 44d, fifth region 45d, sixth region 46d, seventh region 51d, eighth region 52d, ninth region 53d, and tenth region 54d. First region 41d is a linear region extending in one direction from first starting point S1 which is spaced apart from first corner portion C1. Second region 42d is a linear region extending in one direction from second starting point S2 which is spaced apart from second corner portion C2. Third region 43d is a linear region extending in one direction from third starting point S3 which is spaced apart from third corner portion C3. Fourth region 44d is a linear region extending in one direction from fourth starting point S4 which is spaced apart from fourth corner portion C4.

Third region 43d is disposed on the extended line of first region 41d and spaced apart from first region 41d, and fourth region 44d is disposed on the extended line of second region 42d and spaced apart from second region 42d.

First region 41d and third region 43d extend in the same direction, and second region 42d and fourth region 44d extend in the same direction.

The extended line of first region 41d and the extended line of second region 42d intersect. The extended line of second region 42d and the extended line of third region 43d intersect. The extended line of third region 43d and the extended line of fourth region 44d intersect. The extended line of fourth region 44d and the extended line of first region 41d intersect.

Each of fifth region 45d, seventh region 51d, and ninth region 53d is a linear region disposed between first region 41d and third region 43d, and is spaced apart from each of first region 41d and third region 43d. Seventh region 51d is disposed between first region 41d and fifth region 45d, and is spaced apart from fifth region 45d. Ninth region 53d is disposed between third region 43d and fifth region 45d, and is spaced apart from fifth region 45d. In other words, first region 41d, seventh region 51d, fifth region 45d, ninth region 53d, and third region 43d are disposed in stated order on the diagonal line connecting first corner portion C1 and third corner portion C3. According to the present variation, fifth region 45d, seventh region 51d, and ninth region 53d extend in the same direction as first region 41d and third region 43d.

Each of sixth region 46d, eighth region 52d, and tenth region 54d is a linear region disposed between second region 42d and fourth region 44d, and is spaced apart from each of second region 42d and fourth region 44d. Eighth region 52d is disposed between second region 42d and sixth region 46d, and is spaced apart from sixth region 46d. Tenth region 54d is disposed between fourth region 44d and sixth region 46d, and is spaced apart from sixth region 46d. In other words, second region 42d, eighth region 52d, sixth region 46d, tenth region 54d, and fourth region 44d are disposed in stated order on the diagonal line connecting second corner portion C2 and fourth corner portion C4. According to the present variation, sixth region 46d, eighth region 52d, and tenth region 54d extend in the same direction as second region 42d and fourth region 44d.

Fifth region 45d and sixth region 46d intersect.

With nitride semiconductor light-emitting element 1d according to the present variation that has the configuration as described above, the same advantageous effects as those of nitride semiconductor light-emitting element 1 according to Embodiment 1 are yielded as well.

### 1-10. Variation 5

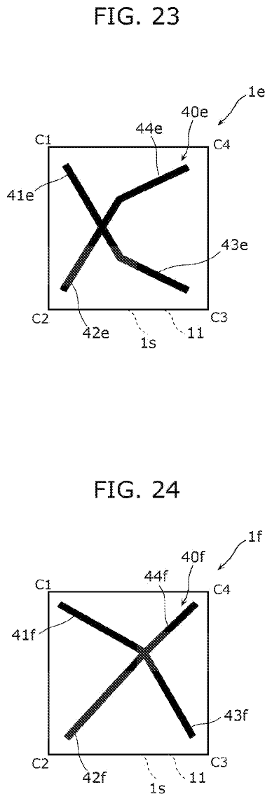

Next, a nitride semiconductor light-emitting element according to Variation 5 of Embodiment 1 will be described. The nitride semiconductor light-emitting element according to the present variation matches nitride semiconductor light-emitting element 1a according to Variation 1 of Embodiment 1 in points other than that the n-side contact region includes four regions, and that, among those four regions, the first region and the third region are connected, and the second region and the fourth region are connected. The following describes the nitride semiconductor light-emitting element according to the present variation focusing on the differences from nitride semiconductor light-emitting element 1a according to Variation 1 of Embodiment 1, with reference to FIG. 23.

FIG. 23 is a plan view schematically illustrating the configuration of n-side contact region 40e of nitride semiconductor light-emitting element 1e according to the present variation. FIG. 23 illustrates n-side contact region 40e in a plan view of main surface 11a of substrate 11.

As illustrated in FIG. 23, n-side contact region 40e according to the present variation includes first region 41e, second region 42e, third region 43e, and fourth region 44e. First region 41e is a linear region extending in one direction from first starting point S1 which is spaced apart from first corner portion C1. Second region 42e is a linear region extending in one direction from second starting point S2 which is spaced apart from second corner portion C2. Third region 43e is a linear region extending in one direction from third starting point S3 which is spaced apart from third corner portion C3. Fourth region 44e is a linear region extending in one direction from fourth starting point S4 which is spaced apart from fourth corner portion C4.

Third region 43e is disposed on the extended line of first region 41e, and first region 41e and third region 43e are connected. Fourth region 44e is disposed on the extended line of second region 42e, and second region 42e and fourth region 44e are connected.

According to the present variation, first region 41e and third region 43e extend in different directions, and second region 42e and fourth region 44e extend in different directions.

It should be noted that first region 41e and third region 43e may extend in the same direction, and second region 42e and fourth region 44e may extend in the same direction. In other words, the region of a combination of first region 41e and third region 43e may extend linearly, and the region of a combination of second region 42e and fourth region 44e may extended linearly. In this case, nitride semiconductor light-emitting element 1e according to the present variation has the same configuration as nitride semiconductor light-emitting element 1 according to Embodiment 1.

First region 41e and second region 42e intersect. Second region 42e and the extended line of third region 43e intersect. The extended line of third region 43e and the extended line of fourth region 44e intersect. The extended line of fourth region 44e and first region 41e intersect.

With nitride semiconductor light-emitting element 1e according to the present variation that has the configuration as described above, the same advantageous effects as those of nitride semiconductor light-emitting element 1 according to Embodiment 1 are yielded as well.

### 1-11. Variation 6

Next, a nitride semiconductor light-emitting element according to Variation 6 of Embodiment 1 will be described. The nitride semiconductor light-emitting element according to the present variation matches nitride semiconductor light-emitting element 1e according to Variation 5 of Embodiment 1 in points other than that the n-side contact region includes four regions, and that these four regions are connected at one point. The following describes the nitride semiconductor light-emitting element according to the present variation focusing on the differences from nitride semiconductor light-emitting element 1e according to Variation 5 of Embodiment 1, with reference to FIG. 24.

FIG. 24 is a plan view schematically illustrating the configuration of n-side contact region 40f of nitride semiconductor light-emitting element 1f according to the present variation. FIG. 24 illustrates n-side contact region 40f in a plan view of main surface 11a of substrate 11.

As illustrated in FIG. 24, n-side contact region 40f according to the present variation includes first region 41f, second region 42f, third region 43f, and fourth region 44f. First region 41f is a linear region extending in one direction from first starting point S1 which is spaced apart from first corner portion C1. Second region 42f is a linear region extending in one direction from second starting point S2 which is spaced apart from second corner portion C2. Third region 43f is a linear region extending in one direction from third starting point S3 which is spaced apart from third corner portion C3. Fourth region 44f is a linear region extending in one direction from fourth starting point S4 which is spaced apart from fourth corner portion C4.

Third region 43f is disposed on the extended line of first region 41f, and first region 41f and third region 43f are connected to each other. Fourth region 44f is disposed on the extended line of second region 42f, and second region 42f and fourth region 44f are connected to each other.

According to the present variation, first region 41f and third region 43f extend in different directions, and second region 42f and fourth region 44f extend in different directions. First region 41f, second region 42f, third region 43f, and fourth region 44f are connected at one point. Here, second region 42f and fourth region 44f may extend in the same direction.

With nitride semiconductor light-emitting element 1f according to the present variation that has the configuration as described above, the same advantageous effects as those of nitride semiconductor light-emitting element 1 according to Embodiment 1 are yielded as well.

### 1-12. Variation 7

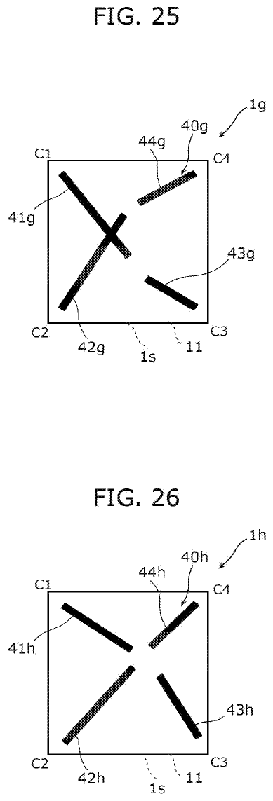

Next, a nitride semiconductor light-emitting element according to Variation 7 of Embodiment 1 will be described. The nitride semiconductor light-emitting element according to the present variation matches nitride semiconductor light-emitting element 1e according to Variation 5 of Embodiment 1 in points other than that the n-side contact region includes four regions, and that, among those four regions, the first region and the third region are spaced apart from each other, and the second region and the fourth region are spaced apart from each other. The following describes the nitride semiconductor light-emitting element according to the present variation focusing on the differences from nitride semiconductor light-emitting element 1e according to Variation 5 of Embodiment 1, with reference to FIG. 25.

FIG. 25 is a plan view schematically illustrating the configuration of n-side contact region 40g of nitride semiconductor light-emitting element 1g according to the present variation. FIG. 25 illustrates n-side contact region 40g in a plan view of main surface 11a of substrate 11.

As illustrated in FIG. 25, n-side contact region 40g according to the present variation includes first region 41g, second region 42g, third region 43g, and fourth region 44g. First region 41g is a linear region extending in one direction from first starting point S1 which is spaced apart from first corner portion C1. Second region 42g is a linear region extending in one direction from second starting point S2 which is spaced apart from second corner portion C2. Third region 43g is a linear region extending in one direction from third starting point S3 which is spaced apart from third corner portion C3. Fourth region 44g is a linear region extending in one direction from fourth starting point S4 which is spaced apart from fourth corner portion C4.

Third region 43g is disposed on the extended line of first region 41g and spaced apart from first region 41g. Fourth region 44g is disposed on the extended line of second region 42g and spaced apart from second region 42g.

According to the present variation, first region 41g and third region 43g extend in different directions, and second region 42g and fourth region 44g extend in different directions.

First region 41g and second region 42g intersect. Second region 42g and the extended line of third region 43g intersect. The extended line of third region 43g and the extended line of fourth region 44g intersect. The extended line of fourth region 44g and first region 41g intersect.

With nitride semiconductor light-emitting element 1g according to the present variation that has the configuration as described above, the same advantageous effects as those of nitride semiconductor light-emitting element 1 according to Embodiment 1 are yielded as well.

### 1-13. Variation 8

Next, a nitride semiconductor light-emitting element according to Variation 8 of Embodiment 1 will be described. The nitride semiconductor light-emitting element according to the present variation matches nitride semiconductor light-emitting element 1f according to Variation 6 of Embodiment 1 in points other than that the n-side contact region includes four regions, and that these four regions are spaced apart from one another. The following describes the nitride semiconductor light-emitting element according to the present variation focusing on the differences from nitride semiconductor light-emitting element 1f according to Variation 6 of Embodiment 1, with reference to FIG.

FIG. 26 is a plan view schematically illustrating the configuration of n-side contact region 40h of nitride semiconductor light-emitting element 1h according to the present variation. FIG. 26 illustrates n-side contact region 40h in a plan view of main surface 11a of substrate 11.

As illustrated in FIG. 26, n-side contact region 40h according to the present variation includes first region 41h, second region 42h, third region 43h, and fourth region 44h. First region 41h is a linear region extending in one direction from first starting point S1 which is spaced apart from first corner portion C1. Second region 42h is a linear region extending in one direction from second starting point S2 which is spaced apart from second corner portion C2. Third region 43h is a linear region extending in one direction from third starting point S3 which is spaced apart from third corner portion C3. Fourth region 44h is a linear region extending in one direction from fourth starting point S4 which is spaced apart from fourth corner portion C4.

Third region 43h is disposed on the extended line of first region 41h and spaced apart from first region 41h. Fourth region 44h is disposed on the extended line of second region 42h and spaced apart from second region 42h.

First region 41h and third region 43h extend in different directions, and second region 42h and fourth region 44h extend in different directions. Here, second region 42h and fourth region 44h may extend in the same direction.

First region 41h, second region 42h, third region 43h, and fourth region 44h are spaced apart from each other.

With nitride semiconductor light-emitting element 1h according to the present variation that has the configuration as described above, the same advantageous effects as those of nitride semiconductor light-emitting element 1 according to Embodiment 1 are yielded as well.

### Embodiment 2

A nitride semiconductor light-emitting element according to Embodiment 2 will be described. The nitride semiconductor light-emitting element according to the present embodiment matches nitride semiconductor light-emitting element 1 according to Embodiment 1 in points other than that the n-side contact region has a rectangular annular shape. The following describes the nitride semiconductor light-emitting element according to the present embodiment focusing on the differences from nitride semiconductor light-emitting element 1 according to Embodiment 1.

### 2-1. Detailed Configuration of N-Side Contact Region 140

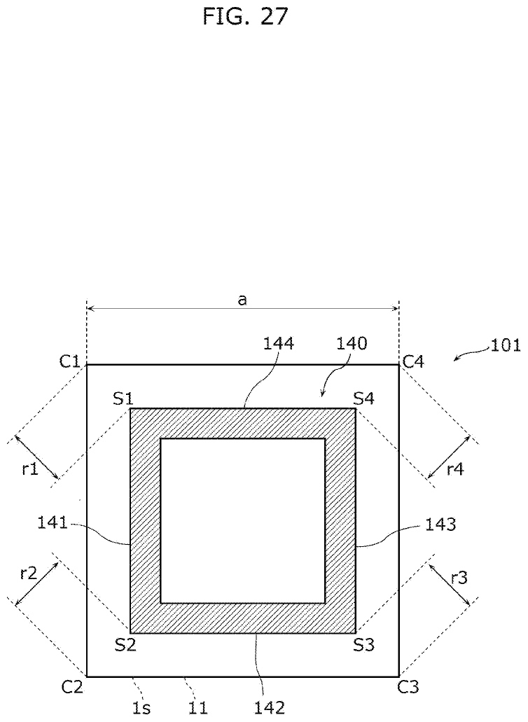

First, the detailed configuration of an n-side contact region included in the nitride semiconductor light-emitting element according to the present embodiment will be described with reference to FIG. 27. FIG. 27 is a plan view schematically illustrating the configuration of n-side contact region 140 of nitride semiconductor light-emitting element 101 according to the present embodiment. FIG. 27 illustrates a plan view of main surface 11a of substrate 11.

As illustrated in FIG. 27, in nitride semiconductor light-emitting element 101 according to the present embodiment, in the plan view of main surface 11a of substrate 11, semiconductor stack structure 1s has a rectangular shape, and includes first corner portion C1, second corner portion C2, third corner portion C3, and fourth corner portion C4 respectively corresponding to the four vertexes of the rectangular shape.

N-side contact region 140 has a rectangular annular shape. More specifically, n-side contact region 140 includes first region 141, second region 142, third region 143, and fourth region 144. First region 141 is a linear region extending in one direction from first starting point S1 which is spaced apart from first corner portion C1. Second region 142 is a linear region extending in one direction from second starting point S2 which is spaced apart from second corner portion C2. Third region 143 is a linear region extending in one direction from third starting point S3 which is spaced apart from third corner portion C3. Fourth region 144 is a linear region extending in one direction from fourth starting point S4 which is spaced apart from fourth corner portion C4.

A p-side contact region is disposed between first starting point S1 and first corner portion C1, between second starting point S2 and second corner portion C2, between third starting point S3 and third corner portion C3, and between fourth starting point S4 and fourth corner portion C4. It should be noted that no n-side contact region 140 is disposed between first starting point S1 and first corner portion C1, between second starting point S2 and second corner portion C2, between third starting point S3 and third corner portion C3, and between fourth starting point S4 and fourth corner portion C4.

Distance r1 between first corner portion C1 and first starting point S1, distance r2 between second corner portion C2 and second starting point S2, distance r3 between third corner portion C3 and third starting point S3, and distance r4 between fourth corner portion C4 and fourth starting point S4 are each less than or equal to 0.26 times length a of the shorter side of semiconductor stack structure 1s in a plan view of main surface 11a of substrate 11. It should be noted that distances r1, r2, r3, and r4 are not particularly limited as long as distances r1, r2, r3, and r4 are each less than or equal to 0.26 times length a of the shorter side. According to the present embodiment, distances r1, r2, r3, and r4 are equal to one another.

According to the present embodiment, first region 141 linearly extends from first starting point S1 to second starting point S2. According to this configuration, first region 141 and second region 142 are connected to each other. Second region 142 linearly extends from second starting point S2 to third starting point S3. According to this configuration, second region 142 and third region 143 are connected to each other. Third region 143 linearly extends from third starting point S3 to fourth starting point S4. According to this configuration, third region 143 and fourth region 144 are connected to each other. Fourth region 144 linearly extends from fourth starting point S4 to first starting point S1. According to this configuration, fourth region 144 and first region 141 are connected to each other. It should be noted that, in n-side contact region 140 according to the present embodiment, first region 141 may be identified as linearly extending from second starting point S2 to first starting point S1. Second region 142 may be identified as linearly extending from third starting point S3 to second starting point S2. Third region 143 may be identified as linearly extending from fourth starting point S4 to third starting point S3. Fourth region 144 may be identified as linearly extending from first starting point S1 to fourth starting point S4. Furthermore, two regions, namely, first region 141 and second region 142, may be identified as linearly extending in different directions from second starting point S2, and two regions, namely, third region 143 and fourth region 144, may be identified as linearly extending in different directions from fourth starting point S4.

### 2-2. Function and Advantageous Effect

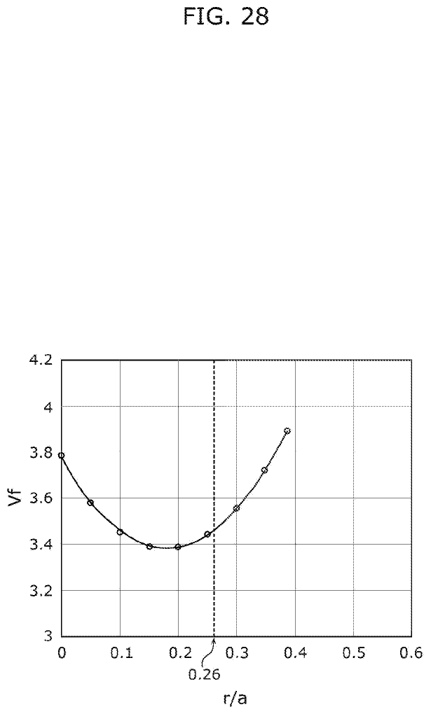

Next, a function and an advantageous effect of nitride semiconductor light-emitting element 101 according to the present embodiment will be described. The forward voltage in nitride semiconductor light-emitting element 101 according to the present embodiment will be described with reference to FIG. 28. FIG. 28 is a graph indicating the relationship between forward voltage Vf and ratio r/a. Ratio r/a is the ratio of distance r from each of the corner portions to n-side contact region 140 to length a of the shorter side of nitride semiconductor light-emitting element 101 according to the present embodiment. The horizontal axis of the graph in FIG. 28 indicates ratio r/a and the vertical axis indicates forward voltage Vf.

In the graph illustrated in FIG. 28, the experimental results of forward voltage Vf when distances r1, r2, r3, and r4 are equal and proportion b of the area of n-side contact region 140 to the area of semiconductor stack structure 1s in the plan view of main surface 11a of substrate 11 is 0.2 are indicated. In this experiment, ratio r/a, etc. were varied under the condition that the area of the n-side contact region is equal. Distance r from each of the corner portions to n-side contact region 40 corresponds to distances r1, r2, r3 and r4. Forward voltage Vf represents the forward voltage when the supply current is 1 A for nitride semiconductor light-emitting element 101 in which the shorter side and the longer side are the same 1 mm.

As illustrated in FIG. 28, forward voltage Vf is a minimal value of approximately 3.4 V when ratio r/a is approximately 0.18, and is close to a minimum value of less than 3.8 V when ratio r/a is greater than 0 and less than or equal to 0.26.

Here, the advantageous effect of nitride semiconductor light-emitting element 101 according to the present embodiment will be described with comparison to nitride semiconductor light-emitting element 1 according to Embodiment 1. According to Embodiment 1, as indicated in graph (b) of FIG. 8, the distance from the vicinity of the center of each side of the peripheral edge of nitride semiconductor light-emitting element 1 to n-side contact region 40 is largest in p-side contact region 60 in the plan view of the main surface of the substrate. According to the present embodiment, first region 141 linearly extends from first starting point S1 to second starting point S2, and thus it is possible to reduce the distance from (i) the vicinity of the center of the side of semiconductor stack structure 1s including first corner portion C1 and second corner portion C2 in the p-side contact region to (ii) n-side contact region 140. Accordingly, it is possible to reduce the electrical resistance of nitride semiconductor light-emitting element 101 in the same manner as Embodiment 1. As a result, it is possible to reduce the forward voltage in nitride semiconductor light-emitting element 101 according to the present embodiment.

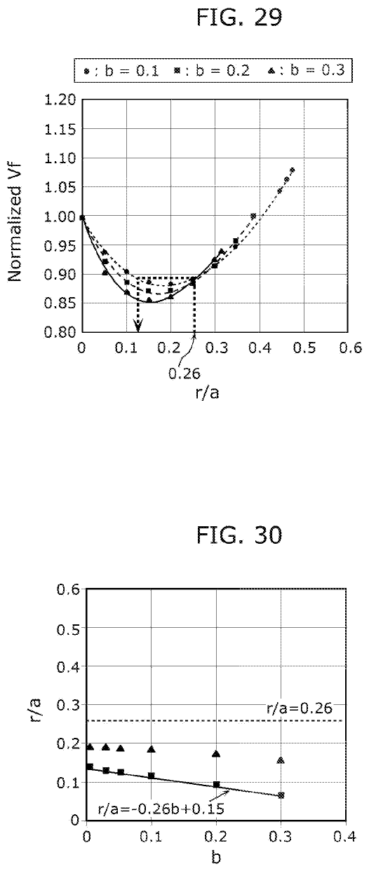

Next, the relationship between forward voltage Vf and proportion b of the area of n-side contact region 140 to the area of semiconductor stack structure 1s of nitride semiconductor light-emitting element 101 according to the the present embodiment will be described with reference to FIG. 29. FIG. 29 is a graph indicating the relationship between normalized forward voltage Vf and ratio r/a. Ratio r/a is the ratio of distance r from each of the corner portions to n-side contact region 140 to length a of the shorter side of nitride semiconductor light-emitting element 101 according to the present embodiment. The horizontal axis of the graph in FIG. 29 indicates ratio r/a and the vertical axis indicates normalized forward voltage Vf. In FIG. 29, the experimental results when proportion b is 0.1, 0.2, and 0.3 are indicated by a triangle, a square, and a circle, respectively. Normalized forward voltage Vf represents the ratio of forward voltage Vf to forward voltage Vf of the case where ratio r/a is 0.

As illustrated in FIG. 29, normalized forward voltage Vf has a minimal value in the range in which ratio r/a is greater than 0 and less than or equal to 0.26 for each of the cases where proportion b is 0.1, 0.2, and 0.3.

The maximum value of the ratio r/a indicated in FIG. 29 is ratio r/a when the gap inside n-side contact region 140 is eliminated as a result of n-side contact region 140 being away from the corner portion, and n-side contact region 140 no longer has an annular shape.

Here, the range of ratio r/a which allows normalized forward voltage Vf as indicated in FIG. 29 to be less than or equal to 1 will be considered. As illustrated in FIG. 29, normalized forward voltage Vf is 1 when ratio r/a is 0, and normalized forward voltage Vf is less than or equal to 1 in the range in which ratio r/a is greater than 0 and less than or equal to a predetermined value. As indicated in FIG. 29, the maximum value of the range of ratio r/a in which the normalized forward voltage Vf is less than or equal to 1 is greater than 0.26 for any proportion b. Accordingly, when proportion b is less than or equal to 0.3 and ratio r/a is less than or equal to 0.26, forward voltage Vf of nitride semiconductor light-emitting element 101 can be less than forward voltage Vf of the case where ratio r/a is 0.

Next, the range of ratio r/a which allows normalized forward voltage Vf as indicated in FIG. 29 to be smaller than in the case where ratio r/a is 0.26 will be considered. As illustrated in FIG. 29, in the range in which ratio r/a is less than 0.26 and greater than or equal to a predetermined value, the normalized forward voltage can be smaller than in the case where ratio r/a is 0.26. For example, as indicated by the arrow in FIG. 29, when proportion b is 0.1, the normalized forward voltage can be smaller than in the case where ratio r/a is 0.26 in the range in which ratio r/a is greater than or equal to approximately 0.12. Here, the minimum value of the range of ratio r/a which allows normalized forward voltage Vf to be smaller than in the case where ratio r/a is 0.26 will be described with reference to FIG. 30.

FIG. 30 is a graph illustrating the relationship between proportion b and the minimum value of the range of ratio r/a that allows normalized forward voltage Vf to be smaller than in the case where ratio r/a is 0.26. Proportion b is the proportion of the area of n-side contact region 140 to the area of semiconductor stack structure 1s of nitride semiconductor light-emitting element 101 according to the present embodiment. The horizontal axis of the graph in FIG. 30 indicates proportion b, and the vertical axis indicates ratio r/a. In FIG. 30, the minimum value of the range of ratio r/a is indicated by a square. It should be noted that ratio r/a in the case where normalized forward voltage Vf has a minimal value is also indicated by a triangle in FIG. 30.

As illustrated in FIG. 30, when the relationship between proportion b and the minimum value of the range of ratio r/a is approximated by a linear function of proportion b, the relationship can be represented by the following expression (21) when b is less than or equal to 0.3.

r/a=−0.26b+0.15 (21)

Accordingly, distances r1 to r4, length a of the shorter side of semiconductor stack structure 1s, and proportion b may satisfy the following expressions (22) to (24).

b≤0.3 (22)

r1=r2=r3=r4 (23)

−0.26b+0.15<r1/a<0.26 (24)

This allows forward voltage Vf of nitride semiconductor light-emitting element 101 to be less than forward voltage Vf of the case where ratio r/a is 0.26.

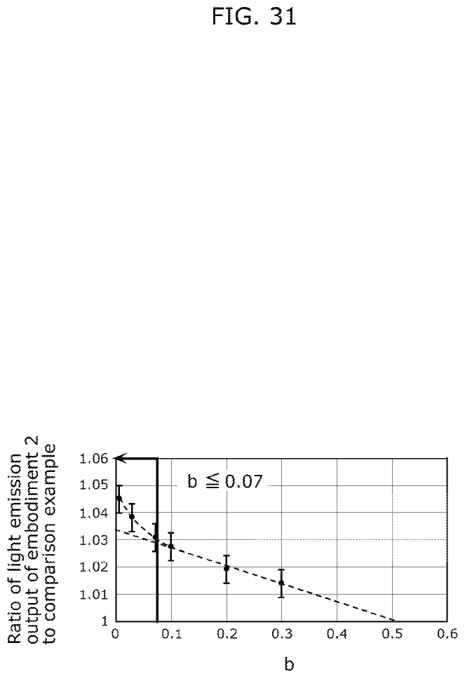

Next, the relationship between a light emission output and proportion b of the area of n-side contact region 140 to the area of semiconductor stack structure 1s of nitride semiconductor light-emitting element 101 will be described with reference to FIG. 31. FIG. 31 is a graph indicating the relationship between (i) proportion b of the area of the n-side contact region to the area of the semiconductor stack structure of nitride semiconductor light-emitting element 101 according to the present embodiment and (ii) the ratio of the light emission output of nitride semiconductor light-emitting element 101 according to the present embodiment in the case where ratio r/a is the ratio when normalized forward voltage Vf has a minimal value to the light emission output of the nitride semiconductor light-emitting element according to the comparison example. FIG. 31 is a graph indicating the experimental results. The horizontal axis of the graph indicates proportion b and the vertical axis indicates the ratio of the light emission output. It should be noted that the nitride semiconductor light-emitting element according to the comparison example has the same configuration as the nitride semiconductor light-emitting element according to the comparison example described in Embodiment 1.

As illustrated in FIG. 31, the ratio of the light emission output is greater than 1 in the entire range in which proportion b is less than or equal to 0.3. In other words, nitride semiconductor light-emitting element 101 according to the present embodiment has a greater light emission output than the nitride semiconductor light-emitting element according to the comparison example. In addition, as proportion b decreases from 0.3 to 0.07, the ratio of the light emission output increases substantially linearly, and as proportion b decreases further from 0.07, the ratio of the light emission output increases more steeply than linearly. Accordingly, in nitride semiconductor light-emitting element 101 according to the present embodiment, proportion b may satisfy b≤0.07. In this manner, it is possible to further increase the light emission output of nitride semiconductor light-emitting element 101 compared to the light emission output of the nitride semiconductor light-emitting element of the comparison example.

### 2-3. Variation 1

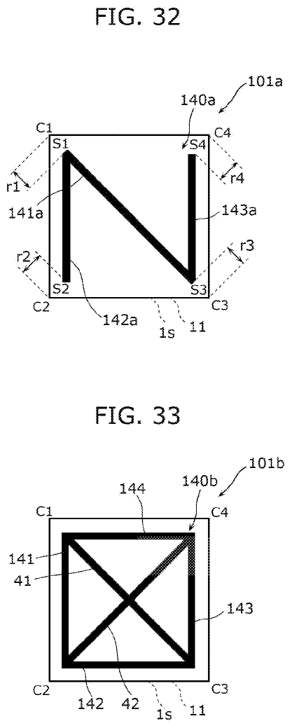

Next, a nitride semiconductor light-emitting element according to Variation 1 of Embodiment 2 will be described. The nitride semiconductor light-emitting element according to the present variation differs from nitride semiconductor light-emitting element 101 according to Embodiment 2 in that the n-side contact region includes 3 regions, etc. The following describes the nitride semiconductor light-emitting element according to the present variation focusing on the differences from nitride semiconductor light-emitting element 101 according to Embodiment 2, with reference to FIG. 32.

FIG. 32 is a plan view schematically illustrating the configuration of n-side contact region 140a of nitride semiconductor light-emitting element 101a according to the present variation. FIG. 32 illustrates n-side contact region 140a in a plan view of main surface 11a of substrate 11.

As illustrated in FIG. 32, n-side contact region 140a according to the present variation includes first region 141a, second region 142a, and third region 143a. First region 141a is a linear region extending in one direction from first starting point S1 which is spaced apart from first corner portion C1. Second region 142a is a linear region extending in one direction from second starting point S2 which is spaced apart from second corner portion C2. Third region 143a is a linear region extending in one direction from third starting point S3 which is spaced apart from third corner portion C3.

According to the present variation, first region 141a linearly extends from first starting point S1 to third starting point S3. According to this configuration, first region 141a and third region 143a are connected to each other. Second region 142a linearly extends from second starting point S2 to first starting point S1. According to this configuration, second region 142a and first region 141a are connected to each other. Third region 143a linearly extends from third starting point S3 to fourth starting point S4. It should be noted that, in n-side contact region 140a according to the present variation, first region 141a may be identified as linearly extending from third starting point S3 to first starting point S1. Second region 142a may be identified as linearly extending from first starting point S1 to second starting point S2. Third region 143a may be identified as linearly extending from fourth starting point S4 to third starting point S3. Furthermore, two regions, namely, first region 141a and second region 142a, may be identified as linearly extending in different directions from first starting point S1, and two regions, namely, first region 141a and third region 143a, may be identified as linearly extending in different directions from third starting point S3.

Distance r1 between first corner portion C1 and first starting point S1, distance r2 between second corner portion C2 and second starting point S2, distance r3 between third corner portion C3 and third starting point S3, and distance r4 between fourth corner portion C4 and fourth starting point S4 are each less than or equal to 0.26 times length a of the shorter side of semiconductor stack structure 1s in the plan view of main surface 11a of substrate 11. It should be noted that distances r1, r2, r3, and r4 are not particularly limited as long as distances r1, r2, r3, and r4 are each less than or equal to 0.26 times length a of the shorter side. According to the present variation, distances r1, r2, r3, and r4 are equal to one another.

With nitride semiconductor light-emitting element 101a according to the present variation that has the configuration as described above, the same advantageous effects as those of nitride semiconductor light-emitting element 101 according to Embodiment 2 are yielded as well.

### 2-4. Variation 2

Next, a nitride semiconductor light-emitting element according to Variation 2 of Embodiment 2 will be described. The nitride semiconductor light-emitting element according to the present variation matches nitride semiconductor light-emitting element 101 according to Embodiment 2 in points other than that the n-side contact region includes n-side contact region 40 according to Embodiment 1 in addition to n-side contact region 140 according to Embodiment 2. The following describes the nitride semiconductor light-emitting element according to the present variation focusing on the differences from nitride semiconductor light-emitting element 101 according to Embodiment 2, with reference to FIG. 33.

FIG. 33 is a plan view illustrating the configuration of n-side contact region 140b of nitride semiconductor light-emitting element 101b according to the present variation. It should be noted that the following describes the configurations of n-side contact region 140b, etc. in a plan view of main surface 11a of substrate 11.

N-side contact region 140b includes first region 141, second region 142, third region 143, and fourth region 144, as with n-side contact region 140 according to Embodiment 2. N-side contact region 140b according to the present variation further includes first region 41 and second region 42 which are equivalent to those included in n-side contact region 40 according to Embodiment 1. First region 41 and second region 42 included in n-side contact region 140b according to the present variation are examples of a first additional region having a linear shape and extending from first starting point S1 in a direction different from a direction of first region 141 and a second additional region having a linear shape and extending from second starting point S2 in a direction different from a direction of second region 142, respectively.

It should be noted that first region 41 may be identified as including: the first additional region having a linear shape and extending from first starting point S1 in a direction different from a direction of first region 141; and the third additional region having a linear shape and extending from third starting point S3 in a direction different from a direction of third region 143. In addition, second region 42 may be identified as including: the second additional region having a linear shape and extending from second starting point S2 in a direction different from a direction of second region 142; and the fourth additional region having a linear shape and extending from fourth starting point S4 in a direction different from a direction of fourth region 144. In this case, first region 141 and the second additional region are connected at second starting point S2, second region 142 and the third additional region are connected at third starting point S3, third region 143 and the fourth additional region are connected at fourth starting point S4, and fourth region 144 and the first additional region are connected at first starting point S1.

With nitride semiconductor light-emitting element 101b according to the present variation that has the configuration as described above, the same advantageous effects as those of nitride semiconductor light-emitting element 101 according to Embodiment 2 are yielded as well.

### 2-5. Variation 3

Next, a nitride semiconductor light-emitting element according to Variation 3 of Embodiment 2 will be described. The nitride semiconductor light-emitting element according to the present variation matches nitride semiconductor light-emitting element 101 according to Embodiment 2 in points other than that the n-side contact region has four regions which are spaced apart from one another. The following describes the nitride semiconductor light-emitting element according to the present variation focusing on the differences from nitride semiconductor light-emitting element 101 according to Embodiment 2.

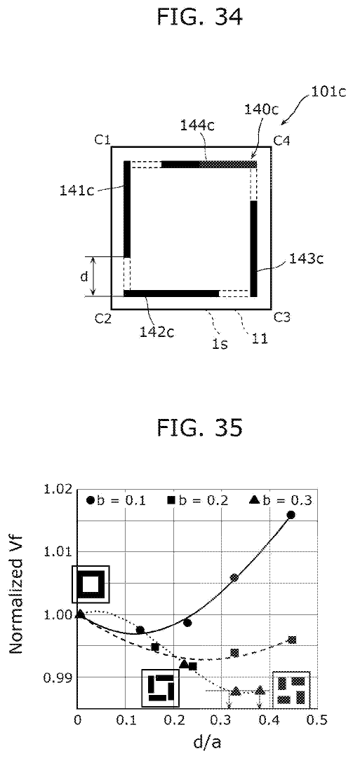

First, the configuration of the n-side contact region according to the present variation will be described with reference to FIG. 34. FIG. 34 is a plan view schematically illustrating the configuration of n-side contact region 140c of nitride semiconductor light-emitting element 101c according to the present variation. FIG. 34 illustrates n-side contact region 140c in a plan view of main surface 11a of substrate 11

As illustrated in FIG. 34, n-side contact region 140c according to the present variation includes first region 141c, second region 142c, third region 143c, and fourth region 144c. First region 141c is a linear region extending in one direction from first starting point S1 which is spaced apart from first corner portion C1. Second region 142c is a linear region extending in one direction from second starting point S2 which is spaced apart from second corner portion C2. Third region 143c is a linear region extending in one direction from third starting point S3 which is spaced apart from third corner portion C3. Fourth region 144c is a linear region extending in one direction from fourth starting point S4 which is spaced apart from fourth corner portion C4.

According to the present variation, first region 141c linearly extends from first starting point S1 to a predetermined point located between first starting point S1 and second starting point S2. Second region 142c is disposed on the extended line of first region 141c and spaced apart from first region 141c. Second region 142c linearly extends from second starting point S2 to a predetermined point located between second starting point S2 and third starting point S3. Third region 143c is disposed on the extended line of second region 142c and spaced apart from second region 142c. Third region 143c linearly extends from third starting point S3 to a predetermined point located between third starting point S3 and fourth starting point S4. Fourth region 144c is disposed on the extended line of third region 143c and spaced apart from third region 143c. Fourth region 144c linearly extends from fourth starting point S4 to a predetermined point located between fourth starting point S4 and first starting point S1. First region 141c is disposed on the extended line of fourth region 144c and spaced apart from fourth region 144c.

As described above, first region 141c, second region 142c, third region 143c, and fourth region 144c are spaced apart from each other. According to the present variation, first region 141c is spaced apart from second starting point S2 by distance d. In the same manner as first region 141c, second region 142c, third region 143c, and fourth region 144c are also spaced apart from third starting point S3, fourth starting point S4, and first starting point S1, respectively, by distance d. It should be noted that, according to the present variation, distance d by which the regions are spaced apart from one another is constant. However, distance d need not necessarily be constant.

With nitride semiconductor light-emitting element 101c according to the present variation that has the configuration as described above, the same advantageous effects as those of nitride semiconductor light-emitting element 101 according to Embodiment 2 are yielded as well.

Next, the relationship between forward voltage Vf and distance d by which the regions of n-side contact region 140c of nitride semiconductor light-emitting element 101c according to the present variation are spaced apart from one another will be described with reference to FIG. 35. It should be noted that, in the following description, the experimental results in the case where: r1=r2=r3=r4; and ratio r1/a is the ratio when normalized forward voltage Vf has a minimal value (indicated by the triangle in FIG. 30) will be described. FIG. 35 is a graph indicating the relationship between normalized forward voltage Vf and ratio d/a. Ratio d/a is the ratio of distance d by which the regions are spaced apart from one another to length a of the shorter side of semiconductor stack structure 1s of nitride semiconductor light-emitting element 101c according to the present variation. It should be noted that the horizontal axis of the graph in FIG. 35 indicates ratio d/a and the vertical axis indicates normalized forward voltage Vf. In FIG. 35, the experimental results when proportion b of the area of n-side contact region 140c to the area of semiconductor stack structure 1s is 0.1, 0.2, and 0.3 are indicated by a circle, a square, and a triangle, respectively. Normalized forward voltage Vf represents the ratio of forward voltage Vf to forward voltage Vf of the case where ratio d/a is 0. In this experiment, ratio d/a, etc. were varied under the condition that the area of the n-side contact region is equal.

As indicated schematically in the graph of FIG. 35, as ratio d/a on the horizontal axis decreases, each region of n-side contact region 140c becomes narrower and longer, and as ratio d/a increases, each region of n-side contact region 140c becomes wider and shorter.

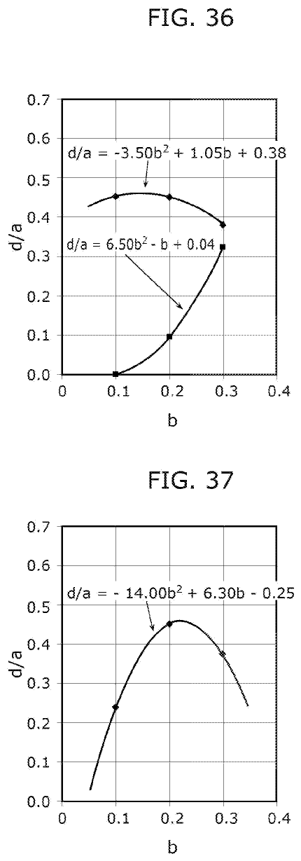

Here, the range of ratio d/a which allows normalized forward voltage Vf to be smaller than in the case where ratio d/a is at the maximum (i.e., the maximum value for the width of each region to be placeable) will be considered. For example, as illustrated in FIG. 35, when proportion b is 0.3, the maximum value of ratio d/a is approximately 0.38, and normalized forward voltage Vf can be smaller than in the case where ratio d/a is at the maximum, in the range where ratio d/a is greater than or equal to approximately 0.33 and less than approximately 0.38. In the same manner, when proportion b is 0.1 and 0.2, the minimum value and the maximum value of the range of ratio d/a that allows normalized forward voltage Vf to be smaller than in the case where ratio d/a is at the maximum can also be obtained. The minimum value and the maximum value of the range of ratio d/a obtained as described above will be described with reference to FIG. 36. FIG. 36 is a graph indicating the relationship between proportion b and the minimum and maximum values of ratio d/a of nitride semiconductor light-emitting element 101c according to the present variation. Proportion b is the proportion of the area of n-side contact region 140c to the area of semiconductor stack structure 1s. Ratio d/a is the ratio of distance d by which the regions are spaced apart from one another to length a of the shorter side of semiconductor stack structure 1s. In FIG. 36, the minimum value and the maximum value of the range of ratio d/a are indicated by a square and a diamond, respectively.

As illustrated in FIG. 36, when the relationship between proportion b and the minimum value of ratio d/a is approximated by a quadratic function of proportion b, the relationship can be represented by the following expression (25) when b is greater than or equal to 0.1 and less than or equal to 0.3.

d/a=6.50b²−b+0.04 (25)

In addition, when the relationship between proportion b and the maximum value of ratio d/a is approximated by a quadratic function of proportion b, the relationship can be represented by the following expression (26) when b is greater than or equal to 0.1 and less than or equal to 0.3.

d/a=−3.50b²+1.05b+0.38 (26)

Accordingly, distance d, length a of the shorter side of semiconductor stack structure 1s, and proportion b may satisfy the following expressions (27) to (28).

0.1≤b≤0.3 (27)

6.50b²−b+0.04<d/a<−3.50b²+1.05b+0.38 (28)

This allows forward voltage Vf of nitride semiconductor light-emitting element 101c to be less than forward voltage Vf of the case where ratio d/a is at the maximum.

Next, the range of ratio d/a which allows normalized forward voltage Vf as indicated in FIG. 35 to be less than or equal to 1 will be considered. As illustrated in FIG. 35, normalized forward voltage Vf is 1 when ratio d/a is 0, and normalized forward voltage Vf is less than or equal to 1 in the range where ratio d/a is greater than 0 and less than or equal to a predetermined value. Here, the maximum value of the range of ratio d/a in which the normalized forward voltage Vf is less than or equal to 1 will be explained with reference to FIG. 37.

FIG. 37 is a graph indicating the relationship between proportion b of the area of n-side contact region 140c to the area of semiconductor stack structure 1s of nitride semiconductor light-emitting element 101c according to the present variation and the maximum value of ratio d/a which allows normalized forward voltage Vf to be less than or equal to 1. The horizontal axis of the graph in FIG. 37 indicates proportion b, and the vertical axis indicates ratio d/a. In FIG. 37, the maximum value of ratio d/a which allows normalized forward voltage Vf to be less than or equal to 1 is indicated by a diamond.

As illustrated in FIG. 37, when the relationship between proportion b and the maximum value of ratio d/a which allows normalized forward voltage Vf to be less than or equal to 1 is approximated by a quadratic function of proportion b, the relationship can be represented by the following expression (29) when b is greater than or equal to 0.1 and less than or equal to 0.3.

d/a=−14.00b²+6.30b−0.25 (29)

Accordingly, distance d, length a of the shorter side of semiconductor stack structure 1s and proportion b may satisfy the following expressions (30) and (31).

0.1≤b≤0.3 (30)

d/a<−14.00b²+6.30b−0.25 (31)

This allows forward voltage Vf of nitride semiconductor light-emitting element 101c to be less than forward voltage Vf of the case where ratio d/a is 0.

### 2-6. Variation 4

Next, a nitride semiconductor light-emitting element according to Variation 4 of Embodiment 2 will be described. The nitride semiconductor light-emitting element according to the present variation differs from nitride semiconductor light-emitting element 101 according to Embodiment 2 in that the n-side contact region includes 8 regions, etc. The following describes the nitride semiconductor light-emitting element according to the present variation focusing on the differences from nitride semiconductor light-emitting element 101 according to Embodiment 2.

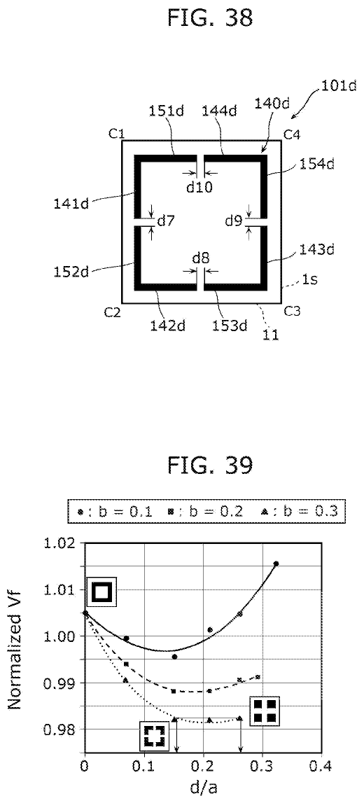

First, the configuration of the n-side contact region according to the present variation will be described with reference to FIG. 38. FIG. 38 is a plan view schematically illustrating the configuration of n-side contact region 140d of nitride semiconductor light-emitting element 101d according to the present variation. FIG. 38 illustrates n-side contact region 140d in a plan view of main surface 11a of substrate 11.

As illustrated in FIG. 38, n-side contact region 140d according to the present variation includes first region 141d, second region 142d, third region 143d, fourth region 144d, first additional region 151d, second additional region 152d, third additional region 153d, and fourth additional region 154d.

First region 141d is a linear region extending in one direction from first starting point S1 which is spaced apart from first corner portion C1. Second region 142d is a linear region extending in one direction from second starting point S2 which is spaced apart from second corner portion C2. Third region 143d is a linear region extending in one direction from third starting point S3 which is spaced apart from third corner portion C3. Fourth region 144d is a linear region extending in one direction from fourth starting point S4 which is spaced apart from fourth corner portion C4.

First additional region 151d is a linear region extending from first starting point S1 in a direction different from first a direction of region 141d. Second additional region 152d is a linear region extending from second starting point S2 in a direction different from a direction of second region 142d. Third additional region 153d is a linear region extending from third starting point S3 in a direction different from a direction of third region 143d. Fourth additional region 154d is a linear region extending from fourth starting point S4 in a direction different from a direction of fourth region 144d.

Second additional region 152d is disposed on the extended line of first region 141d and spaced apart from first region 141d, and extends in the same direction as first region 141d. Third additional region 153d is disposed on the extended line of second region 142d and spaced apart from second region 142d, and extends in the same direction as second region 142d. Fourth additional region 154d is disposed on the extended line of third region 143d and spaced apart from third region 143d, and extends in the same direction as third region 143d. First additional region 151d is disposed on the extended line of fourth region 144d and spaced apart from fourth region 144d, and extends in the same direction as fourth region 144d.

As illustrated in FIG. 38, distance d7 between first region 141d and second additional region 152d, distance d8 between second region 142d and third additional region 153d, distance d9 between third region 143d and fourth additional region 154d, and distance d10 between fourth region 144d and first additional region 151d are not particularly limited. According to the present embodiment, distances d7 to d10 are equal. In addition, the lengths of first region 141d, second region 142d, third region 143d, fourth region 144d, first additional region 151d, second additional region 152d, third additional region 153d, and fourth additional region 154d are equal to one another.

It should be noted that second additional region 152d may be identified as one example of the second region. In this case, the second region is disposed on the extended line of first region 141d and spaced apart from first region 141d, and extends in the same direction as first region 141d.

With nitride semiconductor light-emitting element 101d according to the present variation that has the configuration as described above, the same advantageous effects as those of nitride semiconductor light-emitting element 101 according to Embodiment 2 are yielded as well.

Next, the relationship between forward voltage Vf and distances d7 to d10 by which the regions of n-side contact region 140d of nitride semiconductor light-emitting element 101d according to the present variation are spaced apart will be described with reference to FIG. 39. It should be noted that, in the following description, the experimental results in the case where: d7=d8=d9=d10; r1=r2=r3=r4; and ratio r1/a is the ratio when normalized forward voltage Vf has a minimal value (indicated by a triangle in FIG. 30) will be described. FIG. 39 is a graph indicating the relationship between forward voltage Vf and ratio d/a. Ratio d/a is the ratio of distance d by which the regions are spaced apart to length a of the shorter side of semiconductor stack structure 1s of nitride semiconductor light-emitting element 101d according to the present variation. It should be noted that the horizontal axis of the graph in FIG. 39 indicates ratio d/a and the vertical axis indicates normalized forward voltage Vf. In FIG. 39, the experimental results when proportion b of the area of n-side contact region 140d to the area of semiconductor stack structure 1s is 0.1, 0.2, and 0.3 are indicated by a circle, a square, and a triangle, respectively. Standardized forward voltage Vf represents the ratio of forward voltage Vf to forward voltage Vf when ratio d/a is 0. In this experiment, ratio d/a, etc. were varied under the condition that the area of the n-side contact region is equal.

As indicated schematically in the graph of FIG. 39, as ratio d/a on the horizontal axis becomes smaller, each region of n-side contact region 140d becomes narrower and longer, and as ratio d/a increases, each region of n-side contact region 140d becomes wider and shorter.

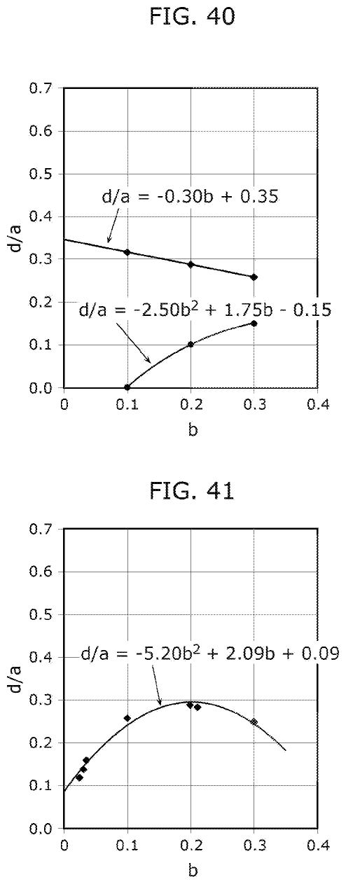

Here, the range of ratio d/a which allows normalized forward voltage Vf to be smaller than in the case where ratio d/a is at the maximum (i.e., the maximum value for the width of each region to be placeable) will be considered. For example, as illustrated in FIG. 39, when proportion b is 0.3, the maximum value of ratio d/a is approximately 0.26, and normalized forward voltage Vf can be smaller than in the case where ratio d/a is at the maximum, in the range where ratio d/a is greater than or equal to approximately 0.15 and less than approximately 0.26. In the same manner, when proportion b is 0.1 and 0.2, the minimum value and the maximum value of the range of ratio d/a that allows normalized forward voltage Vf to be smaller than in the case where ratio d/a is at the maximum can also be obtained. The minimum value and the maximum value of the range of ratio d/a obtained in this manner will be described with reference to FIG. 40. FIG. 40 is a graph indicating the relationship between proportion b and the minimum and maximum values of ratio d/a of nitride semiconductor light-emitting element 101d according to the present variation. Proportion b is the proportion of the area of n-side contact region 140d to the area of semiconductor stack structure 1s. Ratio d/a is the ratio of distance d by which the regions are spaced apart to length a of the shorter side of semiconductor stack structure 1s. In FIG. 40, the minimum value and the maximum value of the range of ratio d/a are indicated by a circle and a diamond, respectively.

As illustrated in FIG. 40, when the relationship between proportion b and the minimum value of ratio d/a is approximated by a quadratic function of proportion b, the relationship can be represented by the following expression (32) when b is greater than or equal to 0.1 and less than or equal to 0.3. d/a=−2.5b²+1.75b−0.15 (32)

In addition, when the relationship between proportion b and the maximum value of ratio d/a is approximated by a linear function of proportion b, the relationship can be represented by the following expression (33) when b is less than or equal to 0.3.

d/a=−0.30b+0.35 (33)

Accordingly, distances d7 to d10, length a of the shorter side of semiconductor stack structure 1s, and proportion b may satisfy the following expressions (34) to (36).

0.1≤b≤0.3 (34)

d7=d8=d9=d10 (35)

−2.5b²+1.75b−0.15<d7/a<−0.30b+0.35 (36)

This allows forward voltage Vf of nitride semiconductor light-emitting element 101d to be less than forward voltage Vf of the case where ratio d/a is at the maximum.

Next, the range of ratio d/a which allows normalized forward voltage Vf as indicated in FIG. 39 to be less than or equal to 1 will be considered. As illustrated in FIG. 39, normalized forward voltage Vf is 1 when ratio d/a is 0, and normalized forward voltage Vf is less than or equal to 1 in the range where ratio d/a is greater than 0 and less than or equal to a predetermined value. Here, the maximum value of the range of ratio d/a in which the normalized forward voltage Vf is less than or equal to 1 will be explained with reference to FIG. 41.

FIG. 41 is a graph indicating the relationship between proportion b of the area of n-side contact region 140d to the area of semiconductor stack structure 1s of nitride semiconductor light-emitting element 101d according to the present variation and the maximum value of ratio d/a which allows normalized forward voltage Vf to be less than or equal to 1. The horizontal axis of the graph in FIG. 41 indicates proportion b, and the vertical axis indicates ratio d/a. In FIG. 41, the maximum value of ratio d/a which allows normalized forward voltage Vf to be less than or equal to 1 is indicated by a diamond.

As illustrated in FIG. 41, when the relationship between proportion b and the maximum value of ratio d/a which allows normalized forward voltage Vf to be less than or equal to 1 is approximated by a quadratic function of proportion b, the relationship can be represented by the following expression (37) when b is less than or equal to 0.3.

d/a=−5.20b²+2.09b+0.09 (37)

Accordingly, distances d7 to d10, length a of the shorter side of semiconductor stack structure 1s, and proportion b may satisfy the following expressions (38) to (40).

b≤0.3 (38)

d7=d8=d9=d10 (39)

0<d7/a<−5.20b²+2.09b+0.09 (40)

This allows forward voltage Vf of nitride semiconductor light-emitting element 101d to be less than forward voltage Vf of the case where ratio d/a is 0.

### 2-7. Variation 5

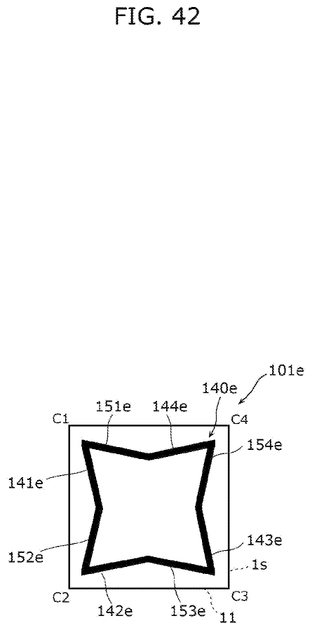

Next, a nitride semiconductor light-emitting element according to Variation 5 of Embodiment 2 will be described. The nitride semiconductor light-emitting element according to the present variation differs from nitride semiconductor light-emitting element 101 according to Embodiment 2 in that the n-side contact region includes 8 regions, and that the regions extend in directions different from one another, etc. The following describes the nitride semiconductor light-emitting element according to the present variation focusing on the differences from nitride semiconductor light-emitting element 101 according to Embodiment 2, with reference to FIG. 42.

FIG. 42 is a plan view schematically illustrating the configuration of n-side contact region 140e of nitride semiconductor light-emitting element 101e according to the present variation. FIG. 42 illustrates n-side contact region 140e in a plan view of main surface 11a of substrate 11.

As illustrated in FIG. 42, n-side contact region 140e according to the present variation includes first region 141e, second region 142e, third region 143e, fourth region 144e, first additional region 151e, second additional region 152e, third additional region 153e, and fourth additional region 154e.

First region 141e is a linear region extending in one direction from first starting point S1 which is spaced apart from first corner portion C1. Second region 142e is a linear region extending in one direction from second starting point S2 which is spaced apart from second corner portion C2. Third region 143e is a linear region extending in one direction from third starting point S3 which is spaced apart from third corner portion C3. Fourth region 144e is a linear region extending in one direction from fourth starting point S4 which is spaced apart from fourth corner portion C4.

First additional region 151e is a linear region extending from first starting point S1 in a direction different from a direction of first region 141e. Second additional region 152e is a linear region extending from second starting point S2 in a direction different from a direction of second region 142e. Third additional region 153e is a linear region extending from third starting point S3 in a direction different from a direction of third region 143e. Fourth additional region 154e is a linear region extending from fourth starting point S4 in a direction different from a direction of fourth region 144e.

First region 141e and second additional region 152e are connected to each other, second region 142e and third additional region 153e are connected to each other, third region 143e and fourth additional region 154e are connected to each other, and fourth region 144e and first additional region 151e are connected to each other.

According to the present variation, second additional region 152e extends in a direction different from a direction of first region 141e. Third additional region 153e extends in a direction different from a direction of second region 142e. Fourth additional region 154e extends in a direction different from a direction of third region 143e. First additional region 151e extends in a direction different from a direction of fourth region 144e.

It should be noted that first region 141e and second additional region 152e may extend in the same direction, second region 142e and third additional region 153e may extend in the same direction, third region 143e and fourth additional region 154e may extend in the same direction, and fourth region 144e and first additional region 151e may extend in the same direction. In this case, nitride semiconductor light-emitting element 101e according to the present variation has the same configuration as nitride semiconductor light-emitting element 101 according to Embodiment 2.

In nitride semiconductor light-emitting element 101e according to the present variation that has the configuration as described above, the same advantageous effects as those of nitride semiconductor light-emitting element 101 according to Embodiment 2 are yielded as well.

### Embodiment 3

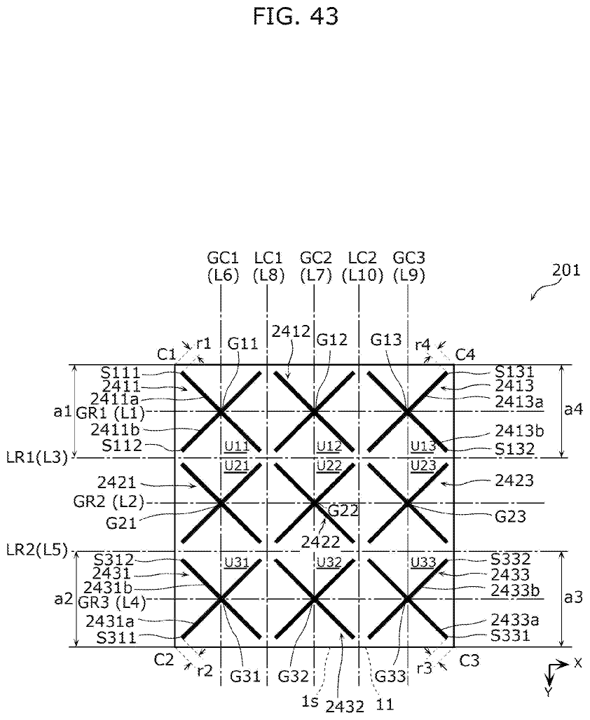

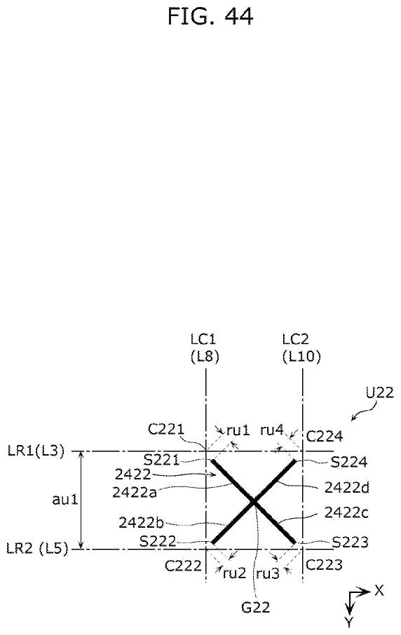

A nitride semiconductor light-emitting element according to Embodiment 3 will be described. The nitride semiconductor light-emitting element according to the present embodiment differs mainly from the nitride semiconductor light-emitting element of Embodiment 1 in that the nitride semiconductor light-emitting element according to the present embodiment includes a plurality of n-side contact regions arranged in a matrix. The following describes the nitride semiconductor light-emitting element according to the present embodiment focusing on the differences from nitride semiconductor light-emitting element 1 according to Embodiment 1, with reference to FIG. 43 and FIG. 44.

FIG. 43 is a plan view schematically illustrating the configuration of the plurality of n-side contact regions of nitride semiconductor light-emitting element 201 according to the present embodiment. FIG. 43 illustrates a plan view of main surface 11a of substrate 11 in a plan view.

As illustrated in FIG. 43, in nitride semiconductor light-emitting element 201 according to the present embodiment, in the plan view of main surface 11a of substrate 11, semiconductor stack structure 1s has a rectangular shape, and includes first corner portion C1, second corner portion C2, third corner portion C3, and fourth corner portion C4. Second corner portion C2 is a corner portion disposed on the same side of the rectangular outer edge of semiconductor stack structure 1s as first corner portion C1. Third corner portion C3 is a corner portion disposed diagonally to first corner portion C1 on the rectangular outer edge of semiconductor stack structure 1s. Fourth corner portion C4 is a corner portion disposed diagonally to second corner portion C2 the rectangular outer edge of semiconductor stack structure 1s.

Nitride semiconductor light-emitting element 201 includes a plurality of n-side contact regions arranged in a matrix of at least three rows and three columns. According to the present embodiment, nitride semiconductor light-emitting element 201 includes nine n-side contact regions arranged in a matrix of three rows and three columns, namely, 2411 to 2413, 2421 to 2423, and 2431 to 2433. Each of the n-side contact regions consists of a single region, i.e., a region that is continuously formed without separation. It should be noted that nitride semiconductor light-emitting element 201 according to the present embodiment includes a plurality of n-side contact electrodes each of which corresponds to a corresponding one of the plurality of n-side contact regions.

Each of the n-side contact regions will be described in detail below.

### 3-1. N-Side Contact Region 2411

First, n-side contact region 2411 will be described. The nine n-side contact regions according to the present embodiment includes: n-side contact region 2411 that is one example of a first n-side contact region disposed in closest proximity to first corner portion C1; n-side contact region 2412 that is one example of a first Xn-side contact region disposed adjacent to the first n-side contact region in the row direction (i.e., in the horizontal direction of FIG. 43); and n-side contact region 2421 that is one example of a first Yn-side contact region disposed adjacent to the first n-side contact region in the column direction (i.e., in the vertical direction of FIG. 43).

N-side contact region 2411 is disposed in unit U11 that is one example of a first unit having a rectangular shape and enclosed by: straight line LC1 that is equidistant from center of gravity G11 of n-side contact region 2411 and center of gravity G12 of n-side contact region 2412; straight line LR1 that is equidistant from center of gravity G11 of n-side contact region 2411 and center of gravity G21 of n-side contact region 2421; and the outer edge of semiconductor stack structure 1s.

N-side contact region 2411 includes first region 2411a having a linear shape and extending in one direction from first starting point S111 which is spaced apart from first corner portion C1. A p-side contact region is disposed between first starting point S111 and first corner portion C1, and distance r1 between first corner portion C1 and first starting point S111 is less than or equal to 0.26 times length a1 of the shorter side of unit U11.

Nitride semiconductor light-emitting element 201 includes first region 2411a as described above, and thus it is possible to reduce the forward voltage in unit U11 in the same manner as nitride semiconductor light-emitting element 1 according to Embodiment 1. As a result, it is possible to reduce the forward voltage in the entirety of nitride semiconductor light-emitting element 201.

In addition, n-side contact region 2411 includes region 2411b having a linear shape and extending in one direction from starting point S112 which is spaced apart from the corner portion disposed on the same side of unit U11 as first corner portion C1. Here, the corner portion disposed on the same side of unit U11 as first corner portion C1 is the intersection of the outer edge of semiconductor stack structure 1s and straight line LR1. P-side contact region 60 is disposed between starting point S112 and the intersection of the outer edge of semiconductor stack structure is and straight line LR1, and the distance between starting point S112 and the intersection of the outer edge of semiconductor stack structure 1s and straight line LR1 is less than or equal to 0.26 times length a1 of the shorter side of unit U11.

Nitride semiconductor light-emitting element 201 includes region 2411b as described above, and thus it is possible to further reduce the forward voltage in unit U11.

### 3-2. N-Side Contact Region 2431, 2433, and 2413

Next, n-side contact regions 2431, 2433, and 2413 will be described. The nine n-side contact regions include: n-side contact region 2431 that is one example of a second n-side contact region disposed in closest proximity to second corner portion C2; n-side contact region 2432 that is one example of a second Xn-side contact region disposed adjacent to the second n-side contact region in the row direction; and a second Yn-side contact region disposed adjacent to the second n-side contact region in the column direction.

In addition, the nine n-side contact regions include: n-side contact region 2433 that is one example of a third n-side contact region disposed in closest proximity to third corner portion C3; n-side contact region 2432 that is one example of a third Xn-side contact region disposed adjacent to the third n-side contact region in the row direction; and n-side contact region 2423 that is one example of a third Yn-side contact region disposed adjacent to the third n-side contact region in the column direction.

In addition, the nine n-side contact regions include: n-side contact region 2413 that is one example of a fourth n-side contact region disposed in closest proximity to fourth corner portion C4; n-side contact region 2412 that is one example of a fourth Xn-side contact region disposed adjacent to the fourth n-side contact region in the row direction; and n-side contact region 2423 that is one example of a fourth Yn-side contact region disposed adjacent to the fourth n-side contact region in the column direction.

N-side contact region 2431 is disposed in unit U31 that is one example of a second unit having a rectangular shape and enclosed by: straight line LC1 that is equidistant from center of gravity G31 of n-side contact region 2431 and center of gravity G32 of n-side contact region 2432; straight line LR2 that is equidistant from center of gravity G31 of n-side contact region 2431 and center of gravity G21 of n-side contact region 2421; and the outer edge of semiconductor stack structure 1s. It should be noted that, according to the present embodiment, the straight line equidistant from center of gravity G11 and center of gravity G12 and the straight line equidistant from center of gravity G31 and center of gravity G32 are the same straight line LC1.

N-side contact region 2433 is disposed in unit U33 that is one example of a third unit having a rectangular shape and enclosed by: straight line LC2 that is equidistant from center of gravity G33 of n-side contact region 2433 and center of gravity G32 of n-side contact region 2432; straight line LR2 that is equidistant from center of gravity G33 of n-side contact region 2433 and center of gravity G23 of n-side contact region 2423; and the outer edge of semiconductor stack structure 1s. It should be noted that, according to the present embodiment, the straight line equidistant from center of gravity G21 and center of gravity G31 and the straight line equidistant from center of gravity G23 and center of gravity G33 are the same straight line LR2.

N-side contact region 2413 is disposed in unit U13 that is one example of a fourth unit having a rectangular shape and enclosed by: straight line LC2 that is equidistant from center of gravity G13 of n-side contact region 2413 and center of gravity G12 of n-side contact region 2412; straight line LR1 that is equidistant from center of gravity G13 of n-side contact region 2413 and center of gravity G23 of n-side contact region 2423; and the outer edge of semiconductor stack structure 1s. It should be noted that, according to the present embodiment, the straight line equidistant from center of gravity G33 and center of gravity G32 and the straight line equidistant from center of gravity G13 and center of gravity G12 are the same straight line LC2. It should be noted that, according to the present embodiment, the straight line equidistant from center of gravity G11 and center of gravity G21 and the straight line equidistant from center of gravity G13 and center of gravity G23 are the same straight line LR1.

N-side contact region 2431 includes second region 2431a having a linear shape and extending in one direction from second starting point S311 which is spaced apart from second corner portion C2. N-side contact region 2433 includes third region 2433a having a linear shape and extending in one direction from third starting point S331 which is spaced apart from third corner portion C3. N-side contact region 2413 includes fourth region 2413a having a linear shape and extending in one direction from fourth starting point S131 which is spaced apart from fourth corner portion C4.

P-side contact region 60 is disposed between second starting point S311 and second corner portion C2, between third starting point S331 and third corner portion C3, and between fourth starting point S131 and fourth corner portion C4.

Distance r2 between second corner portion C2 and second starting point S311 is less than or equal to 0.26 times length a2 of the shorter side of unit U31, distance r3 between third corner portion C3 and third starting point S331 is less than or equal to 0.26 times length a3 of the shorter side of unit U33, distance r4 between fourth corner portion C4 and fourth starting point S131 is less than or equal to 0.26 times length a4 of the shorter side of the fourth unit.

Nitride semiconductor light-emitting element 201 includes second region 2431a, third region 2433a, and fourth region 2413a as described above, and thus it is possible to reduce the forward voltage in units U31, U33, and U13 in the same manner as nitride semiconductor light-emitting element 1 according to Embodiment 1. As a result, it is possible to reduce the forward voltage in the entirety of nitride semiconductor light-emitting element 201.

N-side contact region 2431 includes region 2431b having a linear shape and extending in one direction from starting point S312 which is spaced apart from the corner portion disposed on the same side of unit U31 as second corner portion C2. Here, the corner portion disposed on the same side of unit U31 as second corner portion C2 is the intersection of the outer edge of semiconductor stack structure 1s and straight line LR2. P-side contact region 60 is disposed between starting point S312 and the intersection of the outer edge of semiconductor stack structure 1s and straight line LR2, and the distance between starting point S312 and the intersection of the outer edge of semiconductor stack structure 1s and straight line LR2 is less than or equal to 0.26 times length a2 of the shorter side of unit U31.

N-side contact region 2433 includes region 2433b having a linear shape and extending in one direction from starting point S332 which is spaced apart from the corner portion disposed on the same side of unit U33 as third corner portion C3. Here, the corner portion disposed on the same side of unit U33 as third corner portion C3 is the intersection of the outer edge of semiconductor stack structure 1s and straight line LR2. P-side contact region 60 is disposed between starting point S332 and the intersection of the outer edge of semiconductor stack structure 1s and straight line LR2, and the distance between starting point S332 and the intersection of the outer edge of semiconductor stack structure 1s and straight line LR2 is less than or equal to 0.26 times length a3 of the shorter side of unit U33.

N-side contact region 2413 includes region 2413b having a linear shape and extending in one direction from starting point S132 which is spaced apart from the corner portion disposed on the same side of unit U13 as fourth corner portion C4. Here, the corner portion disposed on the same side of unit U13 as fourth corner portion C4 is the intersection of the outer edge of semiconductor stack structure 1s and straight line LR1. P-side contact region 60 is disposed between starting point S132 and the intersection of the outer edge of semiconductor stack structure 1s and straight line LR1, and the distance between starting point S132 and the intersection of the outer edge of semiconductor stack structure 1s and straight line LR1 is less than or equal to 0.26 times length a4 of the shorter side of unit U13.

Nitride semiconductor light-emitting element 201 includes regions 2431b, 2433b, and 2413b as described above, and thus it is possible to further reduce the forward voltage in the entirety of nitride semiconductor light-emitting element 201.

According to the present embodiment, each of units U11, U31, U33, and U13 has the same configuration as nitride semiconductor light-emitting element 1 according to Embodiment 1. In other words, in unit U11, (i) the distance from the intersection of straight line LR1 and straight line LC1 to first region 2411a and (ii) the distance from the intersection of the outer edge of semiconductor stack structure 1s and straight line LC1 to region 2411b are each less than or equal to 0.26 times length a1 of the shorter side of unit U11. In unit U31, (i) the distance from the intersection of straight line LR2 and straight line LC1 to second region 2431a and (ii) the distance from the intersection of the outer edge of semiconductor stack structure is and straight line LC1 to region 2431b are each less than or equal to 0.26 times length a2 of the shorter side of unit U31. In unit U33, (i) the distance from the intersection of straight line LR2 and straight line LC2 to third region 2433a and (ii) the distance from the intersection of the outer edge of semiconductor stack structure 1s and straight line LC2 to region 2433b are each less than or equal to 0.26 times length a3 of the shorter side of unit U33. In unit U13, (i) the distance from the intersection of straight line LR1 and straight line LC2 to fourth region 2413a and (ii) the distance from the intersection of the outer edge of semiconductor stack structure 1s and straight line LC2 to region 2413b are each less than or equal to 0.26 times length a4 of the shorter side of unit U13. In each of the units, the n-side contact region has an X shape as described above, and the proportion of the area of the n-side contact region to the area of the unit is less than or equal to 0.3. Accordingly, it is possible to reduce the forward voltage in the same manner as Embodiment 1. In addition, the proportion of the area of the nine n-side contact regions to the area of semiconductor stack structure 1s may be less than or equal to 0.1. According to this configuration, it is possible to increase the light emission output of nitride semiconductor light-emitting element 201 in the same manner as Embodiment 1.

### 3-3. N-Side Contact Region 2422

Next, unit U22 that includes, among the nine n-side contact regions illustrated in FIG. 43, n-side contact region 2422 positioned at the center of the matrix of three rows and three columns will be described with reference to FIG. 44 in addition to FIG. 43. Unit U22 is one example of a unit disposed in the i-th row (2≤i≤N−1) and the j-th column (2≤j≤M−1) in the plurality of n-side contact regions arranged in a matrix of N rows and M columns (N≥3, M≥3). FIG. 44 is a plan view schematically illustrating the configuration of unit U22 including the n-side contact region locate at the center among the plurality of n-side contact regions according to the present embodiment. FIG. 44 illustrates only the portion of unit U22 in detail out of FIG. 43.

As illustrated in FIG. 43, according to the present embodiment, the nine n-side contact regions are arranged in a matrix of three rows and three columns. The centers of gravity of three n-side contact regions disposed in each of the first to third rows among the nine n-side contact regions are on a straight line. The centers of gravity of three n-side contact regions disposed in each of the first to third columns among the nine n-side contact regions are on a straight line.

As illustrated in FIG. 43 and FIG. 44, unit U22 is enclosed by straight line LR1, straight line LR2, straight line LC1, and straight line LC2.

Straight line GR1 illustrated in FIG. 43 is a straight line connecting centers of gravity G11, G12, and G13 of three n-side contact regions 2411, 2412, and 2413, respectively, disposed in the first row. Straight line GR2 is a straight line connecting centers of gravity G21, G22, and G23 of three n-side contact regions 2421, 2422, and 2423, respectively, disposed in the second row. Straight line LR1 is a straight line that divides equally a region between straight line GR1 and straight line GR2. Straight line GR3 is a straight line connecting centers of gravity G31, G32, and G33 of three n-side contact regions 2431, 2432, and 2433, respectively, disposed in the third row. Straight line LR2 is a straight line that divides equally a region between straight line GR2 and straight line GR3. Straight line GC1 is a straight line connecting centers of gravity G11, G21, and G31 of three n-side contact regions 2411, 2421, and 2431, respectively, disposed in the first column. Straight line GC2 is a straight line connecting centers of gravity G12, G22, and G32 of three n-side contact regions 2412, 2422, and 2432, respectively, disposed in the second column, and straight line LC1 is a straight line that divides equally a region between straight line GC1 and straight line GC2. Straight line GC3 is a straight line connecting centers of gravity G13, G23, and G33 of three n-side contact regions 2413, 2423, and 2433, respectively, disposed in the third column. Straight line LC2 is a straight line that divides equally a region between straight line GC2 and straight line GC3.

As illustrated in FIG. 44, unit U22 includes: first unit corner portion C221 between straight line LR1 and straight line LC1 (i.e., the intersection of straight line LR1 and straight line LC1); second unit corner portion C222 between straight line LR2 and straight line LC1 (i.e., the intersection of straight line LR2 and straight line LC1); third unit corner portion C223 disposed diagonally to first unit corner portion C221 (i.e., the intersection of straight line LR2 and straight line LC2); and fourth unit corner portion C224 disposed diagonally to second unit corner portion C222 (i.e., the intersection of straight line LR1 and straight line LC2).

N-side contact region 2422 disposed in unit U22 includes first unit region 2422a having a linear shape and extending in one direction from first unit starting point S221 which is spaced apart from first unit corner portion C221, and p-side contact region 60 is disposed between first unit starting point S221 and first unit corner portion C221. Distance ru1 between first unit corner portion C221 and first unit starting point S221 is less than or equal to 0.26 times length au1 of the shorter side of unit U22.

Nitride semiconductor light-emitting element 201 includes first unit region 2422a as described above, and thus it is possible to reduce the forward voltage in unit U22 in the same manner as nitride semiconductor light-emitting element 1 according to Embodiment 1. As a result, it is possible to reduce the forward voltage in the entirety of nitride semiconductor light-emitting element 201.

N-side contact region 2422 disposed in unit U22 includes: second unit region 2422b having a linear shape and extending in one direction from second unit starting point S222 which is spaced apart from second unit corner portion C222; third unit region 2422c having a linear shape and extending in one direction from third unit starting point S223 which is spaced apart from third unit corner portion C223; and fourth unit region 2422d having a linear shape and extending in one direction from fourth unit starting point S224 which is spaced apart from fourth unit corner portion C224.

First unit region 2422a is connected to third unit region 2422c, and second unit region 2422b is connected to fourth unit region 2422d. First unit region 2422a, second unit region 2422b, third unit region 2422c, and fourth unit region 2422d are connected at center of gravity G22 of n-side contact region 2422. First unit region 2422a and third unit region 2422c extend in the same direction, and second unit region 2422b and fourth unit region 2422d extend in the same direction.

P-side contact region 60 is disposed between second unit starting point S222 and second unit corner portion C222, between third unit starting point S223 and third unit corner portion C223, and between fourth unit starting point S224 and fourth unit corner portion C224.

Distance ru2 between second unit corner portion C222 and second unit starting point S222, distance ru3 between third unit corner portion C223 and third unit starting point S223, and distance ru4 between fourth unit corner portion C224 and fourth unit starting point S224 are each less than or equal to 0.26 times length au1 of the shorter side of unit U22.

Nitride semiconductor light-emitting element 201 includes second unit region 2422b, third unit region 2422c, and fourth unit region 2422d as described above. In other words, unit U22 has the same configuration as nitride semiconductor light-emitting element 1 according to Embodiment 1. Accordingly, with nitride semiconductor light-emitting element 201, it is possible to further reduce the forward voltage in unit U22 in the same manner as nitride semiconductor light-emitting element 1 according to Embodiment 1. As a result, it is possible to further reduce the forward voltage in the entirety of nitride semiconductor light-emitting element 201.

### 3-4. N-Side Contact Region 2412, 2421, 2423, and 2432

Next, n-side contact regions other than those described above, i.e., n-side contact regions 2412, 2421, 2423, and 2432 will be described.

As illustrated in FIG. 43, n-side contact regions 2412, 2421, 2423, and 2432 are disposed in units U12, U21, U23, and U32, respectively. Unit U12 is a unit enclosed by the outer edge of semiconductor stack structure 1s, straight line LR1, straight line LC1, and straight line LC2. Unit U21 is a unit enclosed by straight line LR1, straight line LR2, the outer edge of semiconductor stack structure 1s, and straight line LC1. Unit U23 is a unit enclosed by straight line LR1, straight line LR2, straight line LC2, and the outer edge of semiconductor stack structure 1s. Unit U32 is a unit enclosed by straight line LR2, the outer edge of semiconductor stack structure 1s, straight line LC1, and straight line LC2.

The configuration of each of the n-side contact regions is not particularly limited, but each of the n-side contact regions according to the present embodiment has an X shape as with the other n-side contact regions described above, and the distance from the corner portion of the unit to the n-side contact region is less than or equal to 0.26 times the length of the shorter side of the unit. Nitride semiconductor light-emitting element 201 includes units U12, U21, U23, and U32 in which such n-side contact regions are disposed, and thus it is possible to further reduce the forward voltage in each of the units in the same manner as nitride semiconductor light-emitting element 1 according to Embodiment 1. As a result, it is possible to further reduce the forward voltage in the entirety of nitride semiconductor light-emitting element 201.

### 3-5. Other Configuration of N-Side Contact Region

In the present embodiment, nitride semiconductor light-emitting element 201 including nine n-side contact regions arranged in a matrix of three rows and three columns has been described, but the configuration of the plurality of n-side contact regions according to the present embodiment is not limited to this. The plurality of n-side contact regions may be arranged in a matrix of N rows and M columns (N≥3 and M≥3). Here, the centers of gravity of M n-side contact regions disposed in each of the first to N-th rows among the plurality of n-side contact regions are on a straight line. The centers of gravity of N n-side contact regions disposed in each of the first to M-th columns among the plurality of n-side contact regions are on a straight line.

In such a configuration as well, the n-side contact region disposed in the i-th row (2≤i≤N−1) and the j-th column (2≤j≤M−1) may have the following configuration in the same manner as n-side contact region 2422 described above.

The unit in which the n-side contact region disposed at the intersection of the i-th row and the j-th column is enclosed by third straight line L3, fifth straight line L5, eighth straight line L8, and tenth straight line L10 in the same manner as unit U22 illustrated in FIG. 44. Here, as illustrated in FIG. 44, straight line LR1, straight line LR2, straight line LC1, and straight line LC2 of nitride semiconductor light-emitting element 201 are examples of third straight line L3, fifth straight line L5, eighth straight line L8, and tenth straight line L10, respectively.

Third straight line L3 is a straight line that divides equally a region between first straight line L1 and second straight line L2. First straight line L1 connects the centers of gravity of M n-side contact regions disposed in the i−1-th row (2≤i≤N−1). Second straight line L2 connects the centers of gravity of M n-side contact regions disposed in the i-th row. Here, as illustrated in FIG. 43, straight line GR1 and straight line GR2 of nitride semiconductor light-emitting element 201 are examples of first straight line L1 and second straight line L2, respectively.

Fifth straight line L5 is a straight line that divides equally a region between second straight line L2 and fourth straight line L4 that connects the centers of gravity of M n-side contact regions disposed in the i+1-th row. Here, as illustrated in FIG. 43, straight line GR3 of nitride semiconductor light-emitting element 201 is one example of fourth straight line L4.

Eighth straight line L8 is a straight line that divides equally a region between sixth straight line L6 and seventh straight line L7. Sixth straight line connects the centers of gravity of N n-side contact regions disposed in the j−1-th column. Seventh straight line L7 connects the centers of gravity of N n-side contact regions disposed in the j-th column. Here, as illustrated in FIG. 43, straight line GC1 and straight line GC2 of nitride semiconductor light-emitting element 201 are examples of sixth straight line L6 and seventh straight line L7, respectively.

Tenth straight line L10 is a straight line that divides equally a region between seventh straight line L7 and ninth straight line L9 that connects the centers of gravity of N n-side contact regions disposed in the j+1-th column. Here, as illustrated in FIG. 43, straight line GC3 of nitride semiconductor light-emitting element 201 is one example of ninth straight line L9.

The unit in which the n-side contact region disposed at the intersection of i-th row and the j-th column includes: a first unit corner portion between third straight line L3 and eighth straight line L8; a second unit corner portion between fifth straight line L5 and eighth straight line L8; a third unit corner portion disposed diagonally to the first unit corner portion; and a fourth unit corner portion disposed diagonally to the second unit corner portion. Here, first unit corner portion C221, second unit corner portion C222, third unit corner portion C223, and fourth unit corner portion C224 illustrated in FIG. 44 are examples of the first unit corner portion, the second unit corner portion, the third unit corner portion, and the fourth unit corner portion, respectively.

The n-side contact region disposed in the above-described unit includes first unit region having a linear shape and extending in one direction from the first unit starting point that is spaced apart from the first unit corner portion. Here, first unit region 2422a illustrated in FIG. 44 is one example of the first unit region. P-side contact region 60 is disposed between the first unit starting point and the first unit corner portion. In addition, distance ru1 between the first unit corner portion and the first unit starting point is less than or equal to 0.26 times length au1 of the shorter side of the unit.

Among the plurality of n-side contact regions, n-side contact regions disposed in all of the units that satisfy 2≤i≤N−1, and 2≤j≤M−1 may each include the first unit region as described above.

According to this configuration, among the plurality of n-side contact regions arranged in a matrix, all of the n-side contact regions other than those disposed in outer edge portions include the first unit regions as described above. Accordingly, it is possible to reduce the forward voltage in the units other than those disposed in the outer edge portions in the same manner as nitride semiconductor light-emitting element 1 according to Embodiment 1.

The n-side contact region disposed in the above-described unit may include: a second unit region having a linear shape and extending in one direction from the second unit starting point that is spaced apart from the second unit corner portion; a third unit region having a linear shape and extending in one direction from the third unit starting point that is spaced apart from the third unit corner portion; and a fourth unit region having a linear shape and extending in one direction from the fourth unit starting point that is spaced apart from the fourth unit corner portion. Here, second unit region 2422b, third unit region 2422c; and fourth unit region 2422d illustrated in FIG. 44 are examples of the second unit region, the third unit region, and the fourth unit region, respectively. P-side contact region 60 is disposed between the second unit starting point and the second unit corner portion, between the third unit starting point and the third unit corner portion, and between the fourth unit starting point and the fourth unit corner portion.

Distance ru2 between the second unit corner portion and the second unit starting point, distance ru3 between the third unit corner portion and the third unit starting point, and distance ru4 between the fourth unit corner portion and the fourth unit starting point are each less than or equal to 0.26 times length au1 of the shorter side of the unit.

According to this configuration, among the plurality of n-side contact regions arranged in a matrix, all of the n-side contact regions other than those disposed in outer edge portions include the second to the fourth unit regions as described above. Accordingly, it is possible to further reduce the forward voltage in the units other than those disposed in the outer edge portions, in the same manner as nitride semiconductor light-emitting element 1 according to Embodiment 1.

It should be noted that, according to the present embodiment, the n-side contact region disposed in each unit has the configuration equivalent to the configuration of n-side contact region 40 according to Embodiment 1, but the configuration of each of the n-side contact regions according to the present embodiment is not limited to this. For example, each of the n-side contact regions may have the configuration equivalent to the configuration of Embodiment 1, Embodiment 2, and the variations of Embodiment 1 and Embodiment 2 as described above. For example, each of the plurality of n-side contact regions included in the nitride semiconductor light-emitting element may have a rectangular annular shape as indicated in Embodiment 2 and the variations thereof. In this case, as with Embodiment 2, proportion b of the area of the n-side contact region to the area of the semiconductor stack structure may satisfy b≤0.07. In addition, the plurality of n-side contact regions included in the nitride semiconductor light-emitting element may all have the same configuration, or may respectively have different configurations. In addition, among the plurality of n-side contact regions, one or more of the n-side contact regions may have a configuration different from the n-side contact region according to present disclosure. For example, one or more of the n-side contact regions may have a configuration equivalent to the configuration of the n-side contact region of the comparison example described in Embodiment 1.

### Embodiment 4

A nitride semiconductor light-emitting element according to Embodiment 4 will be described. The nitride semiconductor light-emitting element according to the present embodiment matches nitride semiconductor light-emitting element 1 according to Embodiment 1 in the configuration other than the configuration of the electrodes. The following describes the nitride semiconductor light-emitting element according to the present embodiment focusing on the differences from nitride semiconductor light-emitting element 1 according to Embodiment 1.

### 4-1. Overall Configuration

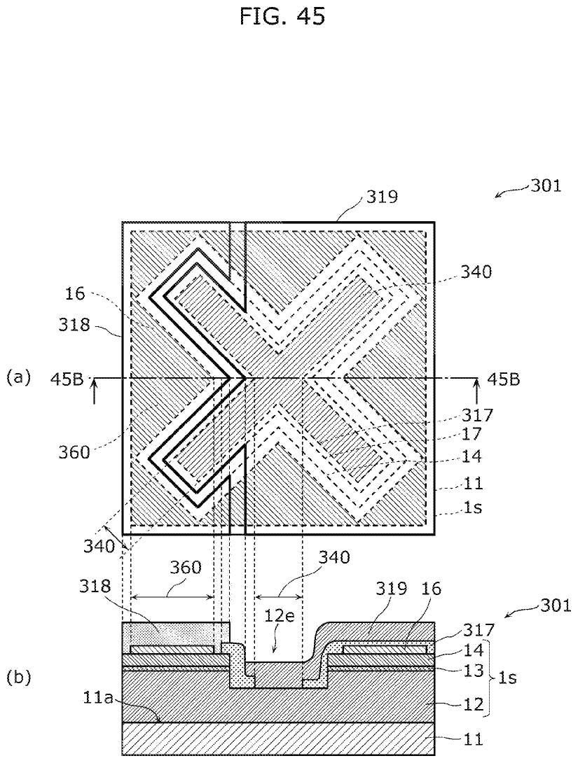

First, an overall configuration of the nitride semiconductor light-emitting element according to the present embodiment will be described with reference to FIG. 45. FIG. 45 is a diagram schematically illustrating the overall configuration of nitride semiconductor light-emitting element 301 according to the present embodiment. FIG. 45 illustrates plan view (a) and cross-sectional view (b) of nitride semiconductor light-emitting element 301. Cross-sectional view (b) of FIG. 45 illustrates a cross-section surface taken along line 45B-45B indicated in plan view (a).

As illustrated in FIG. 45, nitride semiconductor light-emitting element 301 includes substrate 11, semiconductor stack structure 1s, p-side contact electrode 16, insulating layer 317, n-side electrode 319, and cover electrode 318. According to the present embodiment, nitride semiconductor light-emitting element 301 is a flip-chip LED in which semiconductor stack structure 1s, n-side electrode 319, and p-side contact electrode 16 are arranged on a main surface 11a side of substrate 11. Main surface 11a is one of main surfaces of substrate 11.

P-side contact electrode 16 includes the same configuration as the configuration of p-side contact electrode 16 according to Embodiment 1. According to the present embodiment, p-side contact electrode 16 is in contact with P-type semiconductor layer 14 in p-side contact region 360. Insulating layer 317 and n-side electrode 319 are disposed above a portion of p-side contact electrode 16.

Insulating layer 317 is a layer that comprises an insulating material that covers continuously a portion of exposure portion 12e in which n-type semiconductor layer 12 is exposed and a portion above p-type semiconductor layer 14. Insulating layer 317 may include an opening portion defined above exposure portion 12e. Insulating layer 317 is also disposed in a region of a portion above p-side contact electrode 16. According to the present embodiment, insulating layer 317 covers at least half the region above p-side contact electrode 16. The configuration of insulating layer 317 is not particularly limited as long as insulating layer 317 is a layer that comprises an insulating material. According to the present embodiment, insulating layer 317 is a layer comprising SiO₂ and has a thickness of 1.0 μm.

N-side electrode 319 is one example of the n-side contact electrode that is disposed above n-type semiconductor layer 12 and is in contact with n-type semiconductor layer 12 in n-side contact region 340. N-side electrode 319 is disposed on exposure portion 12e in which n-type semiconductor layer 12 is exposed, and also disposed on a region of a portion above p-type semiconductor layer 14. More specifically, as illustrated in cross-sectional view (b) of FIG. 45, n-side electrode 319 covers continuously the portion from exposure portion 12e to a portion above p-type semiconductor layer 14 and p-side contact electrode 16. Insulating layer 317 is disposed between n-side electrode 319 and p-side contact electrode 16. According to this configuration, n-side electrode 319 and p-side contact electrode 16 are insulated. The configuration of n-side electrode 319 is not particularly limited as long as n-side electrode 319 is a conductive layer that makes ohmic contact with n-type semiconductor layer 12. According to the present embodiment, n-side electrode 319 is a stack structure including an Al layer having a thickness of 0.3 μm, a Ti layer having a thickness of 0.3 μm, and an Au layer having a thickness of 1.0 μm, which are stacked in sequence from the n-type semiconductor layer 12 side.

Cover electrode 318 is an electrode that covers p-side contact electrode 16. The configuration of cover electrode 318 is not particularly limited as long as cover electrode 318 is a conductive film. According to the present embodiment, cover electrode 318 is a stack structure including an Al layer having a thickness of 0.3 μm, a Ti layer having a thickness of 0.3 μm, and an Au layer having a thickness of 1.0 μm, which are stacked in sequence so as to cover a portion of p-side contact electrode 16. It should be noted that cover electrode 318 may have the configuration equivalent to the configuration of n-side electrode 319.

With nitride semiconductor light-emitting element 301 having the configuration as described above, the same advantageous effects as those of nitride semiconductor light-emitting element 1 according to Embodiment 1 are yielded as well.

### 4-2. Mounting Aspect

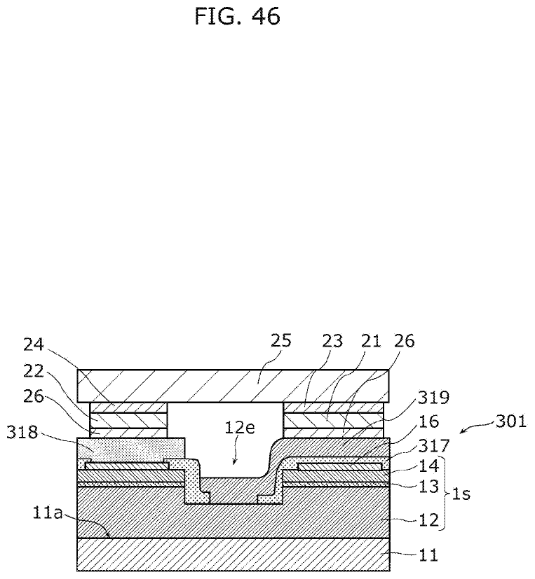

Next, A mounting aspect of nitride semiconductor light-emitting element 301 according to the present embodiment will be described. FIG. 46 is a cross sectional view schematically illustrating one example of the mounting aspect of nitride semiconductor light-emitting element 301 according to the present embodiment.

As illustrated in FIG. 46, in one example of the mounting aspect of nitride semiconductor light-emitting element 301 according to the present embodiment, nitride semiconductor light-emitting element 301 is flip-chip mounted on mounted board 25 in the same manner as nitride semiconductor light-emitting element 1 according to Embodiment 1.

Cover electrode 318 of nitride semiconductor light-emitting element 301 is electrically connected to p-side wiring electrode 24 of mounting substrate 25, and n-side electrode 319 is electrically connected to n-side wiring electrode 23 of mounting substrate 25.

Seed metal 26 and p-side connecting member 22 are disposed in sequence from the cover electrode 318 side between cover electrode 318 and p-side wiring electrode 24. Seed metal 26 and n-side connecting member 21 are disposed in sequence from the n-side electrode 319 side between n-side electrode 319 and n-side wiring electrode 23.

Nitride semiconductor light-emitting element 301 is mounted on mounting substrate 25 as described above. With the configuration as described above, an electric current is supplied to nitride semiconductor light-emitting element 301 from the mounting substrate 25 side, and light generated in active layer 13 is emitted from the substrate 11 side of nitride semiconductor light-emitting element 301.

### 4-3. Manufacturing Method

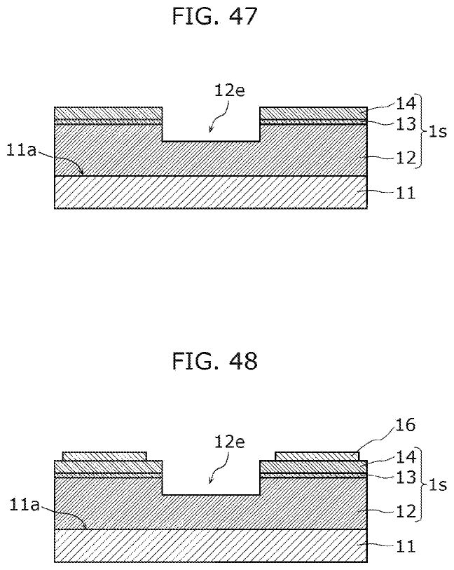

Next, the manufacturing method of nitride semiconductor light-emitting element 301 according to the present embodiment will be described with reference to FIG. 47 to FIG. 50. FIG. 47 to FIG. 50 are cross sectional views schematically illustrating the processes of manufacturing nitride semiconductor light-emitting element 301 according to the present embodiment.

First, as illustrated in FIG. 47, substrate 11 is prepared, and semiconductor stack structure 1s is stacked on main surface 11a that is one of the main surfaces of substrate 11, in the same manner as the manufacturing method of nitride semiconductor light-emitting element 1 according to Embodiment 1.

Then, as illustrated in FIG. 48, p-side contact electrode 16 having a predetermined shape is formed above p-type semiconductor layer 14, in the same manner as the manufacturing method of nitride semiconductor light-emitting element 1 according to Embodiment 1.

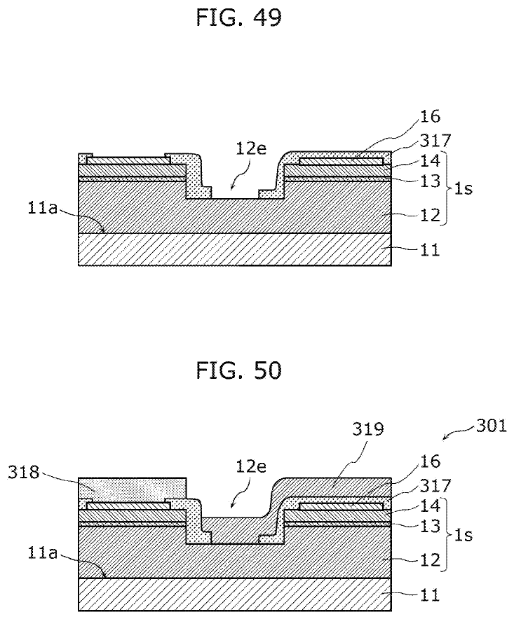

Then, as illustrated in FIG. 49, insulating layer 317 is formed. According to the present embodiment, an oxide film that comprises SiO₂ and has a thickness of 1.0 μm is deposited on the entire surface above semiconductor stack structure 1s and p-side contact electrode 16. Then, a resist pattern is formed in which portions of n-type semiconductor layer 12 and p-type semiconductor layer 14 are opened, and the resist is removed after the oxide film in the region in which the resist pattern is not formed is removed by wet etching. In this manner, insulating layer 317 in which the portions above exposure portion 12e and above p-side contact electrode 16 of the oxide film are removed is formed.

Then, as illustrated in FIG. 50, n-side electrode 319 having a predetermined shape is formed in the region in which insulating layer 317 is not disposed in exposure portion 12e, and in a portion of the region in which insulating layer 317 is disposed above p-type semiconductor layer 14. In addition, cover electrode 318 having a predetermined shape is formed in the region in which p-side contact electrode 16 is disposed above p-type semiconductor layer 14. Cover electrode 318 may also be disposed above insulating layer 317. N-side electrode 319 and cover electrode 318 may have an equivalent layer configuration and be concurrently formed. According to the present embodiment, a resist pattern is formed to cover the region between the region in which n-side electrode 319 is formed and the region in which cover electrode 318 is formed, and a stacked film including an Al film having a thickness of 0.3 μm, a Ti film having a thickness of 0.3 μm, and an Au film having a thickness of 1.0 μm is formed using an EB deposition method. Then, n-side electrode 319 including an Al layer, a Ti layer, and an Au layer and cover electrode 318 are formed by removing the resist and the stacked film above the resist by the lift-off method.

As described above, nitride semiconductor light-emitting element 301 according to the present embodiment can be manufactured.

### Variation, etc.

The nitride semiconductor light-emitting element according to the present disclosure has been described above based on the embodiments and the variations, but the present disclosure is not limited to the above embodiments and the variations.

For example, although each of the n-side contact regions includes the second region and the like in addition to the first region, it is sufficient if each of the n-side contact regions includes at least the first region.

In addition, in each of the embodiments and variations described above, the configuration of the first region extending from the first starting point and the configuration of the first region and the first additional region extending from the first starting point have been described, but the configuration of the region extending from the first starting point is not limited to these configurations. For example, three or more regions each having a linear shape may extend from the first starting point. The same holds true for the regions extending from the second to fourth starting points.

In addition, as a nitride semiconductor light-emitting element according to each of the embodiments and variations described above, an element that emits light having a wavelength in the 450 nm band has been described, but the nitride semiconductor light-emitting element is not limited to this and may also emit light having a wavelength in other wavelength bands.

In addition, forms obtained by various modifications to the respective exemplary embodiments described above that can be conceived by a person of skill in the art as well as forms realized by arbitrarily combining structural components and functions in the respective exemplary embodiments described above which are within the scope of the essence of the present disclosure are also included in the present disclosure.

### INDUSTRIAL APPLICABILITY

The nitride semiconductor light-emitting element according to the present disclosure is applicable as, for example, as a small high-power light source, automotive headlamp devices, etc.

1. A nitride semiconductor light-emitting element comprising:
a substrate;
a semiconductor stack structure including an n-type semiconductor layer, an active layer, and a p-type semiconductor layer stacked in sequence above a main surface of the substrate, the semiconductor stack structure having a rectangular shape in a plan view of the main surface;
a p-side contact electrode disposed above and in contact with the p-type semiconductor layer in a p-side contact region; and
an n-side contact electrode disposed above and in contact with the n-type semiconductor layer in an n-side contact region, wherein
in the plan view of the main surface,
the semiconductor stack structure includes a first corner portion, a second corner portion disposed on a same side of a rectangular outer edge of the semiconductor stack structure as the first corner portion, a third corner portion disposed diagonally to the first corner portion, and a fourth corner portion disposed diagonally to the second corner portion,
the n-side contact region includes a first region having a linear shape and extending in one direction from a first starting point that is spaced apart from the first corner portion, a second region having a linear shape and extending in one direction from a second starting point that is spaced apart from the second corner portion, a third region having a linear shape and extending in one direction from a third starting point that is spaced apart from the third corner portion, and a fourth region having a linear shape and extending in one direction from a fourth starting point that is spaced apart from the fourth corner portion,
the p-side contact region is disposed between the first starting point and the first corner portion, between the second starting point and the second corner portion, between the third starting point and the third corner portion, and between the fourth starting point and the fourth corner portion, and
a first distance that is a distance between the first corner portion and the first starting point, a second distance that is a distance between the second corner portion and the second starting point, a third distance that is a distance between the third corner portion and the third starting point, and a fourth distance that is a distance between the fourth corner portion and the fourth starting point are each less than or equal to 0.26 times a length of a shorter side of the semiconductor stack structure.

2. The nitride semiconductor light-emitting element according to claim 1, wherein
in the plan view of the main surface,
the third region is disposed on an extended line of the first region and spaced apart from the first region,
the fourth region is disposed on an extended line of the second region and spaced apart from the second region,
the first region and the third region extend in a same direction, and
the second region and the fourth region extend in a same direction.

3. The nitride semiconductor light-emitting element according to claim 2, wherein
in the plan view of the main surface,
the n-side contact region includes:
a fifth region disposed between the first region and the third region and spaced apart from each of the first region and the third region, the fifth region having a linear shape; and
a sixth region disposed between the second region and the fourth region and spaced apart from each of the second region and the fourth region, the sixth region having a linear shape, and
the fifth region and the sixth region intersect.

4. The nitride semiconductor light-emitting element according to claim 2, wherein
in the plan view of the main surface,
the first region, the second region, the third region, and the fourth region are spaced apart from one another.

5. The nitride semiconductor light-emitting element according to claim 4, wherein
b≤0.3,
d5=d6, and
0<d5/a<1.06b²−0.95b+0.61 are satisfied, where: d5 denotes a fifth distance that is half a distance between the first region and the third region; d6 denotes a sixth distance that is half a distance between the second region and the fourth region; a denotes the length of the shorter side; and b denotes a proportion of an area of the n-side contact region to an area of the semiconductor stack structure in the plan view of the main surface.

6. The nitride semiconductor light-emitting element according to claim 4, wherein
b≤0.3,
d5=d6, and
0<d5/a<−0.95b²+0.89b+0.11 are satisfied, where: d5 denotes a fifth distance that is half a distance between the first region and the third region; d6 denotes a sixth distance that is half a distance between the second region and the fourth region; a denotes the length of the shorter side; and b denotes a proportion of an area of the n-side contact region to an area of the semiconductor stack structure in the plan view of the main surface.

7. The nitride semiconductor light-emitting element according to claim 1, wherein
in the plan view of the main surface,
the first region and the third region are connected to each other, the third region being disposed on an extended line of the first region,
the second region and the fourth region are connected to each other, the fourth region being disposed on an extended line of the second region, and
b≤0.3,
r1=r2=r3=r4, and
0<r1/a<−0.54b²+0.59b+0.16 are satisfied where:
r1 denotes the first distance that is the distance between the first corner portion and the first starting point, r2 denotes the second distance that is the distance between the second corner portion and the second starting point, r3 denotes the third distance that is the distance between the third corner portion and the third starting point, r4 denotes the fourth distance that is the distance between the fourth corner portion and the fourth starting point;
a denotes the length of the shorter side; and
b denotes a proportion of an area of the n-side contact region to an area of the semiconductor stack structure in the plan view of the main surface.

8. The nitride semiconductor light-emitting element according to claim 1, wherein
in the plan view of the main surface,
the n-side contact region includes:
a first additional region having a linear shape and extending from the first starting point in a direction different from a direction of the first region;
a second additional region having a linear shape and extending from the second starting point in a direction different from a direction of the second region;
a third additional region having a linear shape and extending from the third starting point in a direction different from a direction of the third region; and
a fourth additional region having a linear shape and extending from the fourth starting point in a direction different from a direction of the fourth region,
the first region and the second additional region are connected to each other,
the second region and the third additional region are connected to each other,
the third region and the fourth additional region are connected to each other, and
the fourth region and the first additional region are connected to each other.

9. The nitride semiconductor light-emitting element according to claim 8, wherein
in the plan view of the main surface,
the first region and the second additional region extend in a same direction,
the second region and the third additional region extend in a same direction,
the third region and the fourth additional region extend in a same direction, and
the fourth region and the first additional region extend in a same direction.

10. The nitride semiconductor light-emitting element according to claim 8, wherein
b≤0.3,
r1=r2=r3=r4, and
0<r1/a≤0.26 are satisfied where:
r1 denotes the first distance that is the distance between the first corner portion and the first starting point, r2 denotes the second distance that is the distance between the second corner portion and the second starting point, r3 denotes the third distance that is the distance between the third corner portion and the third starting point, r4 denotes the fourth distance that is the distance between the fourth corner portion and the fourth starting point;
a denotes the length of the shorter side; and
b denotes a proportion of an area of the n-side contact region to an area of the semiconductor stack structure in the plan view of the main surface.

11. The nitride semiconductor light-emitting element according to claim 8, wherein
b≤0.3,
r1=r2=r3=r4, and
−0.26b+0.15<r1/a≤0.26 are satisfied where:
r1 denotes the first distance that is the distance between the first corner portion and the first starting point, r2 denotes the second distance that is the distance between the second corner portion and the second starting point, r3 denotes the third distance that is the distance between the third corner portion and the third starting point, r4 denotes the fourth distance that is the distance between the fourth corner portion and the fourth starting point;
a denotes the length of the shorter side; and
b denotes a proportion of an area of the n-side contact region to an area of the semiconductor stack structure in the plan view of the main surface.

12. The nitride semiconductor light-emitting element according to claim 1, wherein
in the plan view of the main surface,
the n-side contact region includes:
a first additional region having a linear shape and extending from the first starting point in a direction different from a direction of the first region;
a second additional region having a linear shape and extending from the second starting point in a direction different from a direction of the second region;
a third additional region having a linear shape and extending from the third starting point in a direction different from a direction of the third region; and
a fourth additional region having a linear shape and extending from the fourth starting point in a direction different from a direction of the fourth region,
the second additional region is disposed on an extended line of the first region and spaced apart from the first region, the second additional region extending in a same direction as the first region,
the third additional region is disposed on an extended line of the second region and spaced apart from the second region, the third additional region extending in a same direction as the second region,
the fourth additional region is disposed on an extended line of the third region and spaced apart from the third region, the fourth additional region extending in a same direction as the third region, and
the first additional region is disposed on an extended line of the fourth region and spaced apart from the fourth region, the first additional region extending in a same direction as the fourth region.

13. The nitride semiconductor light-emitting element according to claim 12, wherein
0.1≤b≤0.3,
d7=d8=d9=d10, and
−2.50b²+1.75b−0.15<d7/a<−0.30b+0.35 are satisfied where:
d7 denotes a seventh distance that is a distance between the first region and the second additional region, d8 denotes an eighth distance that is a distance between the second region and the third additional region, d9 denotes a ninth distance that is a distance between the third region and the fourth additional region, d10 denotes a tenth distance that is a distance between the fourth region and the first additional region;
a denotes the length of the shorter side; and
b denotes a proportion of an area of the n-side contact region to an area of the semiconductor stack structure in the plan view of the main surface.

14. The nitride semiconductor light-emitting element according to claim 12, wherein
b≤0.3,
d7=d8=d9=d10, and
0<d7/a<−5.20b²+2.09b+0.09 are satisfied where:
d7 denotes a seventh distance that is a distance between the first region and the second additional region, d8 denotes an eighth distance that is a distance between the second region and the third additional region, d9 denotes a ninth distance that is a distance between the third region and the fourth additional region, d10 denotes a tenth distance that is a distance between the fourth region and the first additional region;
a denotes the length of the shorter side; and
b denotes a proportion of an area of the n-side contact region to an area of the semiconductor stack structure in the plan view of the main surface.

15. A nitride semiconductor light-emitting element comprising:
a substrate;
a semiconductor stack structure including an n-type semiconductor layer, an active layer, and a p-type semiconductor layer stacked in sequence above a main surface of the substrate, the semiconductor stack structure having a rectangular shape in a plan view of the main surface;
a p-side contact electrode disposed above and in contact with the p-type semiconductor layer in a p-side contact region; and
an n-side contact electrode disposed above and in contact with the n-type semiconductor layer in an n-side contact region, wherein
in the plan view of the main surface,
the semiconductor stack structure includes a first corner portion, and a second corner portion disposed on a same side of a rectangular outer edge of the semiconductor stack structure as the first corner portion,
the n-side contact region includes a first region having a linear shape and extending in one direction from a first starting point that is spaced apart from the first corner portion, and a second region having a linear shape and extending in one direction from a second starting point that is spaced apart from the second corner portion,
the p-side contact region is disposed between the first starting point and the first corner portion, and between the second starting point and the second corner portion,
the first region and the second region are connected to each other,
a first distance that is a distance between the first corner portion and the first starting point and a second distance that is a distance between the second corner portion and the second starting point are each less than or equal to 0.26 times a length of a shorter side of the semiconductor stack structure, and
the first region includes the second starting point.

16. A nitride semiconductor light-emitting element comprising:
a substrate;
a semiconductor stack structure including an n-type semiconductor layer, an active layer, and a p-type semiconductor layer stacked in sequence above a main surface of the substrate, the semiconductor stack structure having a rectangular shape in a plan view of the main surface of the substrate;
a p-side contact electrode disposed above and in contact with the p-type semiconductor layer in a p-side contact region; and
a plurality of n-side contact electrodes disposed above the n-type semiconductor layer, each of the plurality of n-side contact electrodes being in contact with the n-type semiconductor layer in a corresponding one of a plurality of n-side contact regions arranged in a matrix of at least three rows and three columns, wherein
in the plan view of the main surface,
the semiconductor stack structure includes a first corner portion,
the plurality of n-side contact regions include:
a first n-side contact region disposed in closest proximity to the first corner portion;
a first Xn-side contact region disposed adjacent to the first n-side contact region in a row direction; and
a first Yn-side contact region disposed adjacent to the first n-side contact region in a column direction,
the first n-side contact region is disposed in a first unit having a rectangular shape, the first unit being enclosed by: a straight line that is equidistant from a center of gravity of the first n-side contact region and a center of gravity of the first Xn-side contact region; a straight line that is equidistant from the center of gravity of the first n-side contact region and a center of gravity of the first Yn-side contact region; and an outer edge of the semiconductor stack structure,
the first n-side contact region includes a first region having a linear shape and extending in one direction from a first starting point that is spaced apart from the first corner portion,
the p-side contact region is disposed between the first starting point and the first corner portion, and
a first distance that is a distance between the first corner portion and the first starting point is less than or equal to 0.26 times a length of a shorter side of the first unit.

17. The nitride semiconductor light-emitting element according to claim 16, wherein
in the plan view of the main surface,
the semiconductor stack structure includes a second corner portion disposed on a same side of a rectangular outer edge of the semiconductor stack structure as the first corner portion, a third corner portion disposed diagonally to the first corner portion, and a fourth corner portion disposed diagonally to the second corner portion,
the plurality of n-side contact regions include:
a second n-side contact region disposed in closest proximity to the second corner portion;
a second Xn-side contact region disposed adjacent to the second n-side contact region in a row direction;
a second Yn-side contact region disposed adjacent to the second n-side contact region in a column direction;
a third n-side contact region disposed in closest proximity to the third corner portion;
a third Xn-side contact region disposed adjacent to the third n-side contact region in a row direction;
a third Yn-side contact region disposed adjacent to the third n-side contact region in a column direction;
a fourth n-side contact region disposed in closest proximity to the fourth corner portion;
a fourth Xn-side contact region disposed adjacent to the fourth n-side contact region in a row direction; and
a fourth Yn-side contact region disposed adjacent to the fourth n-side contact region in a column direction,
the second n-side contact region is disposed in a second unit having a rectangular shape, the second unit being enclosed by: a straight line that is equidistant from a center of gravity of the second n-side contact region and a center of gravity of the second Xn-side contact region; a straight line that is equidistant from the center of gravity of the second n-side contact region and a center of gravity of the second Yn-side contact region; and an outer edge of the semiconductor stack structure,
the third n-side contact region is disposed in a third unit having a rectangular shape, the third unit being enclosed by: a straight line that is equidistant from a center of gravity of the third n-side contact region and a center of gravity of the third Xn-side contact region; a straight line that is equidistant from the center of gravity of the third n-side contact region and a center of gravity of the third Yn-side contact region; and an outer edge of the semiconductor stack structure,
the fourth n-side contact region is disposed in a fourth unit having a rectangular shape, the fourth unit being enclosed by: a straight line that is equidistant from a center of gravity of the fourth n-side contact region and a center of gravity of the fourth Xn-side contact region; a straight line that is equidistant from the center of gravity of the fourth n-side contact region and a center of gravity of the fourth Yn-side contact region; and an outer edge of the semiconductor stack structure,
the second n-side contact region includes a second region having a linear shape and extending in one direction from a second starting point that is spaced apart from the second corner portion,
the third n-side contact region includes a third region having a linear shape and extending in one direction from a third starting point that is spaced apart from the third corner portion,
the fourth n-side contact region includes a fourth region having a linear shape and extending in one direction from a fourth starting point that is spaced apart from the fourth corner portion,
the p-side contact region is disposed between the second starting point and the second corner portion, between the third starting point and the third corner portion, and between the fourth starting point and the fourth corner portion, and
a second distance that is a distance between the second corner portion and the second starting point is less than or equal to 0.26 times a length of a shorter side of the second unit, a third distance that is a distance between the third corner portion and the third starting point is less than or equal to 0.26 times a length of a shorter side of the third unit, and a fourth distance that is a distance between the fourth corner portion and the fourth starting point is less than or equal to 0.26 times a length of a shorter side of the fourth unit.

18. The nitride semiconductor light-emitting element according to claim 17, wherein
in the plan view of the main surface,
the plurality of n-side contact regions are arranged in a matrix of N rows and M columns where N≥3 and M≥3,
centers of gravity of M n-side contact regions among the plurality of n-side contact regions are on a straight line, the M n-side contact regions being disposed in each of first to N-th rows,
centers of gravity of N n-side contact regions among the plurality of n-side contact regions are on a straight line, the N n-side contact regions being disposed in each of first to M-th columns,
in a unit enclosed by (i) a third straight line that divides equally a region between a first straight line and a second straight line, (ii) a fifth straight line that divides equally a region between the second straight line and a fourth straight line, (iii) an eighth straight line that divides equally a region between a sixth straight line and a seventh straight line, and (iv) a tenth straight line that divides equally a region between the seventh straight line and a ninth straight line, the first straight line connecting centers of gravity of the M n-side contact regions disposed in an i−1-th row where 2≤i≤N−1, the second straight line connecting centers of gravity of the M n-side contact regions disposed in an i-th row, the fourth straight line connecting centers of gravity of the M n-side contact regions disposed in an i+1-th row, the sixth straight line connecting centers of gravity of the N n-side contact regions disposed in an j−1-th column where 2≤j≤M−1, the seventh straight line connecting centers of gravity of the N n-side contact regions disposed in a j-th column, the ninth straight line connecting the centers of gravity of the N n-side contact regions disposed in a j+1-th column,
the unit includes: a first unit corner portion between the third straight line and the eighth straight line; a second unit corner portion between the fifth straight line and the eighth straight line; a third unit corner portion disposed diagonally to the first unit corner portion; and a fourth unit corner portion disposed diagonally to the second unit corner portion,
among the plurality of n-side contact regions, an n-side contact region disposed in the unit includes a first unit region extending in one direction from a first unit starting point that is spaced apart from the first unit corner portion, the first unit region having a linear shape,
the p-side contact region is disposed between the first unit starting point and the first unit corner portion,
a distance from the first unit corner portion and the first unit starting point is less than or equal to 0.26 times a length of a shorter side of the unit, and
among the plurality of n-side contact regions, n-side contact regions disposed in all of one or more units that satisfy 2≤i≤N−1, and 2≤j≤M−1 include the first unit region, the one or more units comprising the unit.

19. The nitride semiconductor light-emitting element according to claim 18, wherein
the n-side contact region disposed in the unit includes: a second unit region having a linear shape and extending in one direction from a second unit starting point that is spaced apart from the second unit corner portion; a third unit region having a linear shape and extending in one direction from a third unit starting point that is spaced apart from the third unit corner portion; and a fourth unit region having a linear shape and extending in one direction from a fourth unit starting point that is spaced apart from the fourth unit corner portion,
the p-side contact region is disposed between the second unit starting point and the second unit corner portion, between the third unit starting point and the third unit corner portion, and between the fourth unit starting point and the fourth unit corner portion, and
a distance between the second unit corner portion and the second unit starting point, a distance between the third unit corner portion and the third unit starting point, and a distance between the fourth unit corner portion and the fourth unit starting point are each less than or equal to 0.26 times the length of the shorter side of the unit.

20. The nitride semiconductor light-emitting element according to claim 18, wherein
in the plan view of the main surface,
the first n-side contact region, the second n-side contact region, the third n-side contact region, and the fourth n-side contact region each have an X shape, and
b≤0.10 is satisfied where b denotes a proportion of an area of the n-side contact region to an area of the semiconductor stack structure.

21. The nitride semiconductor light-emitting element according to claim 18, wherein
in the plan view of the main surface,
the first n-side contact region, the second n-side contact region, the third n-side contact region, and the fourth n-side contact region each have a rectangular annular shape, and
b≤0.07 is satisfied where b denotes a proportion of an area of the n-side contact region to an area of the semiconductor stack structure.
